(19) United States
(12) Patent Application Publication
(10) Pub. No.: US 2024/0341190 A1
(43) Pub. Date: Oct. 10, 2024

(54) ORGANIC COMPOUND AND ORGANIC LIGHT-EMITTING DEVICE

(71) Applicant: CANON KABUSHIKI KAISHA, Tokyo (JP)

(72) Inventors: YOSUKE NISHIDE, Kanagawa (JP); JUN KAMATANI, Tokyo (JP); NAOKI YAMADA, Tokyo (JP); HIROKI OHRUI, Tokyo (JP); HIRONOBU IWAWAKI, Kanagawa (JP); HIROKAZU MIYASHITA, Miyagi (JP)

(21) Appl. No.: 18/745,601

(22) Filed: Jun. 17, 2024

Related U.S. Application Data
(63) Continuation of application No. PCT/JP2022/045334, filed on Dec. 8, 2022.

(30) Foreign Application Priority Data
Dec. 17, 2021 (JP) 2021-204830

(51) Int. Cl. H10K 85/60; C07F 5/02; C09K 11/06; G03G 15/04; G03G 15/043; H10K 50/13; H10K 59/10; H10K 65/00

(52) U.S. Cl. CPC H10K 85/658; C07F 5/027; C09K 11/06; G03G 15/04036; G03G 15/043; C09K 2211/1018; H10K 50/13; H10K 59/10; H10K 65/00

(57) ABSTRACT

The present disclosure provides an organic compound represented by the following general formula [1-1] or [1-2].

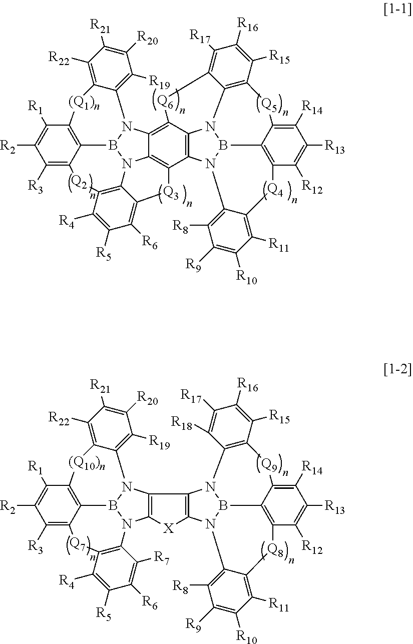

R₁ to R₂₂ are each independently selected from a hydrogen atom, an alkyl group, and so forth. Q₁ to Q₁₀ are each independently selected from a direct bond and a linking group. The linking group is selected from C(R₂₃) (R₂₄), N(R₂₅), an oxygen atom, a sulfur atom, a selenium atom, and a tellurium atom. R₂₃ to R₂₅ are each independently selected from a hydrogen atom, an alkyl group, and so forth. Each n is 0 or 1, provided that in each of general formulae [1-1] and [1-2], at least one of n is 1. X is selected from an oxygen atom, a sulfur atom, a selenium atom, a tellurium atom, and N(R₂₆). R₂₆ is selected from a hydrogen atom, an alkyl group, and so forth.

### CROSS-REFERENCE TO RELATED APPLICATIONS

This application is a Continuation of International Patent Application No. PCT/JP2022/045334, filed Dec. 8, 2022, which claims the benefit of Japanese Patent Application No. 2021-204830, filed Dec. 17, 2021, both of which are hereby incorporated by reference herein in their entirety.

### TECHNICAL FIELD

The present invention relates to an organic compound and an organic light-emitting device containing the same.

### BACKGROUND ART

An organic light-emitting device (hereinafter, also referred to as an “organic electroluminescent device” or “organic EL device”) is an electronic device including a pair of electrodes and an organic compound layer disposed between these electrodes. The injection of electrons and holes from the pair of electrodes generates excitons of the light-emitting organic compound in the organic compound layer, and when the excitons return to the ground state, the organic light-emitting device emits light. Recent progress in organic light-emitting devices has been remarkable, and their features include low driving voltage, various emission wavelengths, fast response time, and a contribution to enabling light-emitting apparatuses to be thinner and lighter.

In addition, sRGB and Adobe RGB standards have been used as color gamuts used for displays, and materials for reproducing them have been required. Recently, BT-2020 has been introduced as a standard for further expanding the color gamut.

Up to now, light-emitting organic compounds have been actively created. This is because the creation of a compound with excellent light emission characteristics is important in providing a high-performance organic light-emitting device. Non Patent Literature 1 describes the following compound 1-a. Patent Literature 1 describes the following compound 2-a.

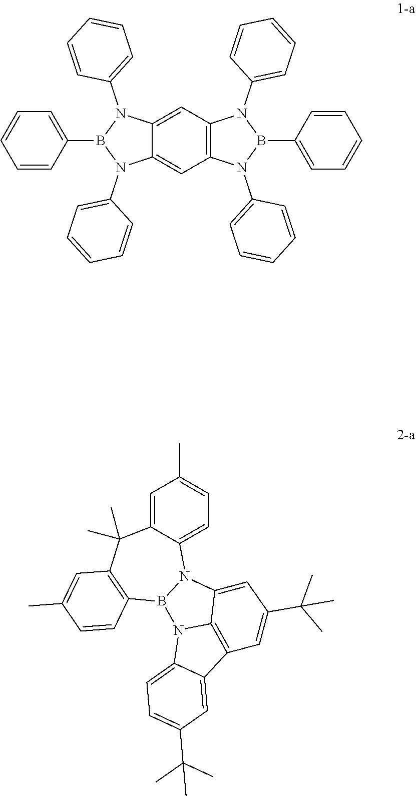 [SMILES: c1ccc(B2N(c3ccccc3)c3cc4c(cc3N2c2ccccc2)N(c2ccccc2)B(c2ccccc2)N4c2ccccc2)cc1 ; Cc1ccc2c(c1)C(C)(C)c1cc(C)ccc1N1B2n2c3ccc(C(C)(C)C)cc3c3cc(C(C)(C)C)cc1c32]

### CITATION LIST

### Patent Literature

PTL 1 Chinese Patent Application Publication No. 111471064

### Non Patent Literature

NPL 1 J. Org. Chem., Vol. 36, No. 8, 1971, 1161

Although the synthesis example of compound 1-a is disclosed in Non Patent Literature 1, there is no suggestion regarding luminous efficiency or emission color. Patent Literature 1 discloses an example of a blue light-emitting device with compound 2-a. Further improvements in luminous efficiency, color purity, and durability characteristics are desired.

### SUMMARY OF INVENTION

The present invention has been made in view of the above problems, and it is an object of the present invention to provide a blue light-emitting material having high luminous efficiency, high color purity, and a deep LUMO level (far from vacuum level). It is another object of the present invention to provide an organic light-emitting device having excellent color purity, luminous efficiency, and durability characteristics.

An organic compound of the present invention is characterized by being represented by the following general formula [1-1] or [1-2].

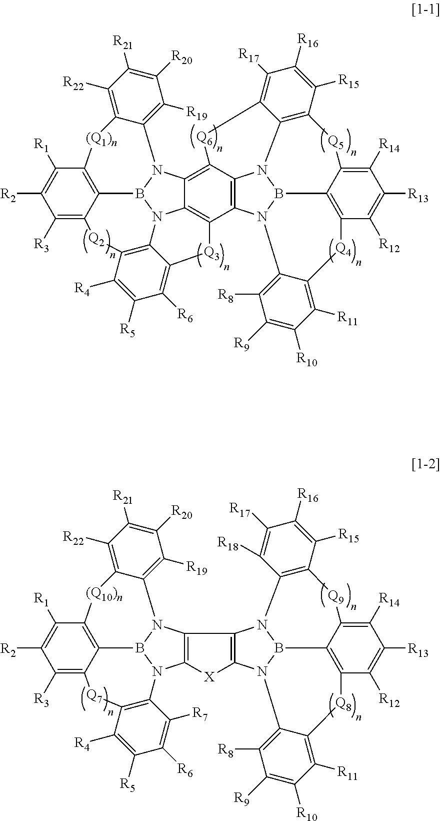

In general formula [1-1] or [1-2], R₁ to R₂₂ are each independently selected from a hydrogen atom, a deuterium atom, a halogen atom, a cyano group, a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a substituted or unsubstituted heteroaryloxy group, and a substituted or unsubstituted silyl group.

Q₁ to Q₁₀ are each independently selected from a direct bond and a linking group. The linking group is selected from C (R₂₃) (R₂₄), N (R₂₅), an oxygen atom, a sulfur atom, a selenium atom, and a tellurium atom. R₂₃ to R₂₅ are each independently selected from a hydrogen atom, a halogen atom, a substituted or unsubstituted alkyl group, a substituted or unsubstituted alkoxy group, a substituted or unsubstituted aryl group, and a substituted or unsubstituted heteroaryl group. R₂₃ and R₂₄ may be taken together to form a ring.

Each n is 0 or 1, provided that in each of general formulae [1-1] and [1-2], at least one of n is 1.

X is selected from an oxygen atom, a sulfur atom, a selenium atom, a tellurium atom, and N(R₂₆). R₂₆ is selected from a hydrogen atom, a halogen atom, a substituted or unsubstituted alkyl group, a substituted or unsubstituted alkoxy group, a substituted or unsubstituted aryl group, and a substituted or unsubstituted heteroaryl group.

Further features of the present invention will become apparent from the following description of exemplary embodiments with reference to the attached drawings.

### BRIEF DESCRIPTION OF DRAWINGS

FIG. 1A is a schematic cross-sectional view of an example of a pixel of a display apparatus according to an embodiment of the present invention.

FIG. 1B is a schematic cross-sectional view of an example of a display apparatus including organic light-emitting devices according to an embodiment of the present invention.

FIG. 2 is a schematic view of an example of a display apparatus according to an embodiment of the present invention.

FIG. 3A is a schematic view of an example of an image pickup apparatus according to an embodiment of the present invention.

FIG. 3B is a schematic view of an example of an electronic apparatus according to an embodiment of the present invention.

FIG. 4A is a schematic view of an example of a display apparatus according to an embodiment of the present invention.

FIG. 4B is a schematic view of an example of a foldable display apparatus.

FIG. 5A is a schematic view of an example of a lighting apparatus according to an embodiment of the present invention.

FIG. 5B is a schematic view of an example of a moving object including an automotive lighting unit according to an embodiment of the present invention.

FIG. 6A is a schematic view illustrating an example of a wearable device according to an embodiment of the present invention.

FIG. 6B is a schematic view of another example of a wearable device according to an embodiment of the present invention.

FIG. 7A is a schematic view of an example of an image-forming apparatus according to an embodiment of the present invention.

FIG. 7B is a schematic view of an example of an exposure light source of an image-forming apparatus according to an embodiment of the present invention.

FIG. 7C is a schematic view of an example of an exposure light source of an image-forming apparatus according to an embodiment of the present invention.

### DESCRIPTION OF EMBODIMENTS

### Organic Compound

An organic compound of the present embodiment is represented by the following general formula [1-1] or [1-2].

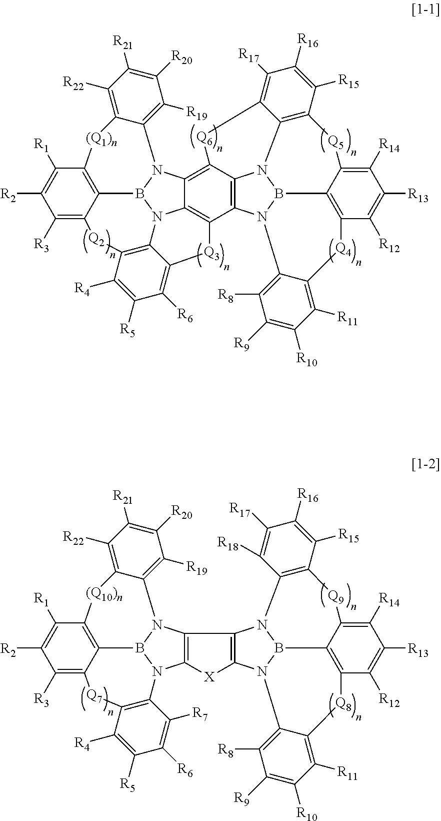

R₁ to R₂₂

In general formula [1-1] or [1-2], R₁ to R₂₂ are each independently selected from a hydrogen atom, a deuterium atom, a halogen atom, a cyano group, a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a substituted or unsubstituted heteroaryloxy group, and a substituted or unsubstituted silyl group.

Examples of the alkyl group include, but are not limited to, a methyl group, an ethyl group, a n-propyl group, an isopropyl group, a n-butyl group, a tert-butyl group, a sec-butyl group, an octyl group, a cyclohexyl group, a 1-adamantyl group, and a 2-adamantyl group. Among these, an alkyl group having 1 to 10 carbon atoms is preferred.

Examples of the alkoxy group include, but are not limited to, a methoxy group, an ethoxy group, a propoxy group, a 2-ethyloctyloxy group, and a benzyloxy group. Among these, an alkoxy group having 1 to 6 carbon atoms is preferred.

Examples of an amino group include, but are not limited to, an N-methylamino group, an N-ethylamino group, an N,N-dimethylamino group, an N,N-diethylamino group, an N-methyl-N-ethylamino group, an N-benzylamino group, an N-methyl-N-benzylamino group, an N,N-dibenzylamino group, an anilino group, an N,N-diphenylamino group, an N,N-dinaphthylamino group, an N,N-difluorenylamino group, an N-phenyl-N-tolylamino group, an N,N-ditolylamino group, an N-methyl-N-phenylamino group, an N,N-dianisolylamino group, an N-mesityl-N-phenylamino group, an N,N-dimesitylamino group, an N-phenyl-N-(4-tert-butylphenyl)amino group, an N-phenyl-N-(4-trifluoromethylphenyl)amino group, and an N-piperidyl group.

Examples of the aryl group include, but are not limited to, a phenyl group, a naphthyl group, an indenyl group, a biphenyl group, a terphenyl group, a fluorenyl group, a phenanthryl group, and a triphenylenyl group. Among these, an aryl group having 6 to 18 carbon atoms is preferred.

Examples of the heteroaryl group include, but are not limited to, a pyridyl group, a pyrazinyl group, a pyrimidinyl group, a triazinyl group, a quinolyl group, an isoquinolyl group, an oxazolyl group, a thiazolyl group, an imidazolyl group, a benzoxazolyl group, a benzothiazolyl group, a benzimidazolyl group, a thienyl group, a furanyl group, a pyrrolyl group, a benzothienyl group, a benzofuranyl group, an indolyl group, a dibenzothiophenyl group, and a dibenzofuranyl group. Among these, a heteroaryl group having 3 to 15 carbon atoms is preferred.

Examples of the aryloxy group and the heteroaryloxy group include, but are not limited to, a phenoxy group and a thienyloxy group. Among these, an aryloxy group having 6 to 18 carbon atoms and a heteroaryloxy group are preferred.

Examples of the silyl group include, but are not limited to, a trimethylsilyl group and a triphenylsilyl group.

Examples of substituents that may be further contained in the alkyl group, the alkoxy group, the amino group, the aryl group, the aryloxy group, the heteroaryl group, the heteroaryloxy group, and the silyl group include, but are not limited to, alkyl groups, such as a methyl group, an ethyl group, a n-propyl group, an isopropyl group, a n-butyl group, and a tert-butyl group; aralkyl groups, such as a benzyl group; aryl groups, such as a phenyl group and a biphenyl group; amino groups, such as a dimethylamino group, a diethylamino group, a dibenzylamino group, a diphenylamino group, and a ditolylamino group; alkoxy groups, such as a methoxy group, an ethoxy group, and propoxy group; aryloxy groups, such as a phenoxy group; halogen atoms, such as a fluorine atom, a chlorine atom, a bromine atom, and an iodine atom; and a thienyl group and a thiol group.

Q₁ to Q₁₀

In general formula [1-1] or [1-2], Q₁ to Q₁₀ are each independently selected from a direct bond and a linking group. The linking group is selected from C(R₂₃) (R₂₄), N(R₂₅), an oxygen atom, a sulfur atom, a selenium atom, and a tellurium atom.

R₂₃ to R₂₅

R₂₃ to R₂₅ are each independently selected from a hydrogen atom, a halogen atom, a substituted or unsubstituted alkyl group, a substituted or unsubstituted alkoxy group, a substituted or unsubstituted aryl group, and a substituted or unsubstituted heteroaryl group. R₂₃ and R₂₄ may be taken together to form a ring.

Specific examples of the alkyl group, the alkoxy group, the aryl group, and the heteroaryl group represented by R₂₃ to R₂₅ include, but are not limited to, the same as those described for R₁ to R₂₂. Specific examples of a substituent that may be further contained in the alkyl group, the alkoxy group, the aryl group, and the heteroaryl group include, but are not limited to, the same as those described for R₁ to R₂₂.

In general formula [1-1], when Q₁ is N(R₂₅), R₂₅ may be combined with R₁ or R₂₂ to form a ring. When Q₂ is N(R₂₅), R₂₅ may be combined with R₃ or R₄ to form a ring. When Q₃ is N(R₂₅), R₂₅ may be combined with R₆ to form a ring. When Q₄ is N(R₂₅), R₂₅ may be combined with R₁₁ or R₁₂ to form a ring. When Q₅ is N(R₂₅), R₂₅ may be combined with R₁₄ or R₁₅ to form a ring. When Q₆ is N(R₂₅), R₂₅ may be combined with R₁₇ to form a ring.

In general formula [1-2], when Q₇ is N(R₂₅), R₂₅ may be combined with R₃ or R₄ to form a ring. When Q₈ is N(R₂₅), R₂₅ may be combined with R₁₁ or R₁₂ to form a ring. When Q₉ is N(R₂₅), R₂₅ may be combined with R₁₄ or R₁₅ to form a ring. When Q₁₀ is N(R₂₅), R₂₅ may be combined with R₁ or R₂₂ to form a ring.

n

In general formula [1-1] or [1-2], each n is 0 or 1, provided that in each of general formulae [1-1] and [1-2], at least one of n is 1.

In the case where n is 1 and where Q₁ to Q₆ and Q₇ to Q₁₀ (hereinafter, also referred to as “Q₁ and the like”) are each a direct bond, atoms via Q₁ and the like are directly bonded. For example, in the case where n is 1 and where Q₁ is a direct bond in “(Q₁)ₙ” of formula [1-1], the carbon atoms via Q₁ are directly bonded to each other.

In the case where n is 1 and where Q₁ and the like are each a linking group, atoms via Q₁ and the like are bonded via the linking group. For example, in the case where n is 1 and where Q₁ is a linking group in “(Q₁)ₙ” of formula [1-1], the carbon atoms via Q₁ are bonded to each other via the linking group.

When n is 0, there is no bond between atoms via Q₁ and the like. For example, when n is 0 in “(Q₁)ₙ” of formula [1-1], the carbon atoms via Q₁ are not bonded to each other. When n is 0, the carbon atoms via Q₁ and the like are each bonded to a hydrogen atom, a deuterium atom, a halogen atom, a cyano group, a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a substituted or unsubstituted heteroaryloxy group, or a substituted or unsubstituted silyl group.

Specific examples of the alkyl group, the alkoxy group, the amino group, the aryl group, the aryloxy group, the heteroaryl group, the heteroaryloxy group, or the silyl group to which the atoms via Q₁ and the like are each bonded when n is 0 include, but are not limited to, the same as those described for R₁ to R₂₂. Specific examples of a substituent that may be further contained in the alkyl group, the alkoxy group, the amino group, the aryl group, the aryloxy group, the heteroaryl group, the heteroaryloxy group, or the silyl group include, but are not limited to, the same as those described for R₁ to R₂₂.

### X

X is selected from an oxygen atom, a sulfur atom, a selenium atom, a tellurium atom, and N(R₂₆).

### R₂₆

R₂₆ is selected from a hydrogen atom, a halogen atom, a substituted or unsubstituted alkyl group, a substituted or unsubstituted alkoxy group, a substituted or unsubstituted aryl group, and a substituted or unsubstituted heteroaryl group.

Specific examples of the alkyl group, the alkoxy group, the aryl group, and the heteroaryl group represented by R₂₆ include, but are not limited to, the same as those described for R₁ to R₂₂. Specific examples of a substituent that may be further contained in the alkyl group, the alkoxy group, the aryl group, and the heteroaryl group include, but are not limited to, the same as those described for R₁ to R₂₂.

The organic compound of the present embodiment is preferably represented by any one of the following general formulae [2] to [4].

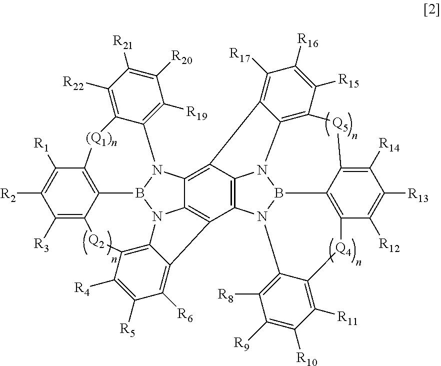

In general formula [2], at least two of n are 1.

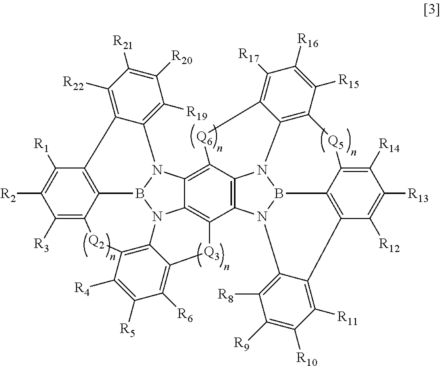

In general formula [3], at least two of n are 1.

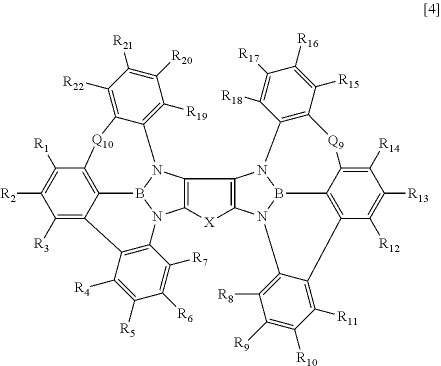

### Synthesis Method

A method for synthesizing an organic compound according to the present embodiment will be described below. The organic compound according to the present embodiment is synthesized in accordance with, for example, reaction schemes illustrated below.

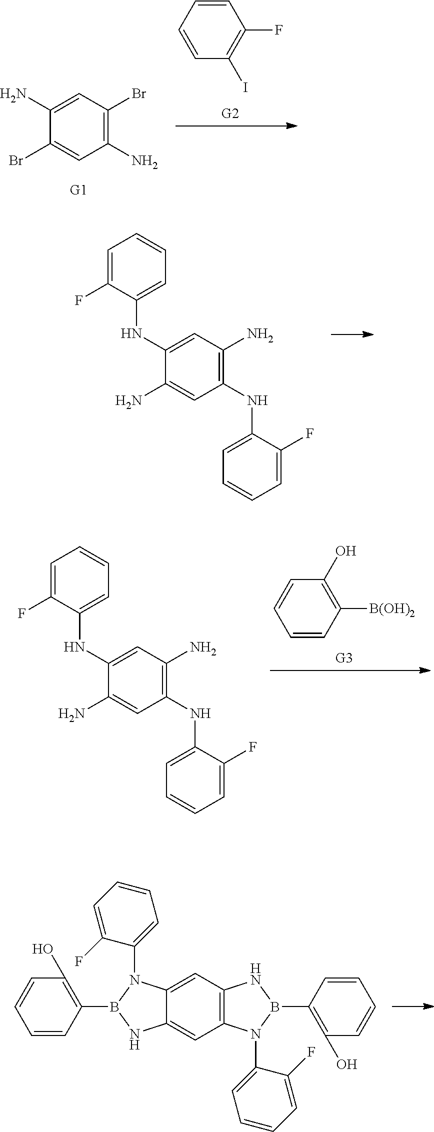 [SMILES: Fc1ccccc1I ; Nc1cc(Br)c(N)cc1Br ; Nc1cc(Nc2ccccc2F)c(N)cc1Nc1ccccc1F ; Nc1cc(Nc2ccccc2F)c(N)cc1Nc1ccccc1F ; OB(O)c1ccccc1O ; Oc1ccccc1B1Nc2cc3c(cc2N1c1ccccc1F)NB(c1ccccc1O)N3c1ccccc1F]

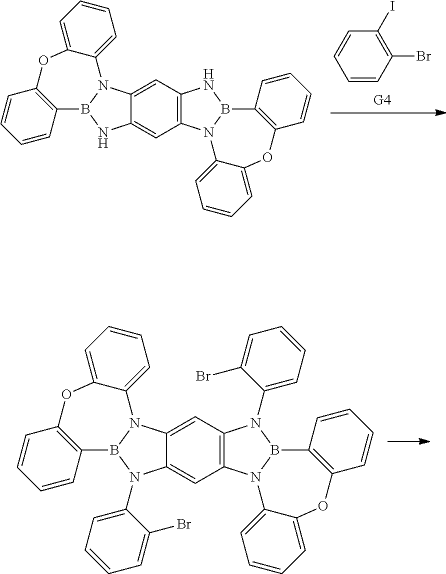

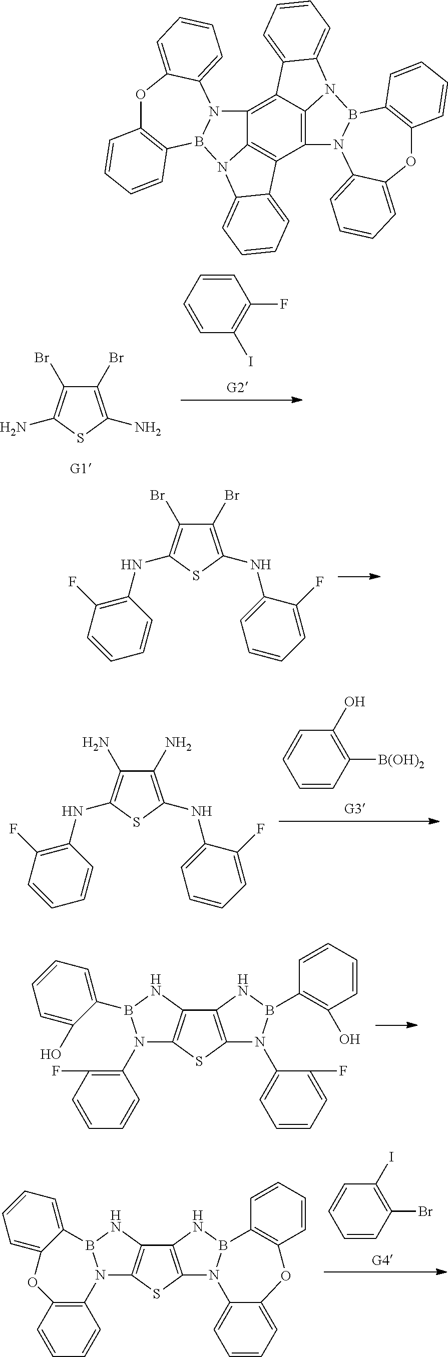

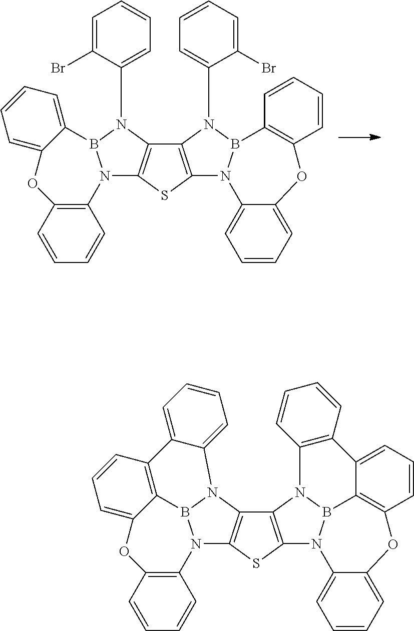 [SMILES: Brc1ccccc1N1B2c3ccccc3Oc3ccccc3N2c2sc3c(c21)N(c1ccccc1Br)B1c2ccccc2Oc2ccccc2N13 ; c1ccc2c(c1)Oc1cccc3c1B1N2c2sc4c(c2N1c1ccccc1-3)N1B2c3c(cccc3-c3ccccc31)Oc1ccccc1N24]

Here, G1 to G4 and G1′ to G4′ are appropriately changed, so that the compounds represented by general formula [1-1] or [1-2] can be synthesized. The synthesis method is not limited thereto. The details of the synthesis method will be described in Examples.

### Feature

The organic compound according to the present embodiment has the following features and thus is a compound having high luminous efficiency, high color purity, a deep HOMO level, a deep LUMO level (far from the vacuum level), and high stability against oxidation. Furthermore, when the organic compound according to the present embodiment is used, it is also possible to provide an organic light-emitting device having color purity, luminous efficiency, and device durability.
(1) The organic compound has a bisdiazaborole derivative having a fused-ring structure, as a basic skeleton and thus emits blue light with high efficiency.
(2) The organic compound has a low LUMO level and thus has high stability against oxygen, resulting in high durability.

Regarding these features, the characteristics of the basic skeleton of the organic compound according to the present embodiment will be described below while comparing with comparative compounds having structures similar to that of the organic compound according to the present embodiment. Specifically, compound 1-a described in Non Patent Literature 1 is used as comparative compound 1-a, comparative compound 2-a described in Patent Document 1 is used as comparative compound 2-a, and exemplified compounds A1, A10, E1, and E7 of the present embodiment are used.
(1) The organic compound has a bisdiazaborole derivative having a fused-ring structure, as a basic skeleton and thus emits blue light with high efficiency.

The inventors have focused on the basic skeleton itself in the invention of the organic compound represented by general formula [1-1] or [1-2].

For blue light emission with high color purity, the basic skeleton itself needs to be in a blue region with high color purity. In the present embodiment, the desired emission wavelength region is a blue region with high color purity. Specifically, when the emission intensity at the maximum emission wavelength in a dilute solution is 1.0, the intensity ratio at 460 nm is 0.3 or more. The basic skeleton in the present embodiment is a skeleton suitable for desired blue light emission.

As presented in Table 1, the S₁ (lowest excited singlet state) wavelength obtained by molecular orbital calculation and the emission spectrum in a dilute toluene solution are compared between exemplified compounds according to the present embodiment and the comparative compounds. Specifically, after the emission spectrum was measured, the emission intensity at 460 nm was compared when the maximum emission intensity was set to 1.0. The emission wavelength was measured by photoluminescence measurement of a dilute toluene solution with F-4500 manufactured by Hitachi, Ltd. at room temperature and at an excitation wavelength of 350 nm.

TABLE 1

| | | S1 (cal.) | PL intensity ratio |
|---|---|---|---|
| | Structural formula | [nm] | @460 nm |
| Exemplified compound A1 | 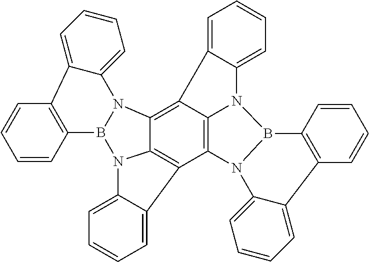 [SMILES: c1ccc2c(c1)B1N(c3ccccc3-2)c2c3c4ccccc4n4c3c(c3c5ccccc5n1c23)N1B4c2ccccc2-c2ccccc21] | 405 | 0.8 |
| Exemplified compound A10 | 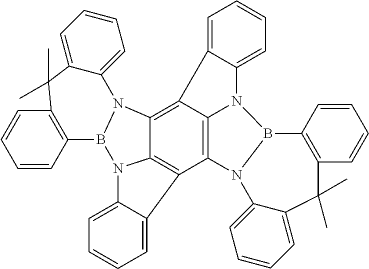 [SMILES: CC1(C)c2ccccc2B2N(c3ccccc31)c1c3c4ccccc4n4c3c(c3c5ccccc5n2c13)N1B4c2ccccc2C(C)(C)c2ccccc21] | 395 | 0.7 |
| Exemplified compound E1 | 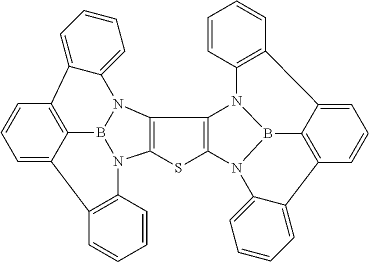 [SMILES: c1ccc2c(c1)-c1cccc3c1B1N2c2sc4c(c2N1c1ccccc1-3)N1B2c3c(cccc3-c3ccccc31)-c1ccccc1N24] | 401 | 0.8 |
| Exemplified compound E7 | 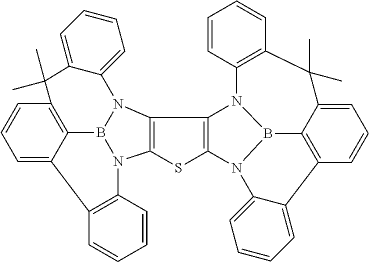 [SMILES: CC1(C)c2ccccc2N2B3c4c(cccc41)-c1ccccc1N3c1sc3c(c12)N1B2c4c(cccc4C(C)(C)c4ccccc41)-c1ccccc1N23] | 393 | 0.7 |
| Comparative compound 1-a | 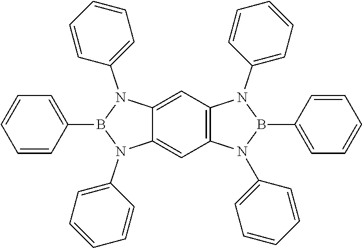 [SMILES: c1ccc(B2N(c3ccccc3)c3cc4c(cc3N2c2ccccc2)N(c2ccccc2)B(c2ccccc2)N4c2ccccc2)cc1] | 327 | <0.1 |
| Comparative compound 2-a | 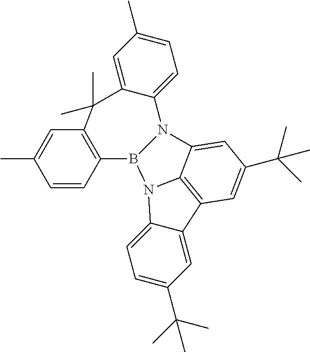 [SMILES: Cc1ccc2c(c1)C(C)(C)c1cc(C)ccc1N1B2n2c3ccc(C(C)(C)C)cc3c3cc(C(C)(C)C)cc1c32] | 342 | <0.1 |

Table 1 indicates that each compound of the present embodiment has two diazaborole units and thus has a longer S₁ wavelength than comparative compounds 1-a and 2-a. The emission (PL) intensity at 460 nm, which is a wavelength required for a blue emission wavelength with high color purity, was less than 0.1 in comparative compounds 1-a and 2-a due to the shorter emission wavelength and 0.3 or more in the compounds according to the present embodiment. That is, each of the compounds according to the present embodiment has two diazaborole skeletons and a fused-ring structure and thus has a longer emission wavelength and efficiently emits light in the blue region with high color purity.

As described above, it has been found that the bisdiazaborole derivatives each having a fused-ring structure exhibits highly efficient blue light emission with high color purity as a unique effect.

The electron orbital distributions at the HOMO and LUMO levels and the S₁ and T₁ energies were visualized by molecular orbital calculations. As the molecular orbital calculation method, the density functional theory (DFT), which is widely used at present, was used with the B3LYP functional and 6-31G* as the basis function. The molecular orbital calculation method was performed using Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010), which is widely used at present. In this specification, hereinafter, the same method is employed for molecular orbital calculations.
(2) The organic compound has a low LUMO level and thus has high stability against oxygen, resulting in high durability.

In organic semiconductors, in the case of compounds having similar band gaps, a compound having lower HOMO-LUMO levels (farther from the vacuum level) has higher stability against oxygen. Lowering the energy level of the LUMO level increases the stability against oxygen, thereby improving the durability of the compound itself and the durability of the organic light-emitting device.

Thus the inventors have focused on the LUMO level. In Table 2, a comparison of the LUMO levels by molecular orbital calculations was made between the exemplified compounds of the present embodiment and the comparative compounds.

TABLE 2

| | | Number of boron | LUMO (cal.) |
|---|---|---|---|
| | Structural formula | units | [eV] |
| Exemplified compound A1 | 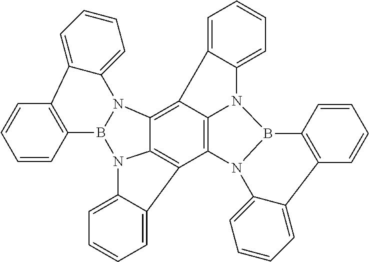 [SMILES: c1ccc2c(c1)B1N(c3ccccc3-2)c2c3c4ccccc4n4c3c(c3c5ccccc5n1c23)N1B4c2ccccc2-c2ccccc21] | 2 | −1.6 |
| Exemplified compound A10 | 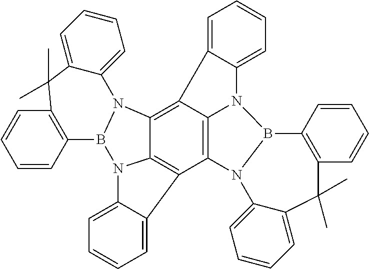 [SMILES: CC1(C)c2ccccc2B2N(c3ccccc31)c1c3c4ccccc4n4c3c(c3c5ccccc5n2c13)N1B4c2ccccc2C(C)(C)c2ccccc21] | 2 | −1.4 |
| Exemplified compound E1 | 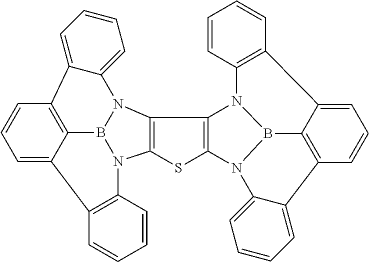 [SMILES: c1ccc2c(c1)-c1cccc3c1B1N2c2sc4c(c2N1c1ccccc1-3)N1B2c3c(cccc3-c3ccccc31)-c1ccccc1N24] | 2 | −1.3 |
| Exemplified compound E7 | 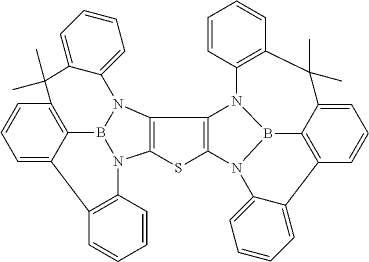 [SMILES: CC1(C)c2ccccc2N2B3c4c(cccc41)-c1ccccc1N3c1sc3c(c12)N1B2c4c(cccc4C(C)(C)c4ccccc41)-c1ccccc1N23] | 2 | −1.2 |
| Comparative compound 1-a | 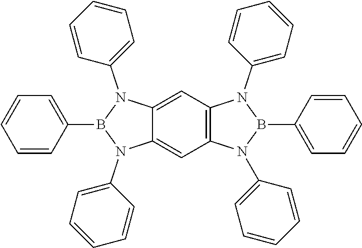 [SMILES: c1ccc(B2N(c3ccccc3)c3cc4c(cc3N2c2ccccc2)N(c2ccccc2)B(c2ccccc2)N4c2ccccc2)cc1] | 2 | −0.5 |
| Comparative compound 2-a | 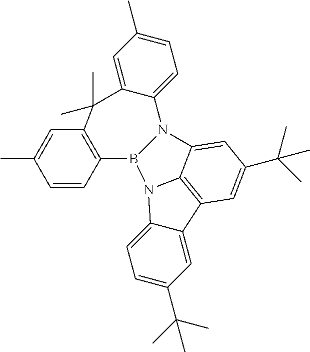 [SMILES: Cc1ccc2c(c1)C(C)(C)c1cc(C)ccc1N1B2n2c3ccc(C(C)(C)C)cc3c3cc(C(C)(C)C)cc1c32] | 1 | −0.9 |

As presented in Table 2, it was found that each compound of the present embodiment is characterized by having two diazaborole units and thus a low LUMO level (far from the vacuum level) compared to comparative compounds 1-a and 2-a. The LUMO level is greatly influenced by a boron atom having electron-withdrawing ability. A compound having higher electron-withdrawing ability has a lower LUMO level. Accordingly, each compound of the present embodiment having two boron atoms in the basic skeleton has a lower LUMO level than comparative compounds 1-a and 2-a.

As described above, it was found that as a unique effect of the bisdiazaborole derivative having a fused-ring structure, the compounds have lower LUMO levels and thus higher stability against oxygen, resulting in higher device durability.

When the organic compound according to the present embodiment further has the following feature, the compound is a stable compound in terms of molecular structure, which is preferable. Furthermore, the use of the organic compound according to the present embodiment can also provide an organic light-emitting device having excellent device durability, which is preferable.
(3) When the compound has a plurality of fused-ring structures formed of Q₁ and the like, liberation due to bond cleavage is less likely to occur; thus, the compound has high thermal stability and high durability.

A compound in an organic layer, particularly, a light-emitting layer, of an organic light-emitting device repeatedly undergoes transition between the ground state and an excited state during the process of light emission of the organic light-emitting device, particularly in the light emitting layer. In this process, strong molecular motions, such as stretching and rotation, occur. At this time, if there is a site where a bond readily dissociates, the bond may cleave to cause liberation of a portion of the compound. Liberation of a portion of the compound causes a change in structure. Thus, when the liberation occurs easily, the compound is less durable. In addition, when such a compound is used in an organic light-emitting device, the liberated portion serves as a quencher and impairs the device durability characteristics. Therefore, a molecule having a structure in which bond dissociation and liberation are less likely to occur provides better device durability characteristics.

In an organic layer during driving of an organic light-emitting device, part of applied electrical energy can be released in the form of thermal energy. When the thermal stability of a compound contained in the organic layer is low, the released thermal energy is liable to cause bond dissociation as described above. In addition, the released thermal energy can cause crystallization of an organic film. As described above, the formation of a quencher by, for example, dissociation of a bond and the crystallization of the organic layer lead to a deterioration in device durability characteristics. Therefore, the use of a compound having high thermal stability can improve the device durability characteristics.

Among the organic compounds represented by general formula [1-1] or [1-2], a greater number of sites where n is 1 in Q₁ to Q₆ or Q₇ to Q₁₀ result in a greater number of fused-ring structures, leading to better stability. A specific description will be given below.

When n is 1, even if the C—N bond between the nitrogen atom of the diazaborole derivative ring and the benzene ring bonded to the nitrogen atom is cleaved, the benzene ring after cleavage remains bonded to another structural moiety in the compound by the bond via Q₁ and the like. For example, when n of (Q), in formula [1-1] is 1, even if the C—N bond between the benzene ring having R₁₉ to R₂₂ and the nitrogen atom is cleaved, the benzene ring remains bonded to the benzene ring having R₁ to R₃ owing to the bond via Q₁. The benzene ring is not released after cleavage, but stays near the nitrogen atom to which the benzene ring was bonded before the C—N bond was cleaved, and is likely to bond again to return to the original structure. Therefore, as compared with the case where n is 0, liberation due to bond cleavage is less likely to occur, resulting in high durability.

A greater number of fused-ring structures formed by Q₁ and the like result in higher thermal stability in the form of a thin film. For example, such a compound has a high glass transition temperature.

From the above, in general formula [1-1], it is preferable that at least two of n be 1, and it is more preferable that at least four of n be 1. Similarly, in general formula [1-2], it is preferable that at least two of n be 1, and it is more preferable that four of n be 1, that is, all be fused rings.

When the compound having feature (3) is used in the organic layer of the organic light-emitting device, it is possible to inhibit liberation due to bond cleavage during the driving of the device. This can provide an organic light-emitting device that is less likely to deteriorate even when driven for a long period of time and that has excellent durability.

When n is 0, the C—N bond between the benzene ring and the nitrogen atom can freely rotate. When a greater number of C—N bonds that can rotate are contained, the molecular bulkiness is further improved. When such a compound is used as a guest of a light-emitting layer, concentration quenching in the form of a thin film can be further reduced.

### SPECIFIC EXAMPLES

Specific examples of the organic compound of the present embodiment are illustrated below. However, the present embodiment is not limited thereto.

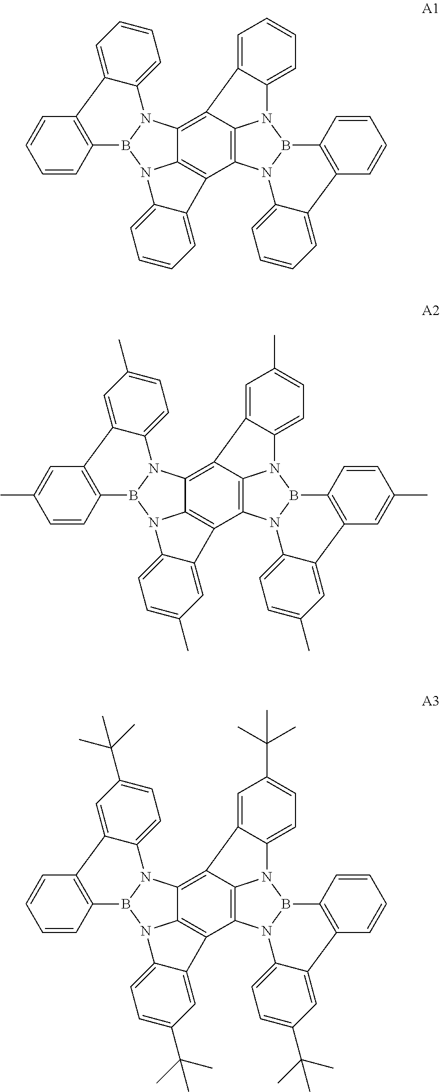

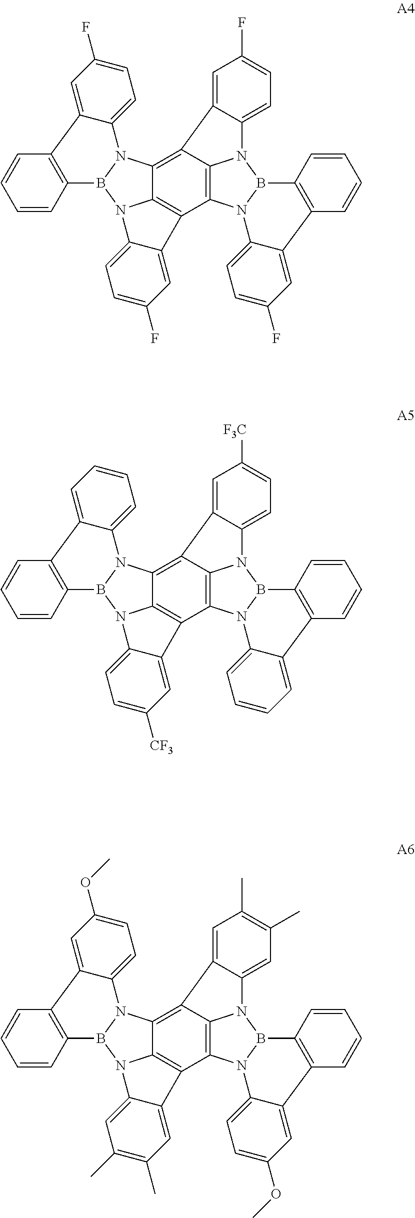 [SMILES: Fc1ccc2c(c1)-c1ccccc1B1N2c2c3c4cc(F)ccc4n4c3c(c3c5cc(F)ccc5n1c23)N1B4c2ccccc2-c2cc(F)ccc21 ; FC(F)(F)c1ccc2c(c1)c1c3c4c(c5c1n2B1c2ccccc2-c2ccccc2N15)c1cc(C(F)(F)F)ccc1n4B1c2ccccc2-c2ccccc2N13 ; COc1ccc2c(c1)-c1ccccc1B1N2c2c3c4cc(C)c(C)cc4n4c3c(c3c5cc(C)c(C)cc5n1c23)N1B4c2ccccc2-c2cc(OC)ccc21]

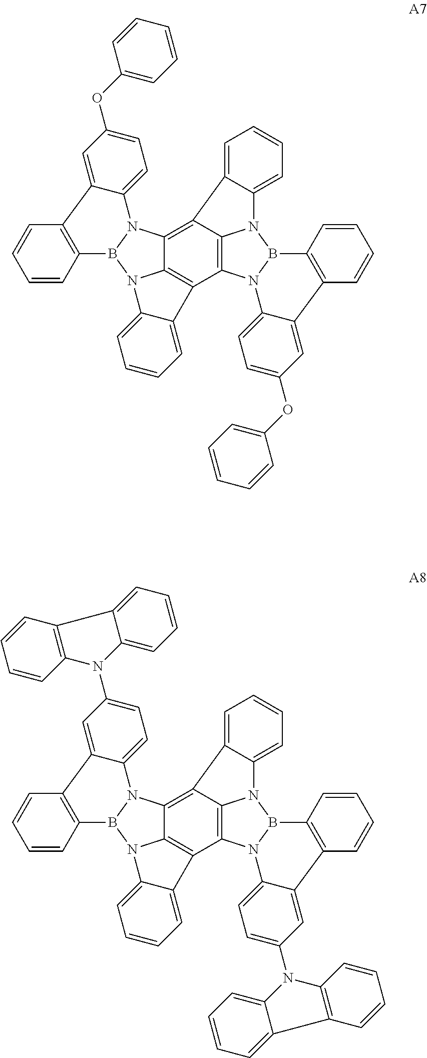 [SMILES: c1ccc(Oc2ccc3c(c2)-c2ccccc2B2N3c3c4c5ccccc5n5c4c(c4c6ccccc6n2c34)N2B5c3ccccc3-c3cc(Oc4ccccc4)ccc32)cc1 ; c1ccc2c(c1)B1N(c3ccc(-n4c5ccccc5c5ccccc54)cc3-2)c2c3c4ccccc4n4c3c(c3c5ccccc5n1c23)N1B4c2ccccc2-c2cc(-n3c4ccccc4c4ccccc43)ccc21]

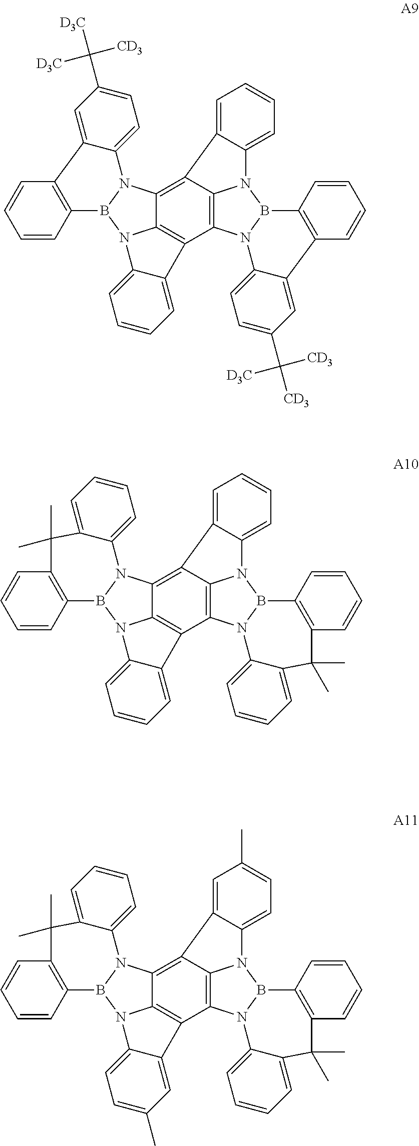 [SMILES: [2H]C([2H])([2H])C(c1ccc2c(c1)-c1ccccc1B1N2c2c3c4ccccc4n4c3c(c3c5ccccc5n1c23)N1B4c2ccccc2-c2cc(C(C([2H])([2H])[2H])(C([2H])([2H])[2H])C([2H])([2H])[2H])ccc21)(C([2H])([2H])[2H])C([2H])([2H])[2H] ; CC1(C)c2ccccc2B2N(c3ccccc31)c1c3c4ccccc4n4c3c(c3c5ccccc5n2c13)N1B4c2ccccc2C(C)(C)c2ccccc21 ; Cc1ccc2c(c1)c1c3c4c(c5c1n2B1c2ccccc2C(C)(C)c2ccccc2N15)c1cc(C)ccc1n4B1c2ccccc2C(C)(C)c2ccccc2N13]

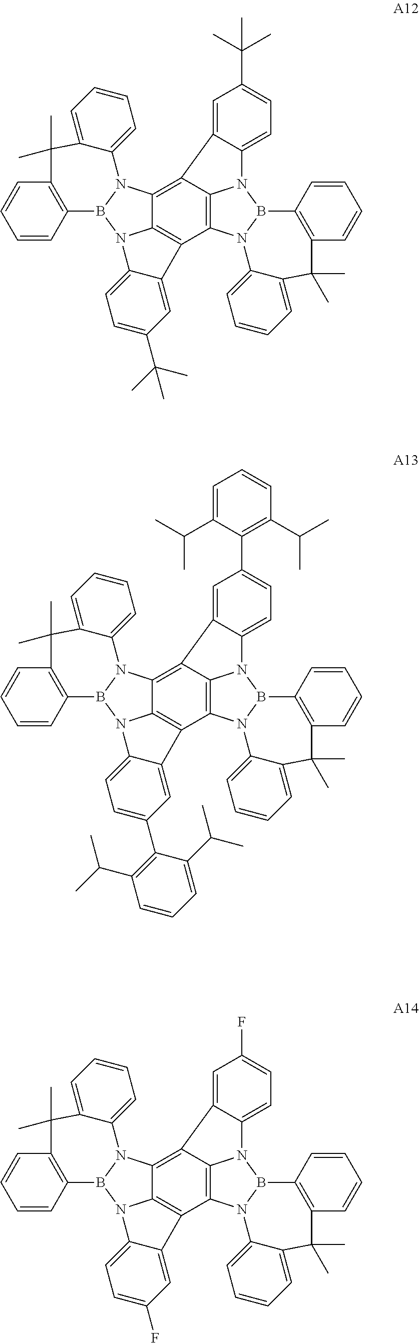 [SMILES: CC(C)(C)c1ccc2c(c1)c1c3c4c(c5c1n2B1c2ccccc2C(C)(C)c2ccccc2N15)c1cc(C(C)(C)C)ccc1n4B1c2ccccc2C(C)(C)c2ccccc2N13 ; CC(C)c1cccc(C(C)C)c1-c1ccc2c(c1)c1c3c4c(c5c1n2B1c2ccccc2C(C)(C)c2ccccc2N15)c1cc(-c2c(C(C)C)cccc2C(C)C)ccc1n4B1c2ccccc2C(C)(C)c2ccccc2N13 ; CC1(C)c2ccccc2B2N(c3ccccc31)c1c3c4cc(F)ccc4n4c3c(c3c5cc(F)ccc5n2c13)N1B4c2ccccc2C(C)(C)c2ccccc21]

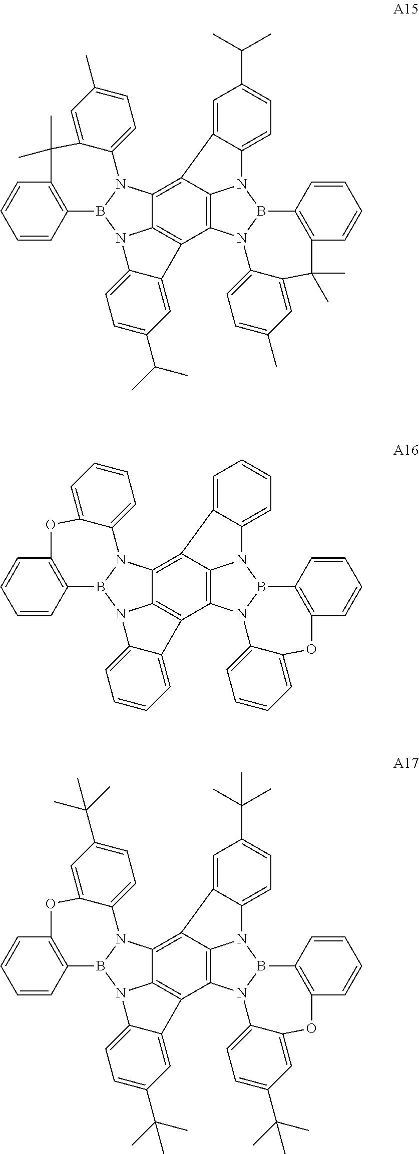 [SMILES: Cc1ccc2c(c1)C(C)(C)c1ccccc1B1N2c2c3c4cc(C(C)C)ccc4n4c3c(c3c5cc(C(C)C)ccc5n1c23)N1B4c2ccccc2C(C)(C)c2cc(C)ccc21 ; c1ccc2c(c1)Oc1ccccc1N1B2n2c3ccccc3c3c4c5c(c1c32)c1ccccc1n5B1c2ccccc2Oc2ccccc2N14 ; CC(C)(C)c1ccc2c(c1)Oc1ccccc1B1N2c2c3c4cc(C(C)(C)C)ccc4n4c3c(c3c5cc(C(C)(C)C)ccc5n1c23)N1B4c2ccccc2Oc2cc(C(C)(C)C)ccc21]

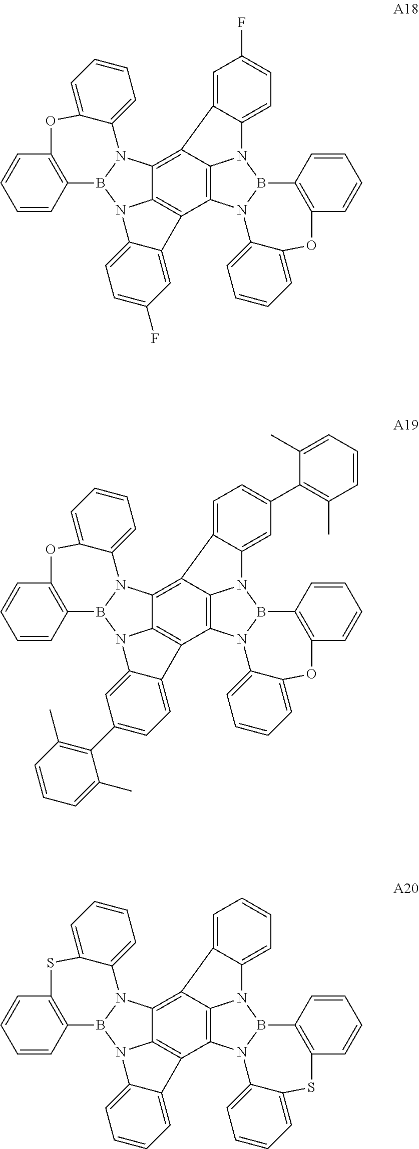 [SMILES: Fc1ccc2c(c1)c1c3c4c(c5c1n2B1c2ccccc2Oc2ccccc2N15)c1cc(F)ccc1n4B1c2ccccc2Oc2ccccc2N13 ; Cc1cccc(C)c1-c1ccc2c3c4c5c(c6c3n(c2c1)B1c2ccccc2Oc2ccccc2N16)c1ccc(-c2c(C)cccc2C)cc1n5B1c2ccccc2Oc2ccccc2N14 ; c1ccc2c(c1)Sc1ccccc1N1B2n2c3ccccc3c3c4c5c(c1c32)c1ccccc1n5B1c2ccccc2Sc2ccccc2N14]

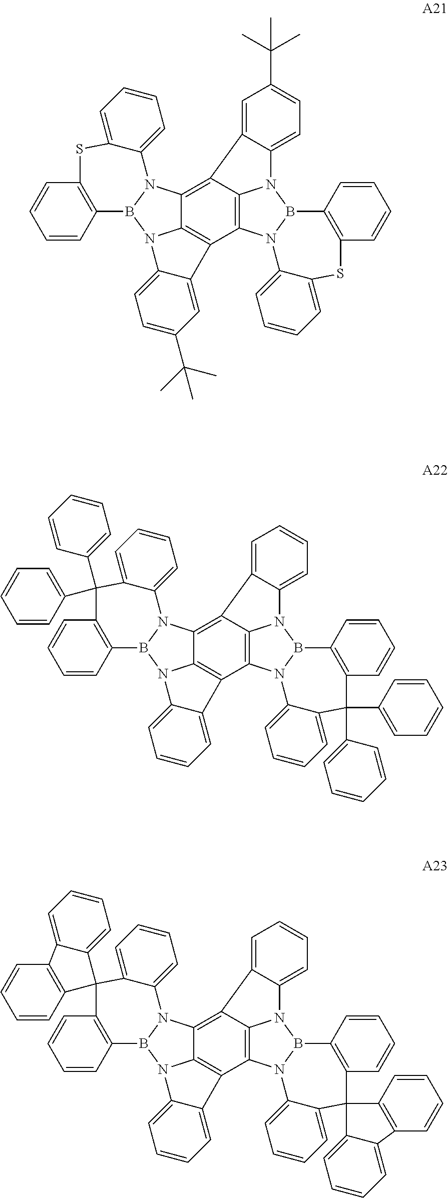 [SMILES: CC(C)(C)c1ccc2c(c1)c1c3c4c(c5c1n2B1c2ccccc2Sc2ccccc2N15)c1cc(C(C)(C)C)ccc1n4B1c2ccccc2Sc2ccccc2N13 ; c1ccc(C2(c3ccccc3)c3ccccc3B3N(c4ccccc42)c2c4c5ccccc5n5c4c(c4c6ccccc6n3c24)N2B5c3ccccc3C(c3ccccc3)(c3ccccc3)c3ccccc32)cc1 ; c1ccc2c(c1)B1N(c3ccccc3C23c2ccccc2-c2ccccc23)c2c3c4ccccc4n4c3c(c3c5ccccc5n1c23)N1B4c2ccccc2C2(c3ccccc3-c3ccccc32)c2ccccc21]

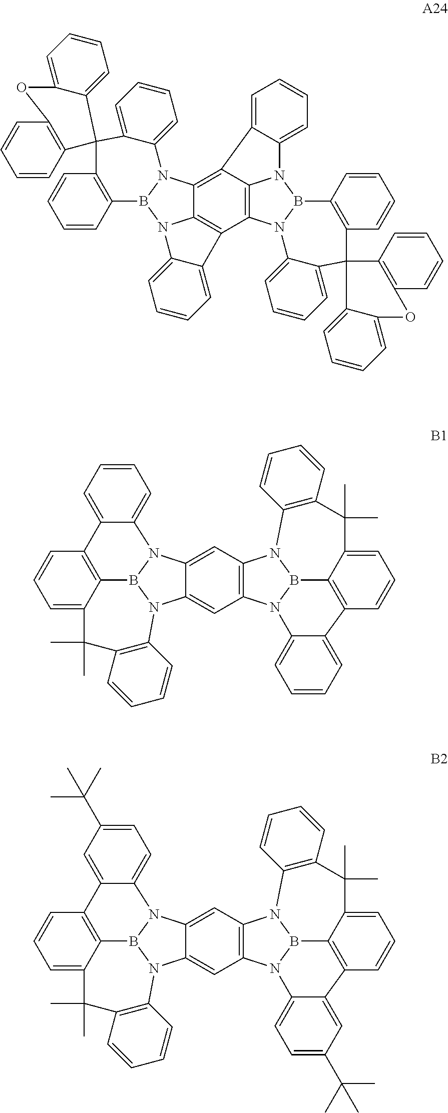 [SMILES: c1ccc2c(c1)Oc1ccccc1C21c2ccccc2B2N(c3ccccc31)c1c3c4ccccc4n4c3c(c3c5ccccc5n2c13)N1B4c2ccccc2C2(c3ccccc3Oc3ccccc32)c2ccccc21 ; CC1(C)c2ccccc2N2B3c4c(cccc41)-c1ccccc1N3c1cc3c(cc12)N1B2c4c(cccc4C(C)(C)c4ccccc4N23)-c2ccccc21 ; CC(C)(C)c1ccc2c(c1)-c1cccc3c1B1N2c2cc4c(cc2N1c1ccccc1C3(C)C)N1B2c3c(cccc3C(C)(C)c3ccccc3N24)-c2cc(C(C)(C)C)ccc21]

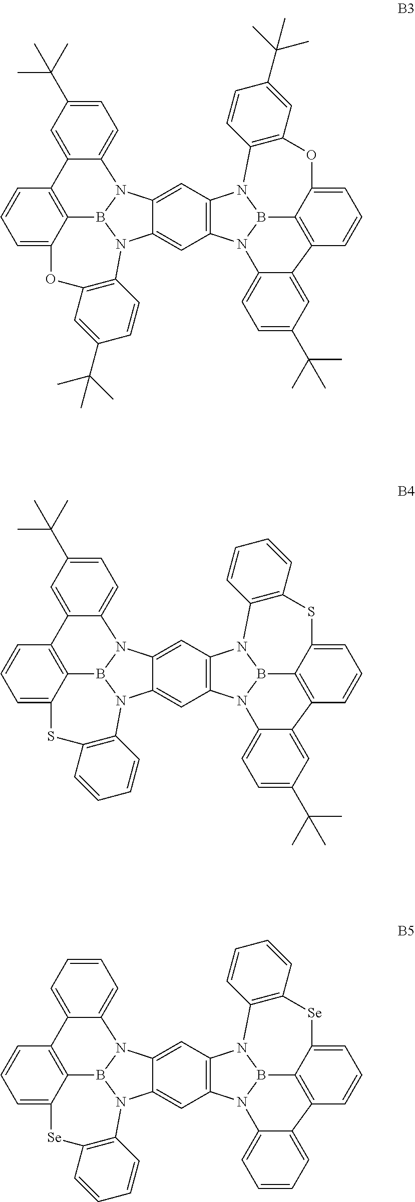 [SMILES: CC(C)(C)c1ccc2c(c1)Oc1cccc3c1B1N2c2cc4c(cc2N1c1ccc(C(C)(C)C)cc1-3)N1B2c3c(cccc3-c3cc(C(C)(C)C)ccc3N24)Oc2cc(C(C)(C)C)ccc21 ; CC(C)(C)c1ccc2c(c1)-c1cccc3c1B1N(c4ccccc4S3)c3cc4c(cc3N12)N1B2c3c(cccc3-c3cc(C(C)(C)C)ccc3N24)Sc2ccccc21 ; c1ccc2c(c1)[Se]c1cccc3c1B1N2c2cc4c(cc2N1c1ccccc1-3)N1B2c3c(cccc3-c3ccccc3N24)[Se]c2ccccc21]

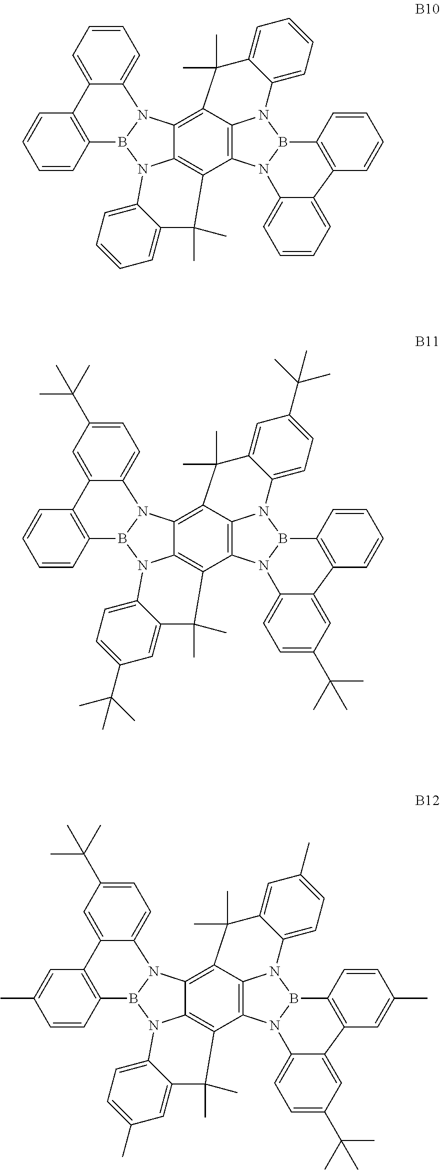

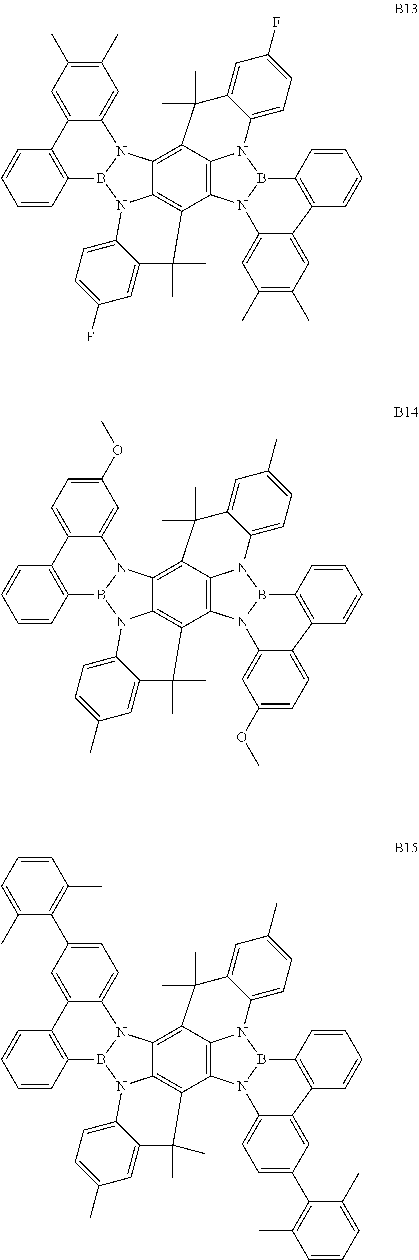 [SMILES: Cc1cc2c(cc1C)N1B(c3ccccc3-2)N2c3ccc(F)cc3C(C)(C)c3c4c5c(c1c32)C(C)(C)c1cc(F)ccc1N5B1c2ccccc2-c2cc(C)c(C)cc2N14 ; COc1ccc2c(c1)N1B(c3ccccc3-2)N2c3ccc(C)cc3C(C)(C)c3c4c5c(c1c32)C(C)(C)c1cc(C)ccc1N5B1c2ccccc2-c2ccc(OC)cc2N14 ; Cc1ccc2c(c1)C(C)(C)c1c3c4c(c5c1N2B1c2ccccc2-c2cc(-c6c(C)cccc6C)ccc2N15)C(C)(C)c1cc(C)ccc1N4B1c2ccccc2-c2cc(-c4c(C)cccc4C)ccc2N13]

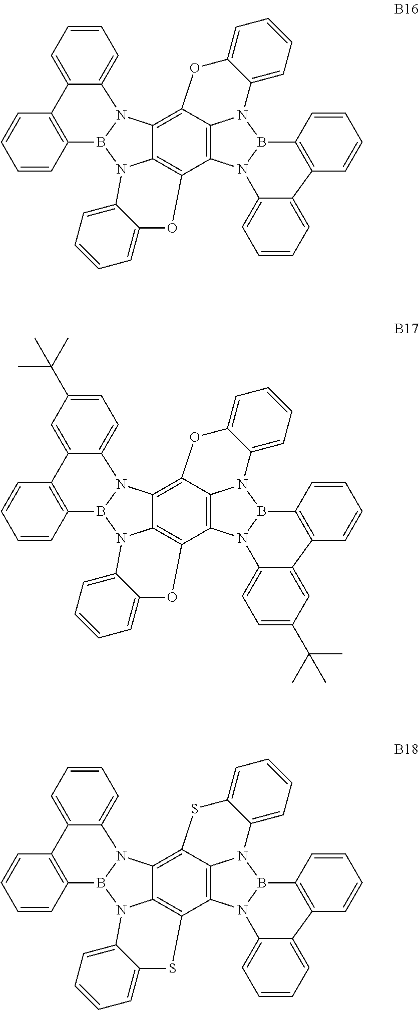 [SMILES: c1ccc2c(c1)B1N(c3ccccc3-2)c2c3oc4ccccc4n4c3c(c3oc5ccccc5n1c23)N1B4c2ccccc2-c2ccccc21 ; CC(C)(C)c1ccc2c(c1)-c1ccccc1B1N2c2c3oc4ccccc4n4c3c(c3oc5ccccc5n1c23)N1B4c2ccccc2-c2cc(C(C)(C)C)ccc21 ; c1ccc2c(c1)B1N(c3ccccc3-2)c2c3sc4ccccc4n4c3c(c3sc5ccccc5n1c23)N1B4c2ccccc2-c2ccccc21]

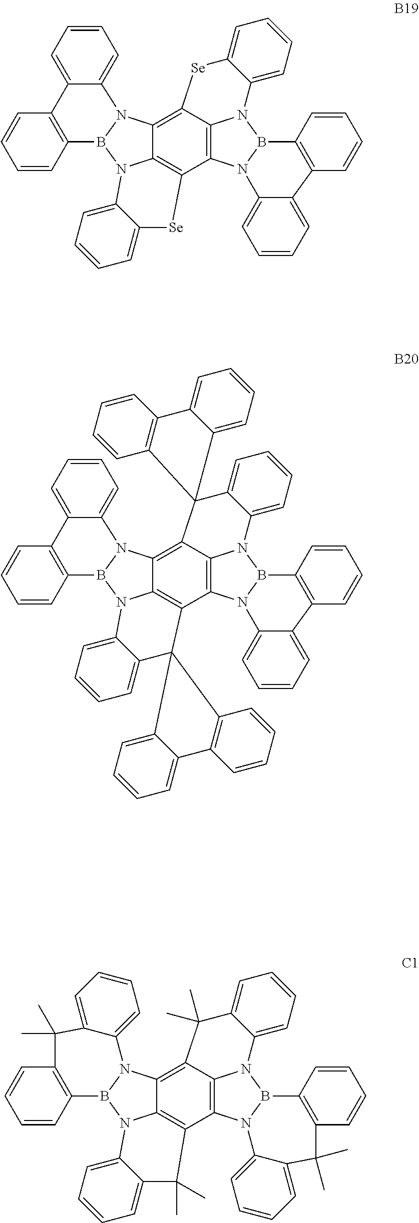 [SMILES: c1ccc2c(c1)B1N(c3ccccc3-2)c2c3[se]c4ccccc4n4c3c(c3[se]c5ccccc5n1c23)N1B4c2ccccc2-c2ccccc21 ; c1ccc2c(c1)B1N(c3ccccc3-2)c2c3c(c4c5c2C2(c6ccccc6-c6ccccc62)c2ccccc2N5B2c5ccccc5-c5ccccc5N24)C2(c4ccccc4-c4ccccc42)c2ccccc2N13 ; CC1(C)c2ccccc2B2N(c3ccccc31)c1c3c(c4c5c1C(C)(C)c1ccccc1N5B1c5ccccc5C(C)(C)c5ccccc5N14)C(C)(C)c1ccccc1N23]

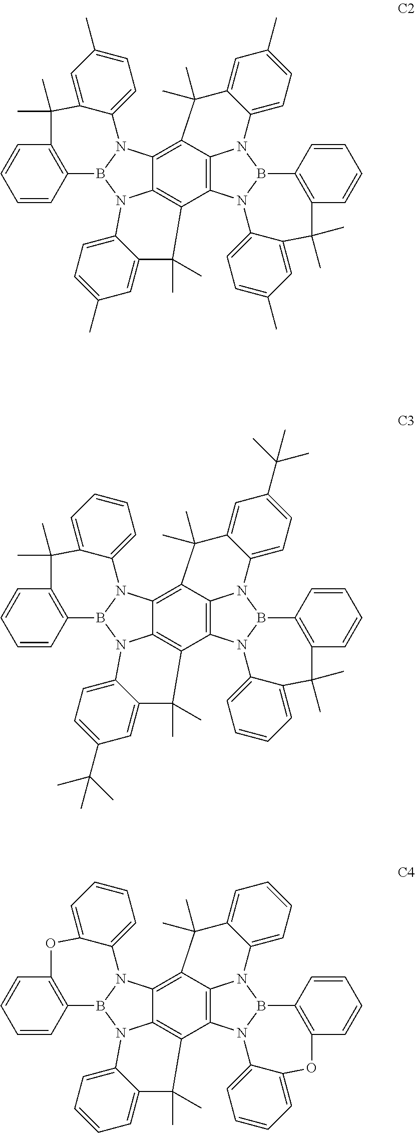 [SMILES: Cc1ccc2c(c1)C(C)(C)c1ccccc1B1N2c2c3c(c4c5c2C(C)(C)c2cc(C)ccc2N5B2c5ccccc5C(C)(C)c5cc(C)ccc5N24)C(C)(C)c2cc(C)ccc2N13 ; CC(C)(C)c1ccc2c(c1)C(C)(C)c1c3c4c(c5c1N2B1c2ccccc2C(C)(C)c2ccccc2N15)C(C)(C)c1cc(C(C)(C)C)ccc1N4B1c2ccccc2C(C)(C)c2ccccc2N13 ; CC1(C)c2ccccc2N2B3c4ccccc4Oc4ccccc4N3c3c2c1c1c2c3C(C)(C)c3ccccc3N2B2c3ccccc3Oc3ccccc3N21]

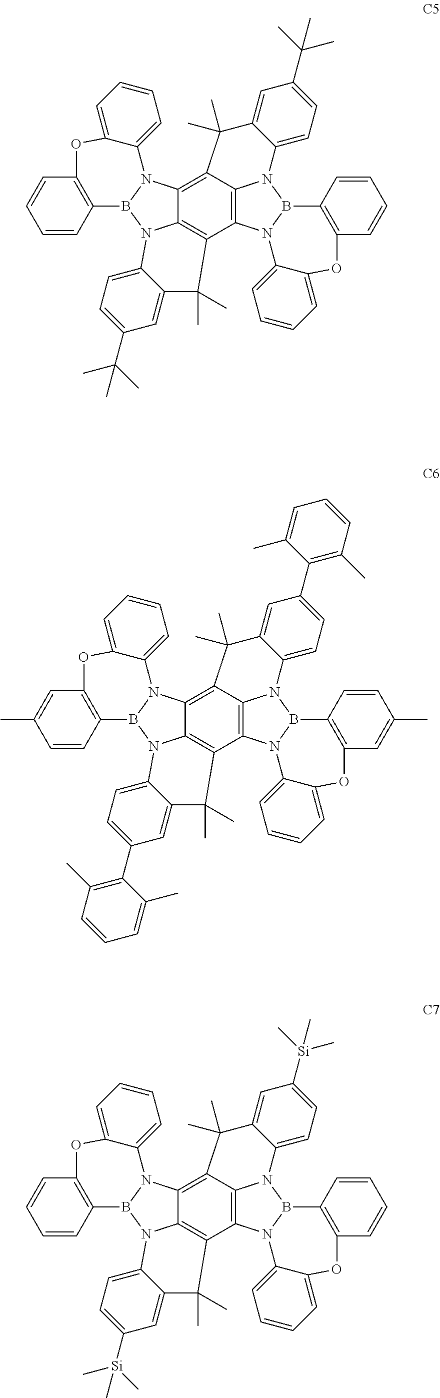

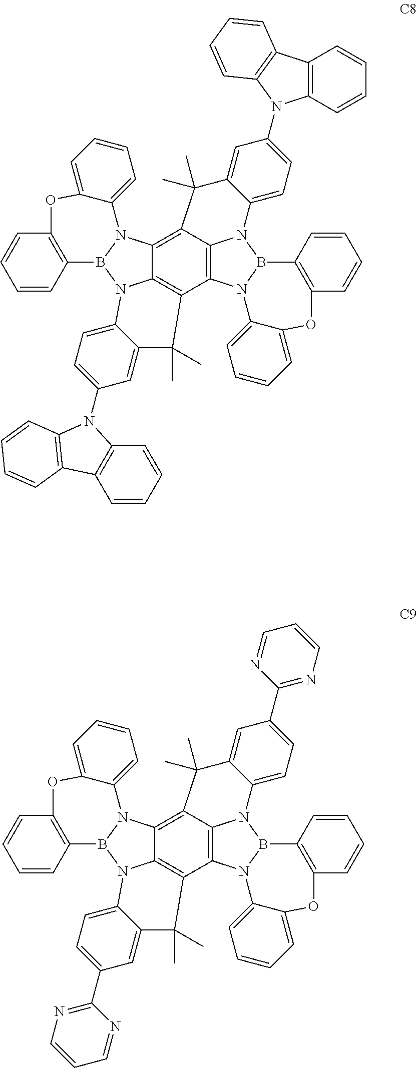 [SMILES: CC1(C)c2cc(-n3c4ccccc4c4ccccc43)ccc2N2B3c4ccccc4Oc4ccccc4N3c3c2c1c1c2c3C(C)(C)c3cc(-n4c5ccccc5c5ccccc54)ccc3N2B2c3ccccc3Oc3ccccc3N21 ; CC1(C)c2cc(-c3ncccn3)ccc2N2B3c4ccccc4Oc4ccccc4N3c3c2c1c1c2c3C(C)(C)c3cc(-c4ncccn4)ccc3N2B2c3ccccc3Oc3ccccc3N21]

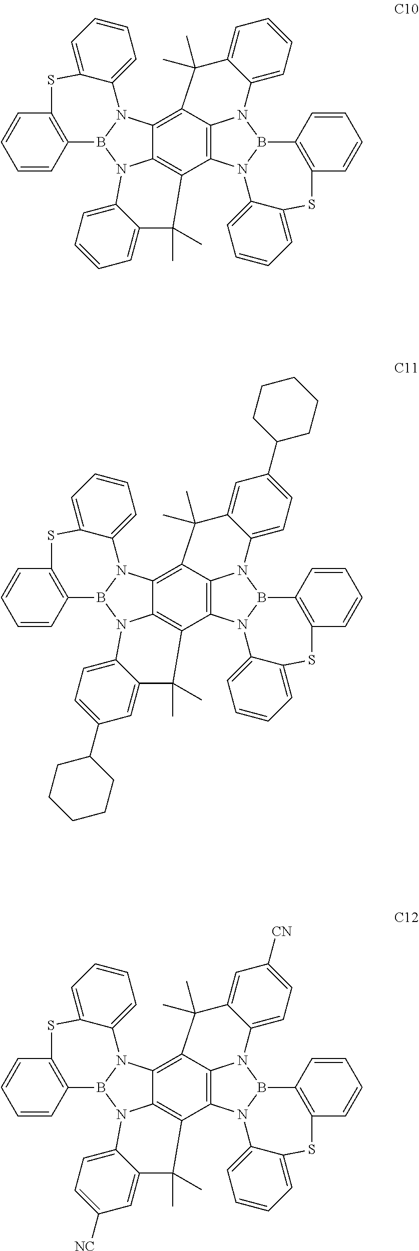 [SMILES: CC1(C)c2ccccc2N2B3c4ccccc4Sc4ccccc4N3c3c2c1c1c2c3C(C)(C)c3ccccc3N2B2c3ccccc3Sc3ccccc3N21 ; CC1(C)c2cc(C3CCCCC3)ccc2N2B3c4ccccc4Sc4ccccc4N3c3c2c1c1c2c3C(C)(C)c3cc(C4CCCCC4)ccc3N2B2c3ccccc3Sc3ccccc3N21 ; CC1(C)c2cc(C#N)ccc2N2B3c4ccccc4Sc4ccccc4N3c3c2c1c1c2c3C(C)(C)c3cc(C#N)ccc3N2B2c3ccccc3Sc3ccccc3N21]

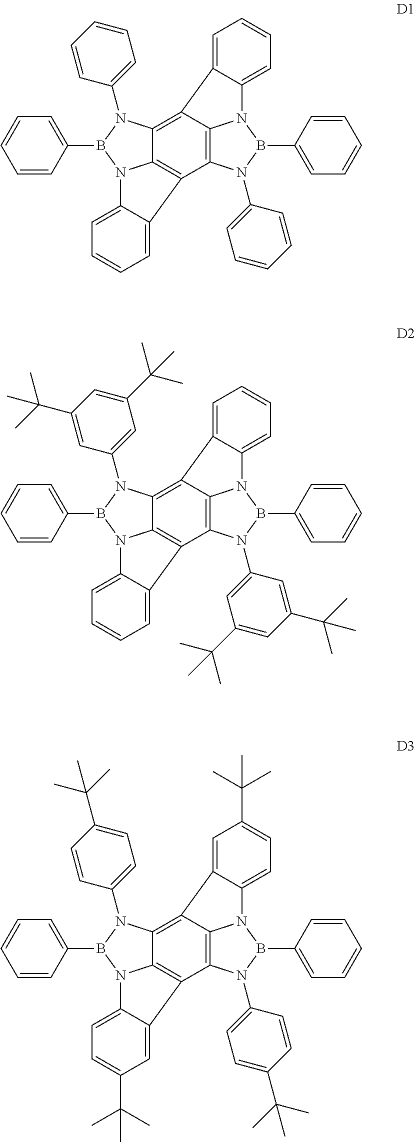 [SMILES: c1ccc(B2N(c3ccccc3)c3c4c5ccccc5n5c4c(c4c6ccccc6n2c34)N(c2ccccc2)B5c2ccccc2)cc1 ; CC(C)(C)c1cc(N2B(c3ccccc3)n3c4ccccc4c4c5c6c(c2c43)c2ccccc2n6B(c2ccccc2)N5c2cc(C(C)(C)C)cc(C(C)(C)C)c2)cc(C(C)(C)C)c1 ; CC(C)(C)c1ccc(N2B(c3ccccc3)n3c4ccc(C(C)(C)C)cc4c4c5c6c(c2c43)c2cc(C(C)(C)C)ccc2n6B(c2ccccc2)N5c2ccc(C(C)(C)C)cc2)cc1]

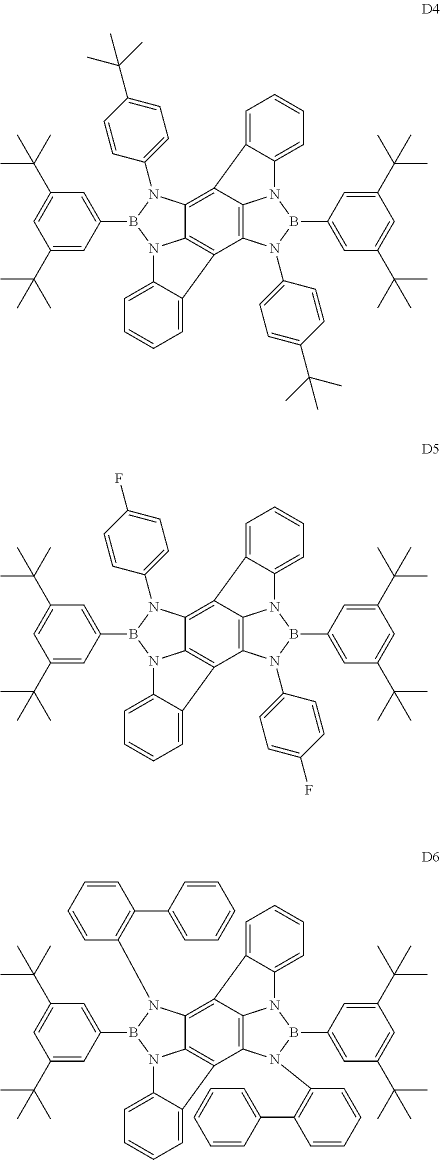

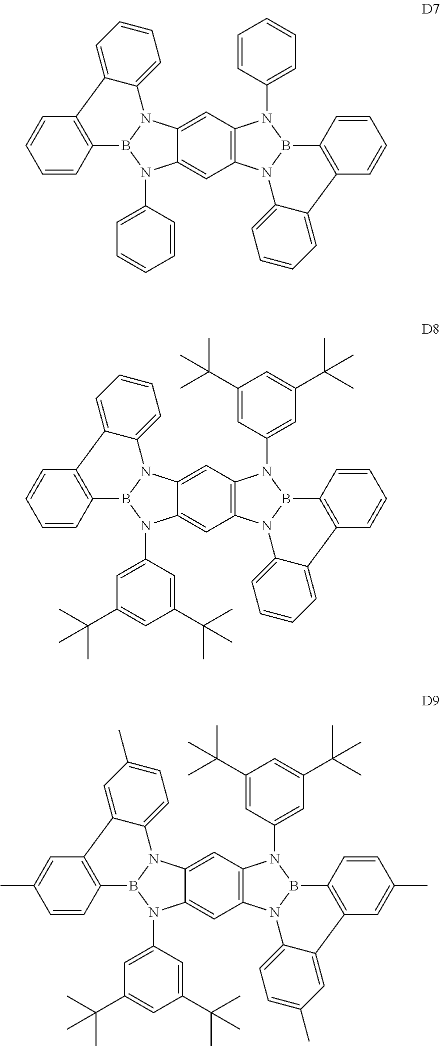

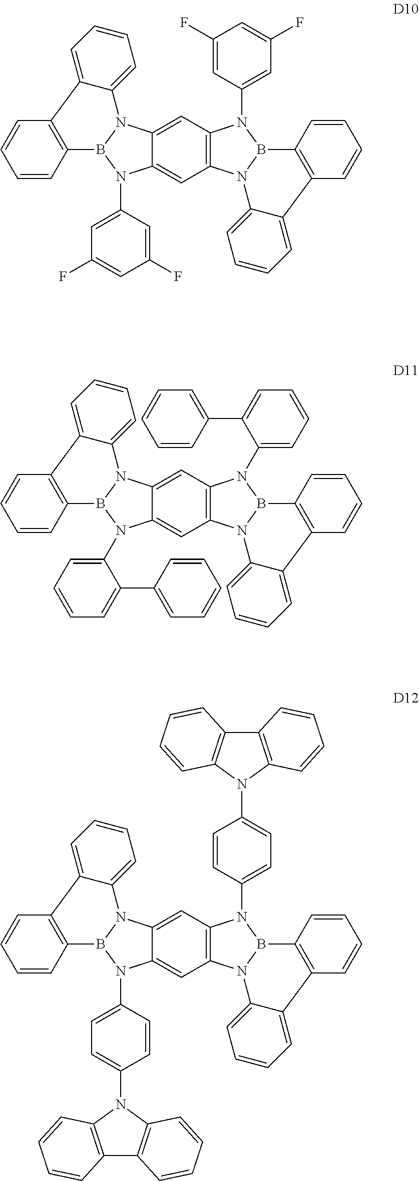 [SMILES: Fc1cc(F)cc(N2B3c4ccccc4-c4ccccc4N3c3cc4c(cc32)N2B(c3ccccc3-c3ccccc32)N4c2cc(F)cc(F)c2)c1 ; c1ccc(-c2ccccc2N2B3c4ccccc4-c4ccccc4N3c3cc4c(cc32)N2B(c3ccccc3-c3ccccc32)N4c2ccccc2-c2ccccc2)cc1 ; c1ccc2c(c1)B1N(c3ccc(-n4c5ccccc5c5ccccc54)cc3)c3cc4c(cc3N1c1ccccc1-2)N(c1ccc(-n2c3ccccc3c3ccccc32)cc1)B1c2ccccc2-c2ccccc2N14]

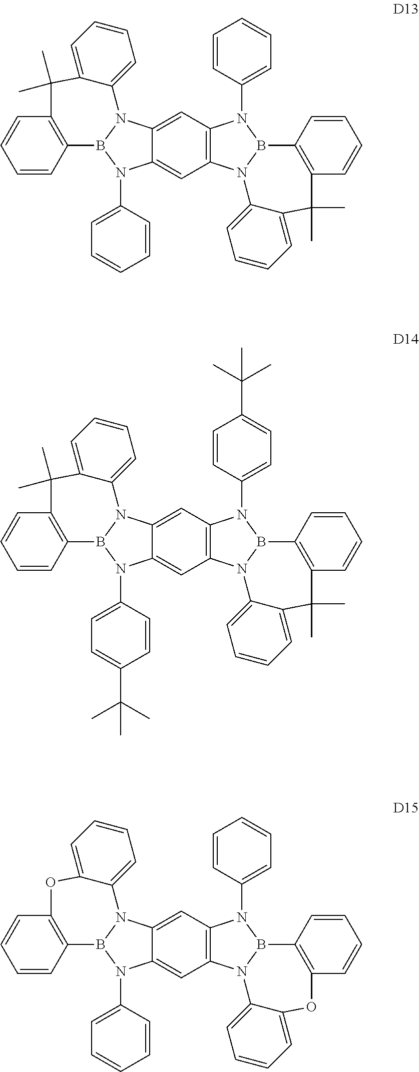 [SMILES: CC1(C)c2ccccc2B2N(c3ccccc3)c3cc4c(cc3N2c2ccccc21)N(c1ccccc1)B1c2ccccc2C(C)(C)c2ccccc2N14 ; CC(C)(C)c1ccc(N2B3c4ccccc4C(C)(C)c4ccccc4N3c3cc4c(cc32)N2B(c3ccccc3C(C)(C)c3ccccc32)N4c2ccc(C(C)(C)C)cc2)cc1 ; c1ccc(N2B3c4ccccc4Oc4ccccc4N3c3cc4c(cc32)N2B(c3ccccc3Oc3ccccc32)N4c2ccccc2)cc1]

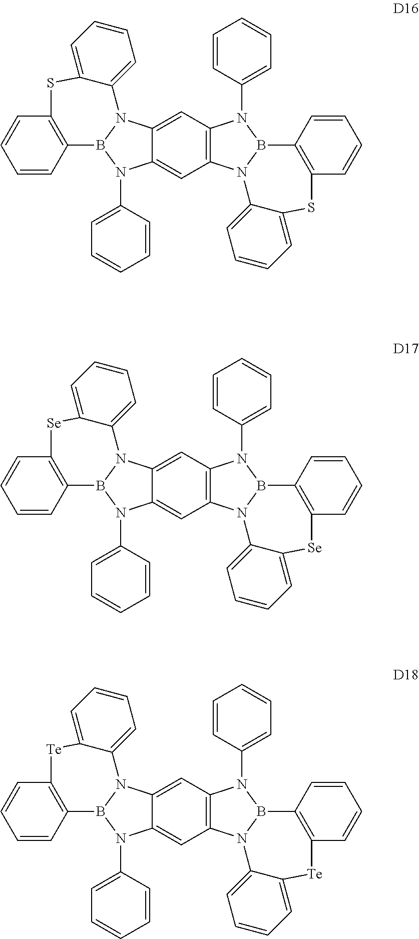

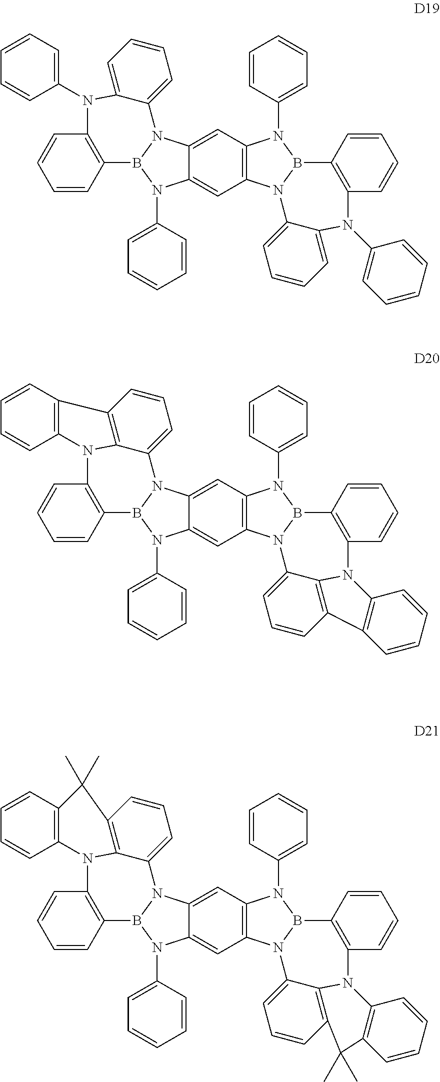 [SMILES: c1ccc(N2B3c4ccccc4N(c4ccccc4)c4ccccc4N3c3cc4c(cc32)N2B(c3ccccc3N(c3ccccc3)c3ccccc32)N4c2ccccc2)cc1 ; c1ccc(N2B3c4ccccc4-n4c5ccccc5c5cccc(c54)N3c3cc4c(cc32)N2B(c3ccccc3-n3c5ccccc5c5cccc2c53)N4c2ccccc2)cc1 ; CC1(C)c2ccccc2N2c3ccccc3B3N(c4ccccc4)c4cc5c(cc4N3c3cccc1c32)N(c1ccccc1)B1c2ccccc2N2c3ccccc3C(C)(C)c3cccc(c32)N15]

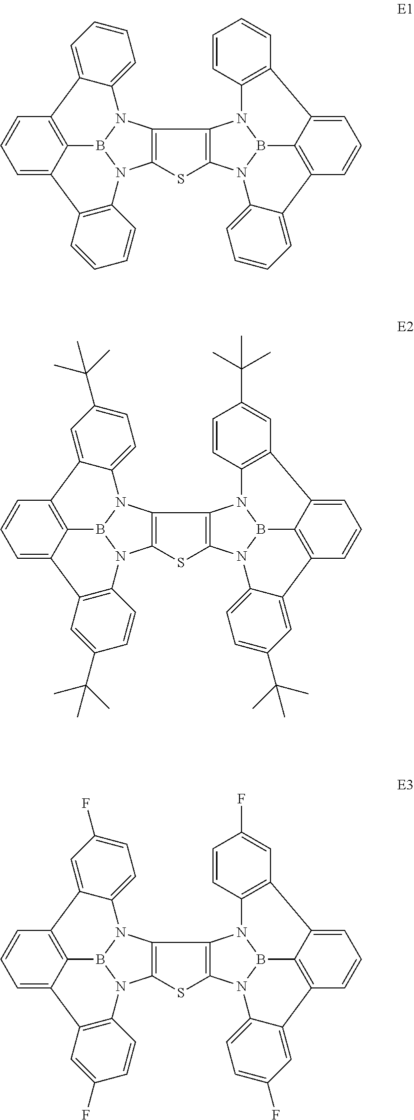 [SMILES: c1ccc2c(c1)-c1cccc3c1B1N2c2sc4c(c2N1c1ccccc1-3)N1B2c3c(cccc3-c3ccccc31)-c1ccccc1N24 ; CC(C)(C)c1ccc2c(c1)-c1cccc3c1B1N2c2sc4c(c2N1c1ccc(C(C)(C)C)cc1-3)N1B2c3c(cccc3-c3cc(C(C)(C)C)ccc31)-c1cc(C(C)(C)C)ccc1N24 ; Fc1ccc2c(c1)-c1cccc3c1B1N2c2sc4c(c2N1c1ccc(F)cc1-3)N1B2c3c(cccc3-c3cc(F)ccc31)-c1cc(F)ccc1N24]

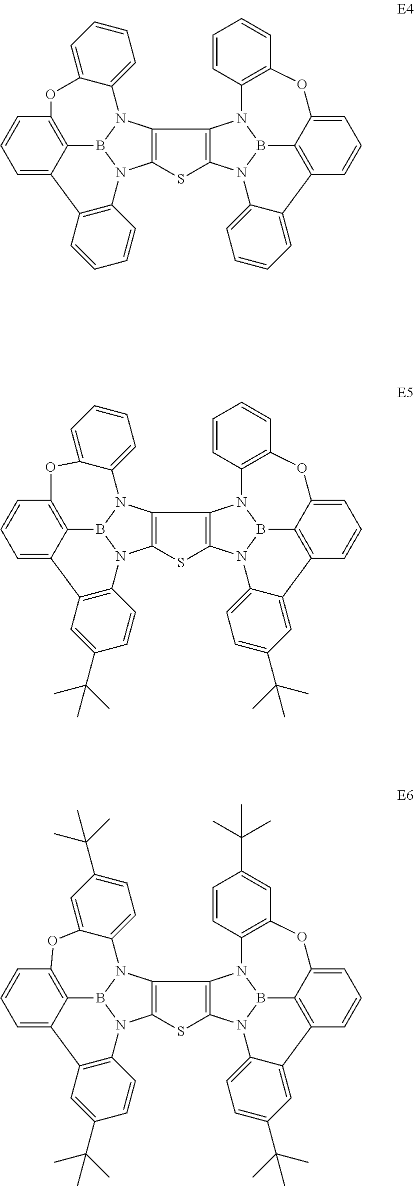 [SMILES: c1ccc2c(c1)Oc1cccc3c1B1N(c4ccccc4-3)c3sc4c(c3N12)N1B2c3c(cccc3-c3ccccc3N24)Oc2ccccc21 ; CC(C)(C)c1ccc2c(c1)-c1cccc3c1B1N2c2sc4c(c2N1c1ccccc1O3)N1B2c3c(cccc3-c3cc(C(C)(C)C)ccc3N24)Oc2ccccc21 ; CC(C)(C)c1ccc2c(c1)Oc1cccc3c1B1N(c4ccc(C(C)(C)C)cc4-3)c3sc4c(c3N12)N1B2c3c(cccc3-c3cc(C(C)(C)C)ccc3N24)Oc2cc(C(C)(C)C)ccc21]

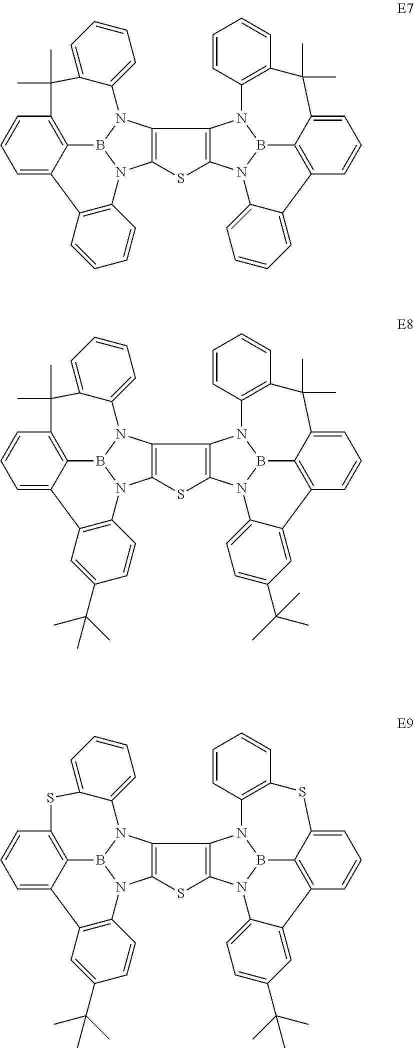 [SMILES: CC1(C)c2ccccc2N2B3c4c(cccc41)-c1ccccc1N3c1sc3c(c12)N1B2c4c(cccc4C(C)(C)c4ccccc41)-c1ccccc1N23 ; CC(C)(C)c1ccc2c(c1)-c1cccc3c1B1N2c2sc4c(c2N1c1ccccc1C3(C)C)N1B2c3c(cccc3C(C)(C)c3ccccc31)-c1cc(C(C)(C)C)ccc1N24 ; CC(C)(C)c1ccc2c(c1)-c1cccc3c1B1N2c2sc4c(c2N1c1ccccc1S3)N1B2c3c(cccc3-c3cc(C(C)(C)C)ccc3N24)Sc2ccccc21]

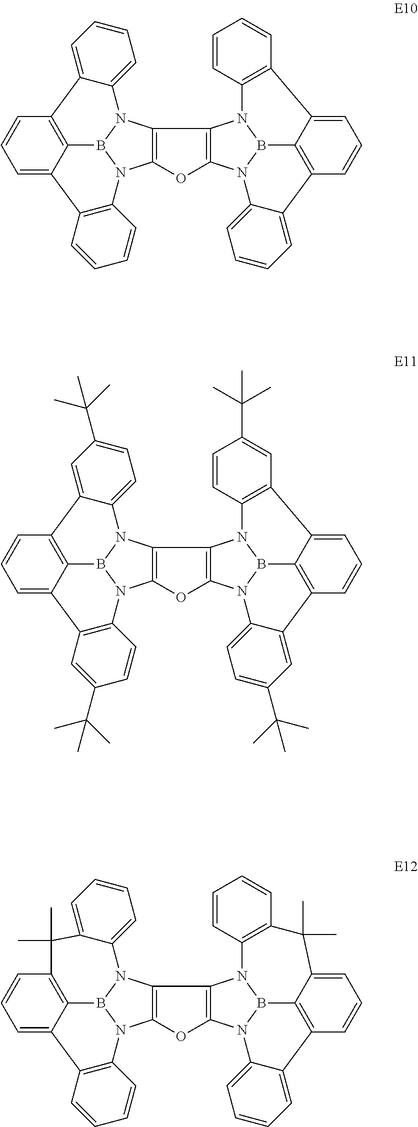 [SMILES: c1ccc2c(c1)-c1cccc3c1B1N2c2oc4c(c2N1c1ccccc1-3)N1B2c3c(cccc3-c3ccccc31)-c1ccccc1N24 ; CC(C)(C)c1ccc2c(c1)-c1cccc3c1B1N2c2oc4c(c2N1c1ccc(C(C)(C)C)cc1-3)N1B2c3c(cccc3-c3cc(C(C)(C)C)ccc31)-c1cc(C(C)(C)C)ccc1N24 ; CC1(C)c2ccccc2N2B3c4c(cccc41)-c1ccccc1N3c1oc3c(c12)N1B2c4c(cccc4C(C)(C)c4ccccc41)-c1ccccc1N23]

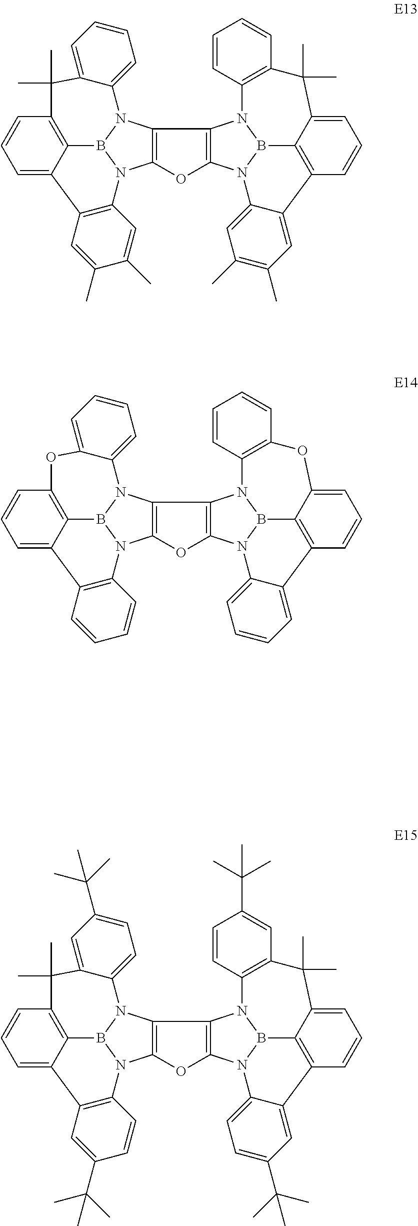 [SMILES: Cc1cc2c(cc1C)N1B3c4c-2cccc4C(C)(C)c2ccccc2N3c2c1oc1c2N2B3c4c(cccc4C(C)(C)c4ccccc42)-c2cc(C)c(C)cc2N31 ; c1ccc2c(c1)Oc1cccc3c1B1N(c4ccccc4-3)c3oc4c(c3N12)N1B2c3c(cccc3-c3ccccc3N24)Oc2ccccc21 ; CC(C)(C)c1ccc2c(c1)-c1cccc3c1B1N2c2oc4c(c2N1c1ccc(C(C)(C)C)cc1C3(C)C)N1B2c3c(cccc3C(C)(C)c3cc(C(C)(C)C)ccc31)-c1cc(C(C)(C)C)ccc1N24]

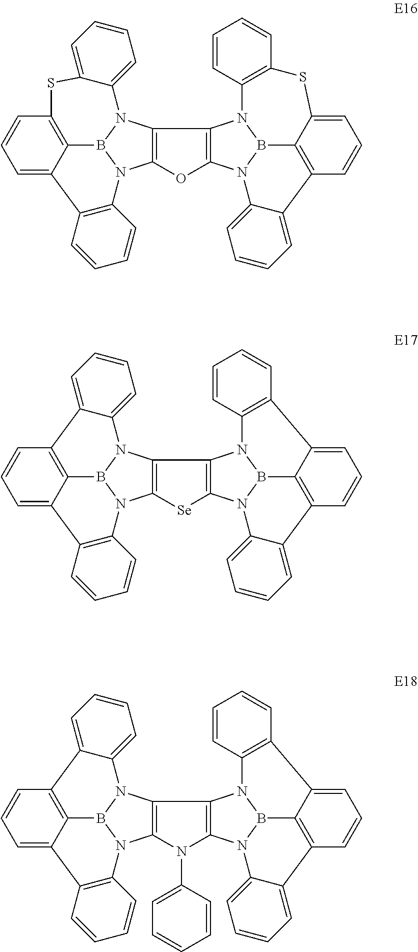 [SMILES: c1ccc2c(c1)Sc1cccc3c1B1N(c4ccccc4-3)c3oc4c(c3N12)N1B2c3c(cccc3-c3ccccc3N24)Sc2ccccc21 ; c1ccc2c(c1)-c1cccc3c1B1N2c2[se]c4c(c2N1c1ccccc1-3)N1B2c3c(cccc3-c3ccccc31)-c1ccccc1N24 ; c1ccc(-n2c3c(c4c2N2B5c6c(cccc6-c6ccccc62)-c2ccccc2N54)N2B4c5c(cccc5-c5ccccc5N43)-c3ccccc32)cc1]

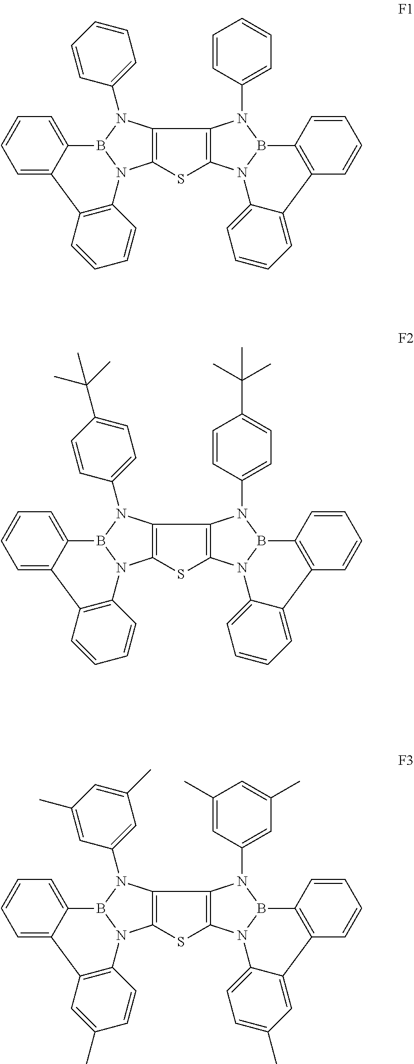 [SMILES: c1ccc(N2B3c4ccccc4-c4ccccc4N3c3sc4c(c32)N(c2ccccc2)B2c3ccccc3-c3ccccc3N24)cc1 ; CC(C)(C)c1ccc(N2B3c4ccccc4-c4ccccc4N3c3sc4c(c32)N(c2ccc(C(C)(C)C)cc2)B2c3ccccc3-c3ccccc3N24)cc1 ; Cc1cc(C)cc(N2B3c4ccccc4-c4cc(C)ccc4N3c3sc4c(c32)N(c2cc(C)cc(C)c2)B2c3ccccc3-c3cc(C)ccc3N24)c1]

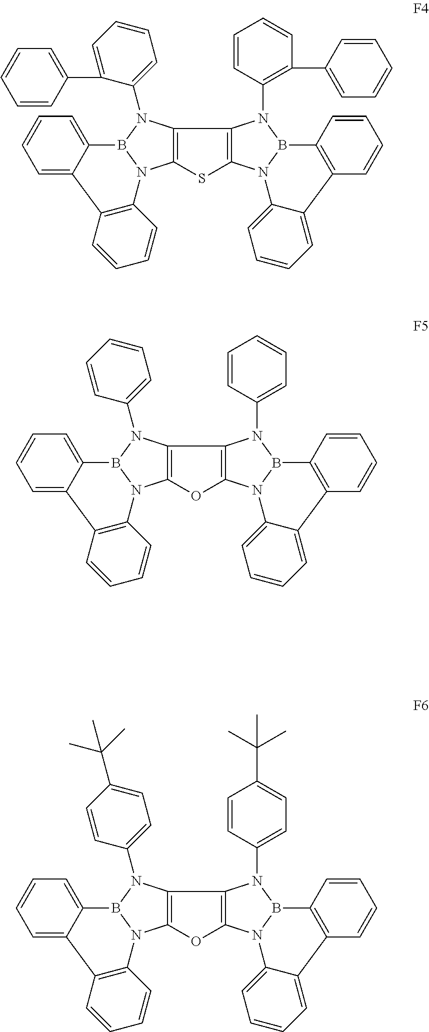 [SMILES: c1ccc(-c2ccccc2N2B3c4ccccc4-c4ccccc4N3c3sc4c(c32)N(c2ccccc2-c2ccccc2)B2c3ccccc3-c3ccccc3N24)cc1 ; c1ccc(N2B3c4ccccc4-c4ccccc4N3c3oc4c(c32)N(c2ccccc2)B2c3ccccc3-c3ccccc3N24)cc1 ; CC(C)(C)c1ccc(N2B3c4ccccc4-c4ccccc4N3c3oc4c(c32)N(c2ccc(C(C)(C)C)cc2)B2c3ccccc3-c3ccccc3N24)cc1]

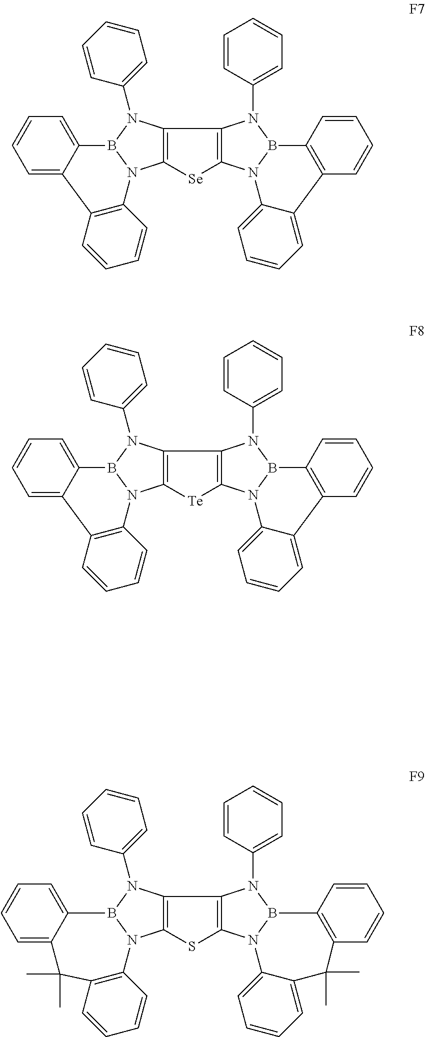

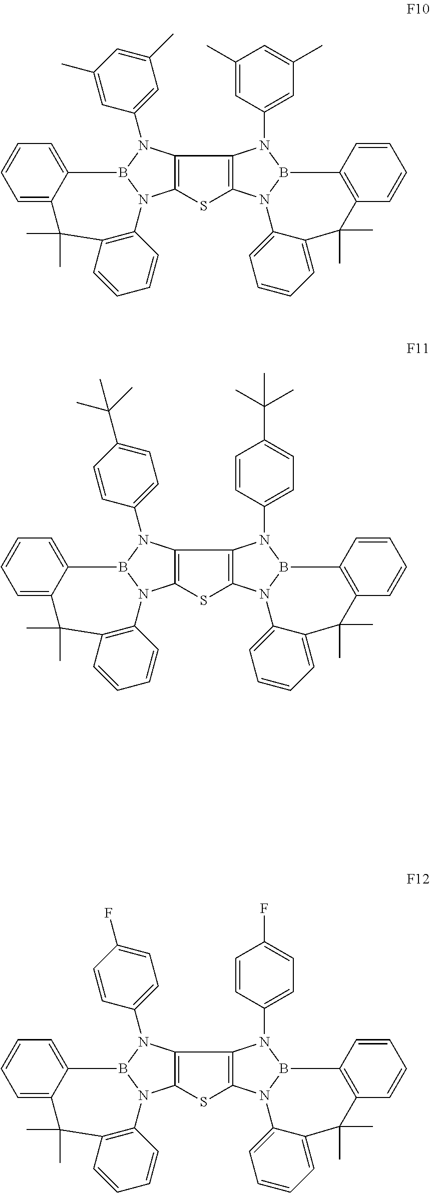 [SMILES: Cc1cc(C)cc(N2B3c4ccccc4C(C)(C)c4ccccc4N3c3sc4c(c32)N(c2cc(C)cc(C)c2)B2c3ccccc3C(C)(C)c3ccccc3N24)c1 ; CC(C)(C)c1ccc(N2B3c4ccccc4C(C)(C)c4ccccc4N3c3sc4c(c32)N(c2ccc(C(C)(C)C)cc2)B2c3ccccc3C(C)(C)c3ccccc3N24)cc1 ; CC1(C)c2ccccc2B2N(c3ccccc31)c1sc3c(c1N2c1ccc(F)cc1)N(c1ccc(F)cc1)B1c2ccccc2C(C)(C)c2ccccc2N13]

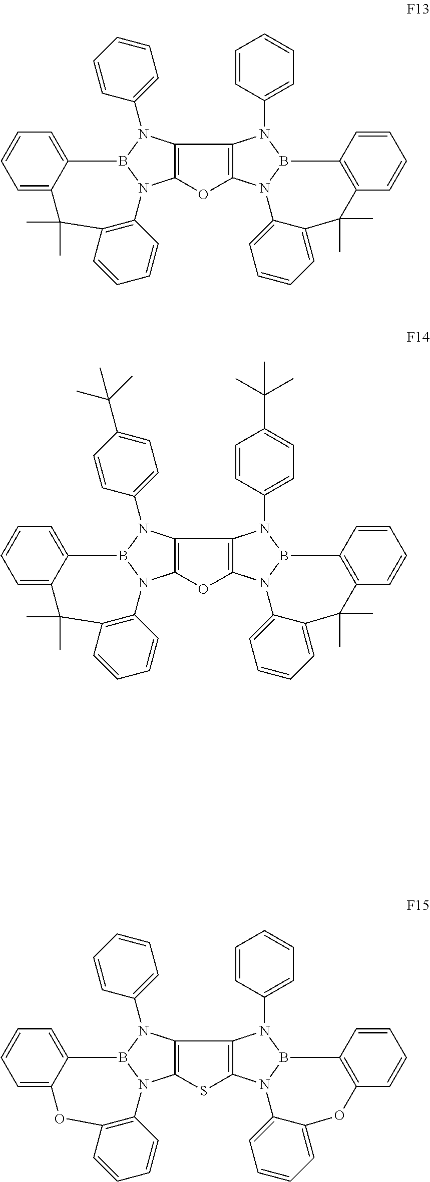 [SMILES: CC1(C)c2ccccc2B2N(c3ccccc31)c1oc3c(c1N2c1ccccc1)N(c1ccccc1)B1c2ccccc2C(C)(C)c2ccccc2N13 ; CC(C)(C)c1ccc(N2B3c4ccccc4C(C)(C)c4ccccc4N3c3oc4c(c32)N(c2ccc(C(C)(C)C)cc2)B2c3ccccc3C(C)(C)c3ccccc3N24)cc1 ; c1ccc(N2B3c4ccccc4Oc4ccccc4N3c3sc4c(c32)N(c2ccccc2)B2c3ccccc3Oc3ccccc3N24)cc1]

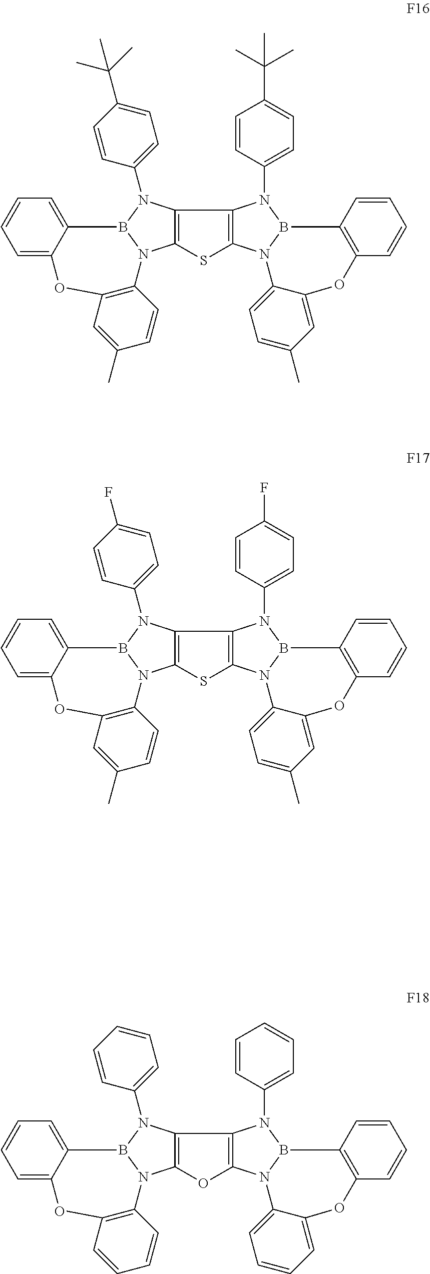 [SMILES: Cc1ccc2c(c1)Oc1ccccc1B1N2c2sc3c(c2N1c1ccc(C(C)(C)C)cc1)N(c1ccc(C(C)(C)C)cc1)B1c2ccccc2Oc2cc(C)ccc2N13 ; Cc1ccc2c(c1)Oc1ccccc1B1N2c2sc3c(c2N1c1ccc(F)cc1)N(c1ccc(F)cc1)B1c2ccccc2Oc2cc(C)ccc2N13 ; c1ccc(N2B3c4ccccc4Oc4ccccc4N3c3oc4c(c32)N(c2ccccc2)B2c3ccccc3Oc3ccccc3N24)cc1]

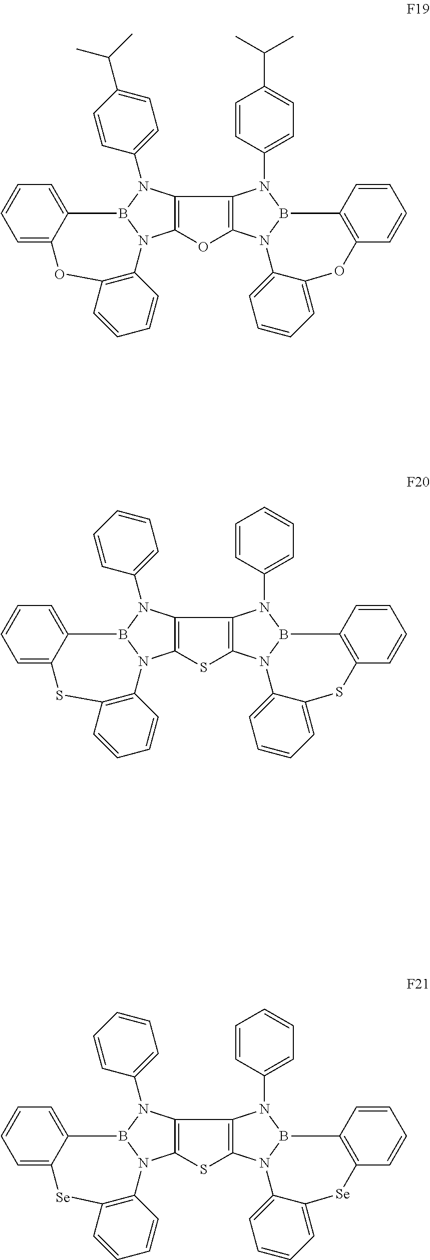 [SMILES: CC(C)c1ccc(N2B3c4ccccc4Oc4ccccc4N3c3oc4c(c32)N(c2ccc(C(C)C)cc2)B2c3ccccc3Oc3ccccc3N24)cc1 ; c1ccc(N2B3c4ccccc4Sc4ccccc4N3c3sc4c(c32)N(c2ccccc2)B2c3ccccc3Sc3ccccc3N24)cc1 ; c1ccc(N2B3c4ccccc4[Se]c4ccccc4N3c3sc4c(c32)N(c2ccccc2)B2c3ccccc3[Se]c3ccccc3N24)cc1]

Exemplified compounds belonging to group A are compounds represented by formula [2]. The compounds belonging to group A emit blue light having a longer wavelength and have a larger oscillator strength among the compounds according to the present embodiment. That is, group A is a group of compounds that emit blue light with higher efficiency.

Exemplified compounds belonging to group B are a group of compounds represented by formula [3]. Compounds belonging to group B have a smaller S-T gap (energy difference between S₁ and T₁) among the compounds according to the present embodiment. That is, group B is a group of exemplified compounds that can convert more excitons into light emission when used in a light-emitting layer of an organic light-emitting device.

Exemplified compounds belonging to group C are compounds in which, in formula [1-1], Q₁ and the like where n is 1 are linking groups. A greater number of seven-membered ring structures formed of Q₁ and the like lead to a reduction in molecular planarity, resulting in higher film stability. Thus, group C is a group of compounds, each of which can further reduce crystallization in the form of a thin film when used as a guest of a light-emitting layer among the compounds according to the present embodiment.

Exemplified compounds belonging to group D are compounds in which two of n are 1 in formula [1-1]. When a greater number of C—N bonds that can rotate are contained, the molecular bulkiness is further improved. Thus, group D is a group of compounds, each of which can further reduce concentration quenching in the form of a thin film when used as a guest of a light-emitting layer among the compounds according to the present embodiment.

Exemplified compounds belonging to group E are compounds represented by formula [4]. Among the compounds according to the present embodiment, each of the compounds belonging to group E has a heterocyclic ring in its basic skeleton and thus is a compound in which the HOMO-LUMO levels can be finely adjusted by the electronic effect of the heterocyclic ring.

Exemplified compounds belonging to group F are compounds in which two of n are 1 in formula [1-2]. When a greater number of C—N bonds that can rotate are contained, the molecular bulkiness is further improved. Thus, group F is a group of compounds, each of which can further reduce concentration quenching in the form of a thin film when used as a guest of a light-emitting layer among the compounds according to the present embodiment.

The organic compound according to the present embodiment is a compound that exhibits light emission suitable for blue light emission at high efficiency and has high stability against oxidation. Accordingly, the use of the organic compound according to the present embodiment as a constituent material for an organic light-emitting device enables the organic light-emitting device to have good light emission characteristics and superior durability characteristics.

### Organic Light-Emitting Device

An organic light-emitting device according to the present embodiment will be described below. The organic light-emitting device according to the present embodiment at least includes an anode and a cathode, which are a pair of electrodes, and an organic compound layer disposed between these electrodes. In the organic light-emitting device of the present embodiment, the organic compound layer may be formed of a single layer or a laminate including multiple layers, as long as it includes a light-emitting layer. When the organic compound layer is formed of a laminate including multiple layers, the organic compound layer may include, in addition to the light-emitting layer, a hole injection layer, a hole transport layer, an electron-blocking layer, a hole/exciton-blocking layer, an electron transport layer, and an electron injection layer, for example. The light-emitting layer may be formed of a single layer or a laminate including multiple layers.

In the organic light-emitting device according to the present embodiment, at least one layer in the organic compound layer contains the organic compound according to the present embodiment. Specifically, the organic compound according to the present embodiment is contained in any one of the light-emitting layer, the hole injection layer, the hole transport layer, the electron-blocking layer, the hole-exciton-blocking layer, the electron transport layer, the electron injection layer, and so forth. The organic compound according to the present embodiment is preferably contained in the light-emitting layer.

In the organic light-emitting device of the present embodiment, when the organic compound according to the present embodiment is contained in the light-emitting layer, the light-emitting layer may consist of only the organic compound according to the present embodiment or may be made of the organic compound according to the present embodiment and another compound. When the light-emitting layer is composed of the organic compound according to the embodiment and another compound, the organic compound according to the present embodiment may be used as a host or a guest in the light-emitting layer. The organic compound according to the present embodiment may be used as an assist material that can be contained in the light-emitting layer. The term “host” used here refers to a compound having the highest proportion by mass in compounds contained in the light-emitting layer. The term “guest” refers to a compound that has a lower proportion by mass than the host in the compounds contained in the light-emitting layer and that is responsible for main light emission. The term “assist material” refers to a compound that has a lower proportion by mass than the host in the compounds contained in the light-emitting layer and that assists the light emission of the guest. The assist material is also referred to as a second host.

When the organic compound according to the present embodiment is used as a guest in the light-emitting layer, the concentration of the guest is preferably 0.01% or more by mass and 20% or less by mass, more preferably 0.1% or more by mass and 5% or less by mass, based on the entire light-emitting layer.

When the organic compound according to the present embodiment is used as a guest in the light-emitting layer, a material having a higher LUMO level than the organic compound according to the present embodiment (a material having a LUMO level closer to the vacuum level) can be used as a host. This is because when a material having a higher LUMO level than the organic compound according to the present embodiment is used as a host, the organic compound according to the embodiment can receive more electrons supplied to the host of the light-emitting layer.

The inventors have conducted various studies and have found that when the organic compound according to the present embodiment is used as a host or guest of a light-emitting layer, especially as a guest of a light-emitting layer, a device that emits light with high efficiency and high luminance and that is extremely durable can be provided. This light-emitting layer can be formed of a single layer or multiple layers and can also contain a light-emitting material having another emission color in order to conduct the color mixture of the blue emission color of the present embodiment and another emission color. The term “multiple layers” refers to a state in which a light-emitting layer and another light-emitting layer are stacked. In this case, the emission color of the organic light-emitting device is not limited to blue. More specifically, the emission color may be white or an intermediate color. In the case of white, the another light-emitting layer emits light of a color other than blue, that is, red or green. Regarding a film-forming method, film is formed by vapor deposition or a coating method. The details thereof will be described in Examples below.

The organic compound according to the present embodiment can be used as a constituent material of an organic compound layer other than the light-emitting layer included in the organic light-emitting device of the present embodiment. Specifically, the organic compound may be used as a constituent material for the electron transport layer, the electron injection layer, the hole transport layer, the hole injection layer, the hole-blocking layer, and so forth. In this case, the emission color of the organic light-emitting device is not limited to blue. More specifically, the emission color may be white or intermediate color.

### Compound Other Than Organic Compound of Present Embodiment

For example, a hole injection compound, a hole transport compound, a compound to be used as a host, a light-emitting compound, an electron injection compound, or an electron transport compound, which is known and has a low or high molecular weight, can be used together with the organic compound according to the present embodiment, as needed. Examples of these compounds are illustrated below.

As a hole injection-transport material, a material having a high hole mobility is preferably used so as to facilitate the injection of holes from the anode and to transport the injected holes to the light-emitting layer. To reduce a deterioration in film quality, such as crystallization, in the organic light-emitting device, a material having a high glass transition temperature is preferred. Examples of a low- or high-molecular-weight material having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Moreover, the hole injection-transport material is also suitably used for the electron-blocking layer. Specific examples of a compound used as the hole injection-transport material are illustrated below, but of course, the compound is not limited thereto.

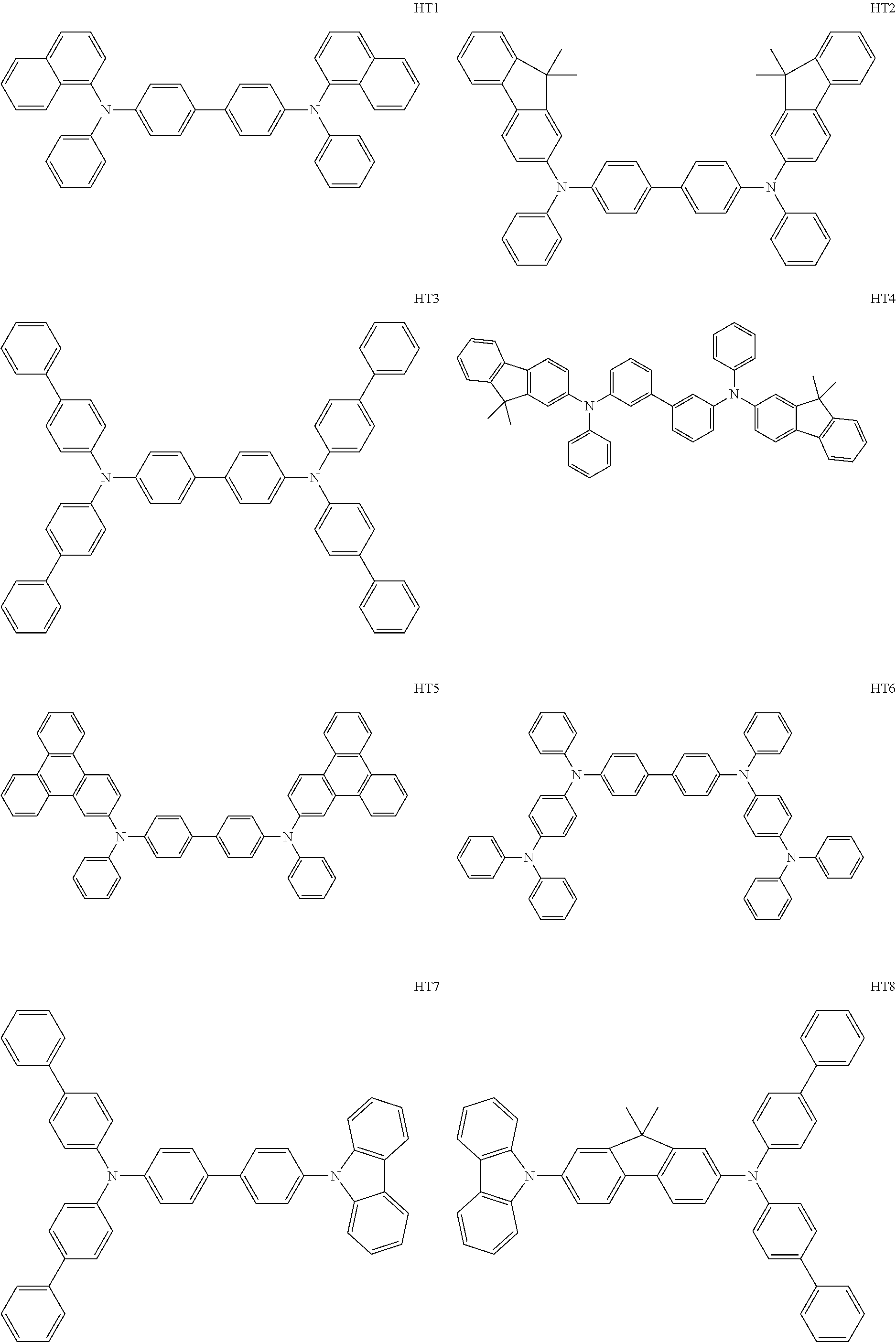

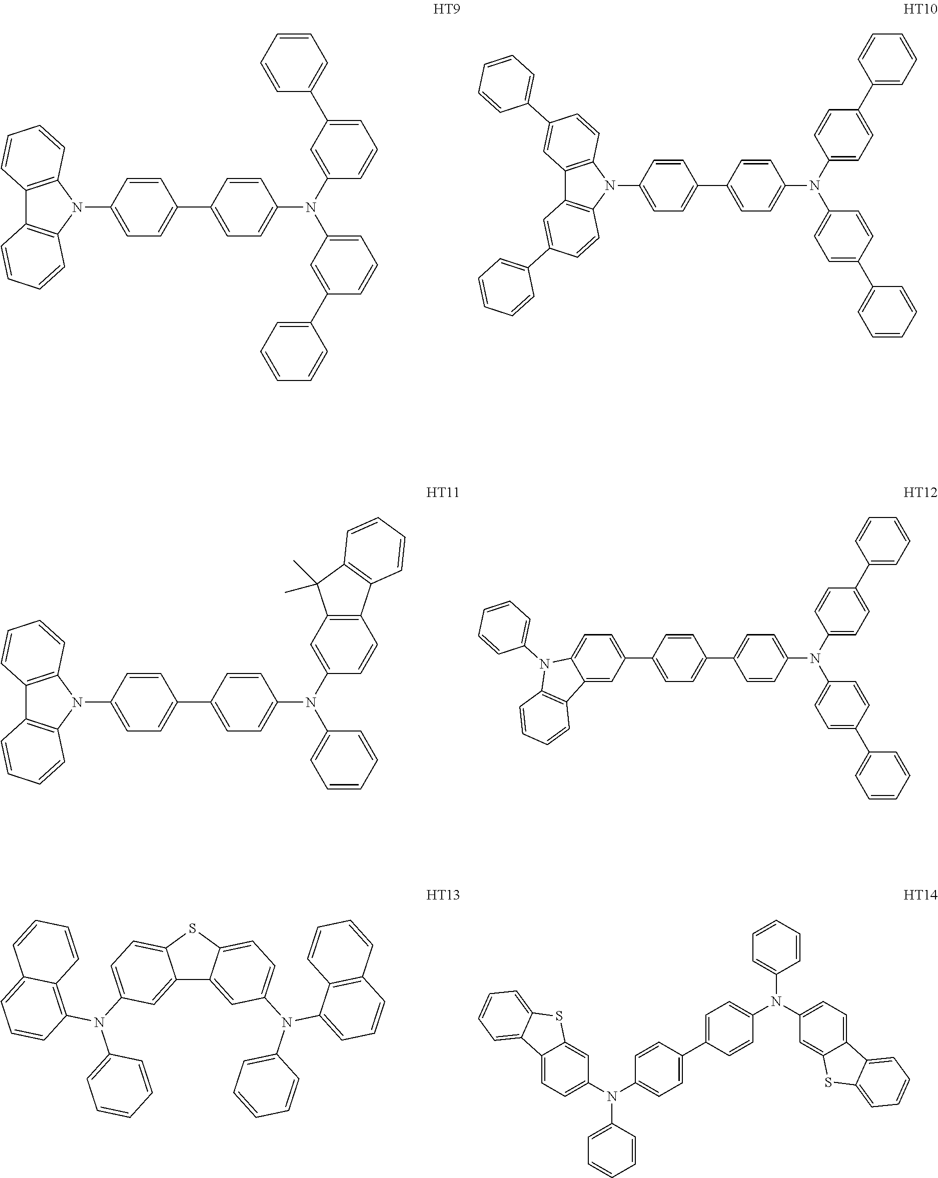

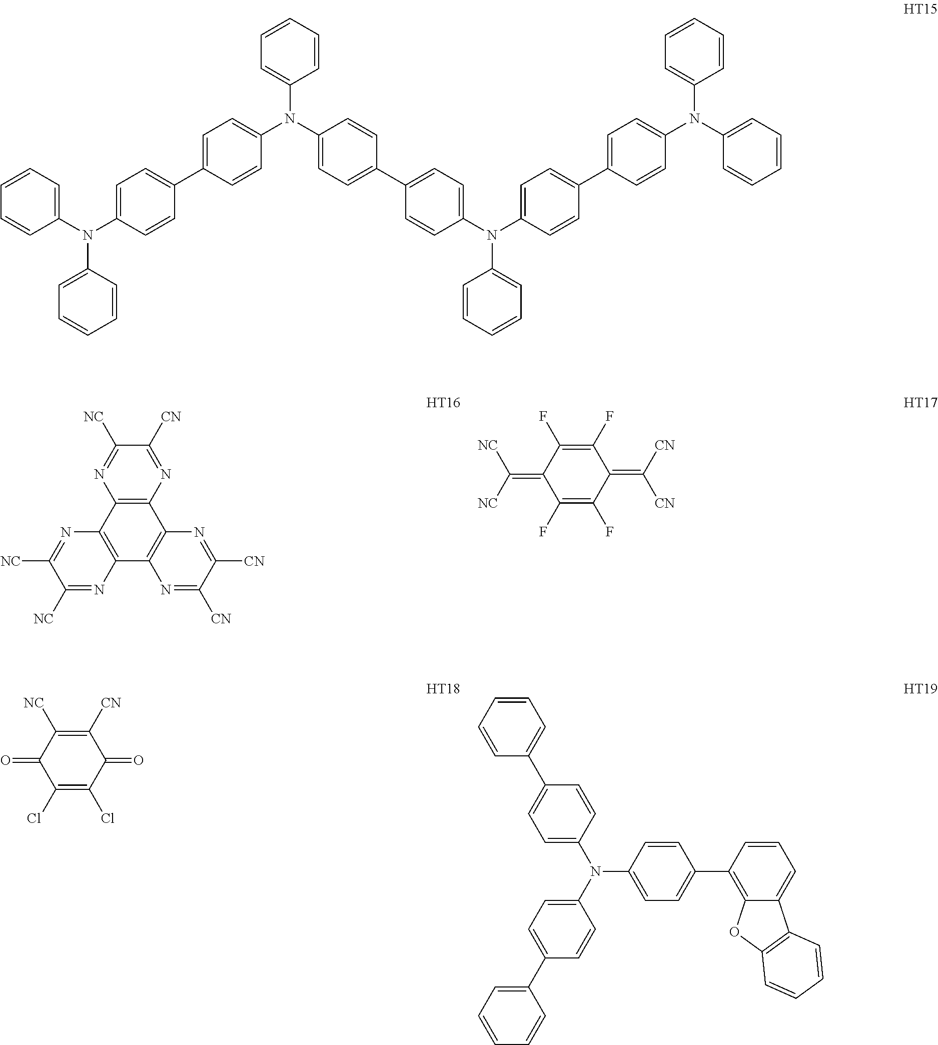 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Examples of the light-emitting material mainly related to the light-emitting function include fused-ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives. Specific examples of a compound used as a light-emitting material are illustrated below, but of course, the light-emitting material is not limited thereto.

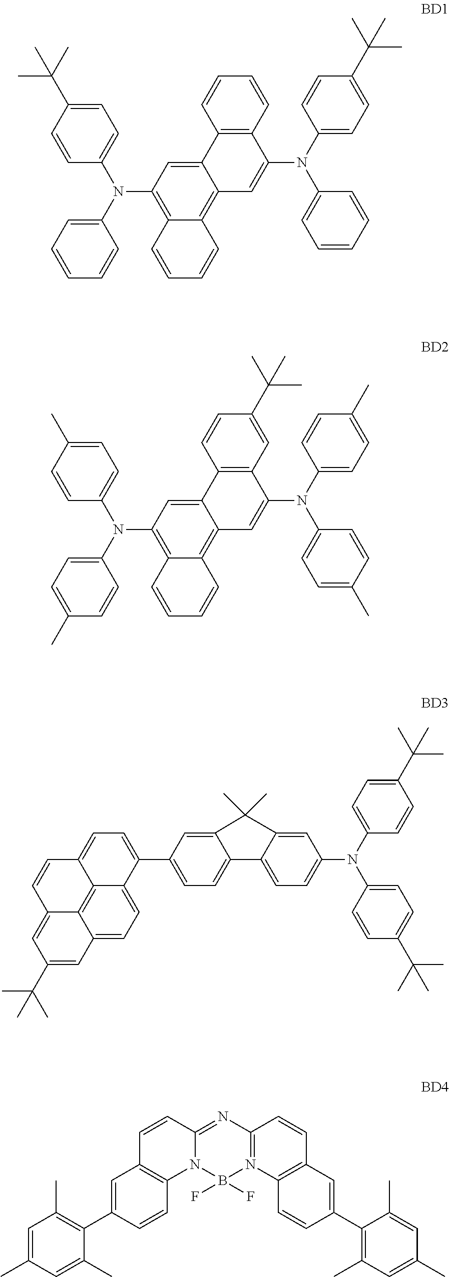

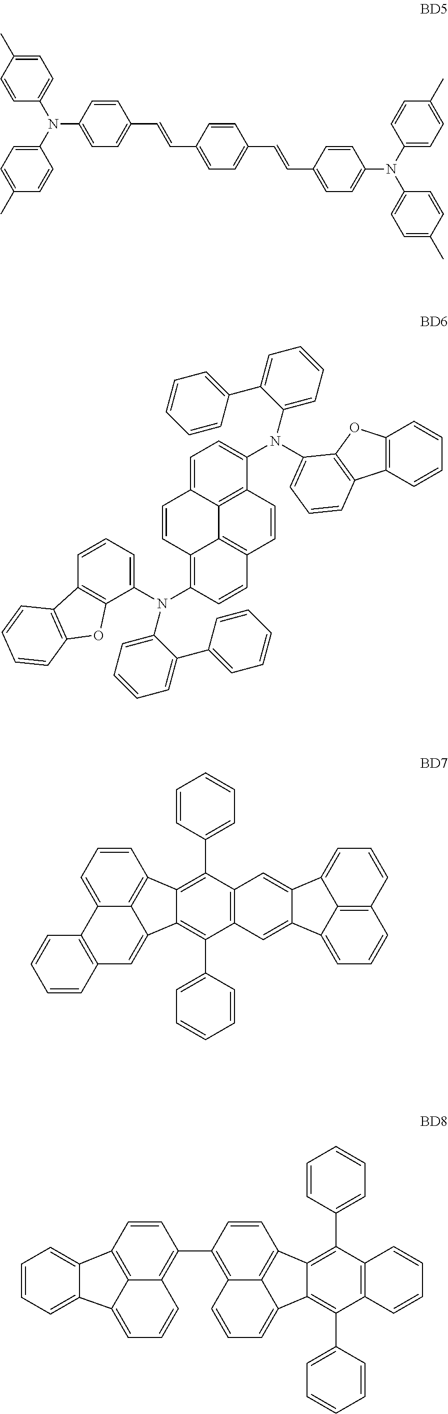

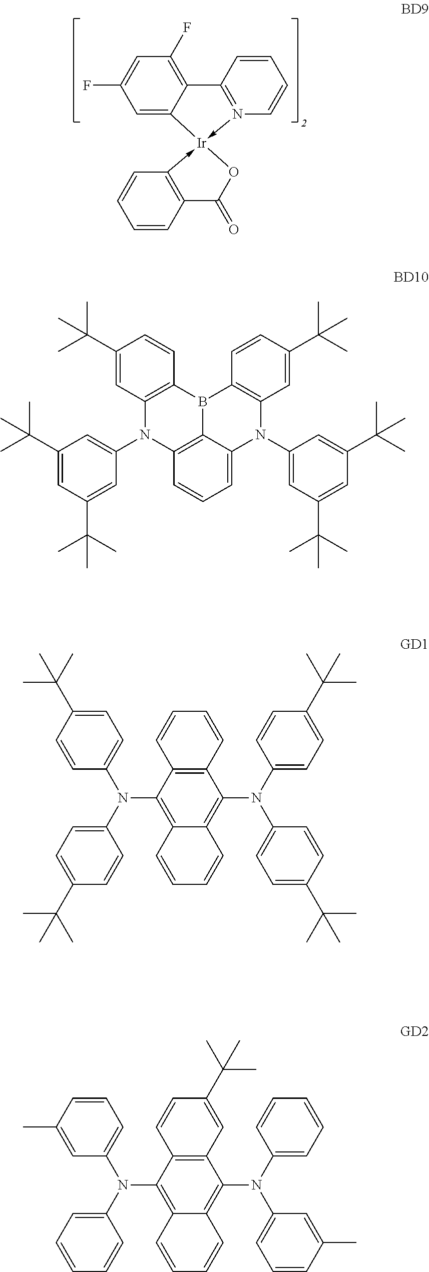

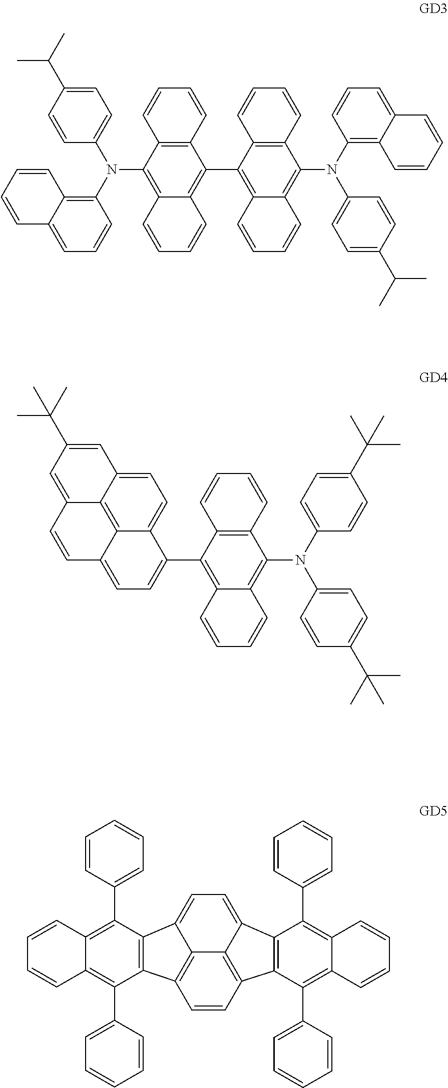

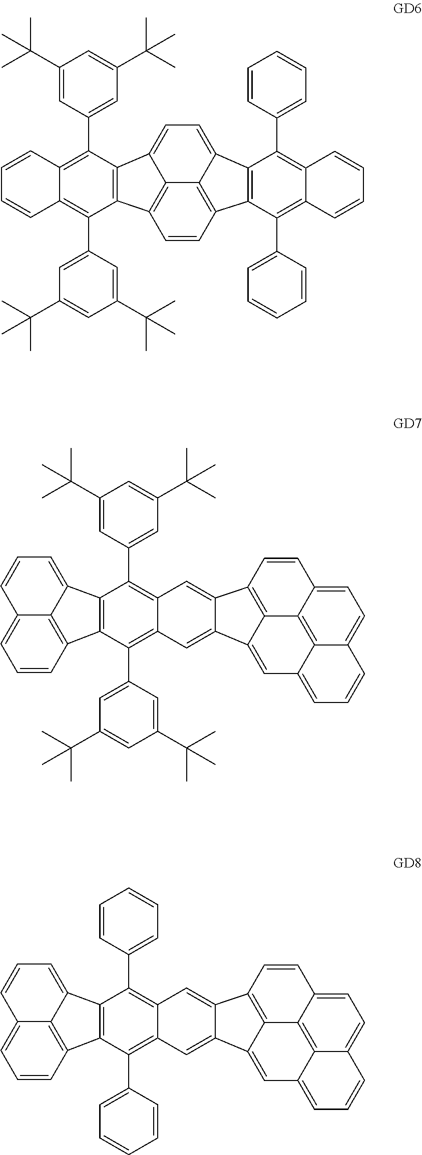

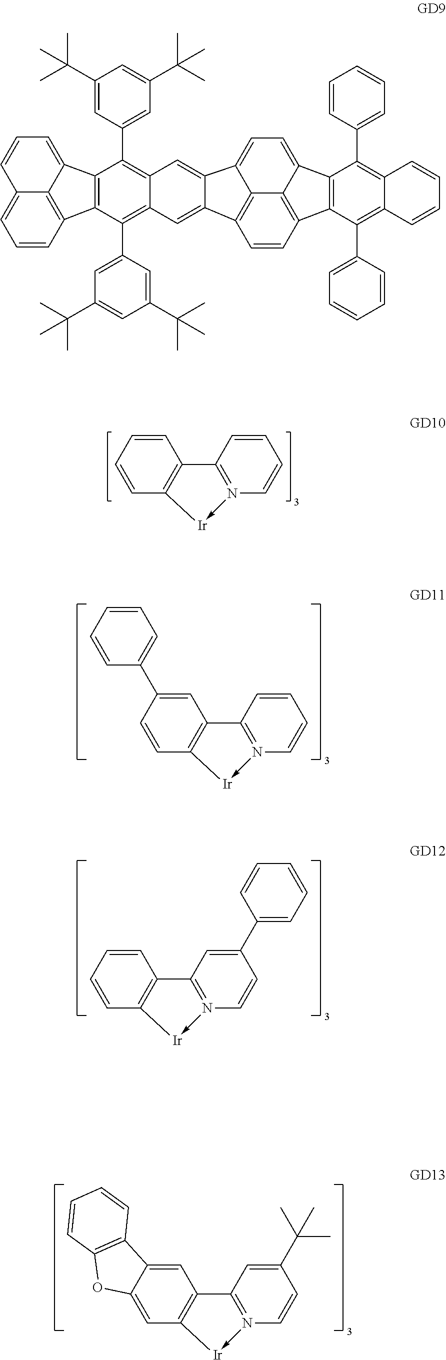

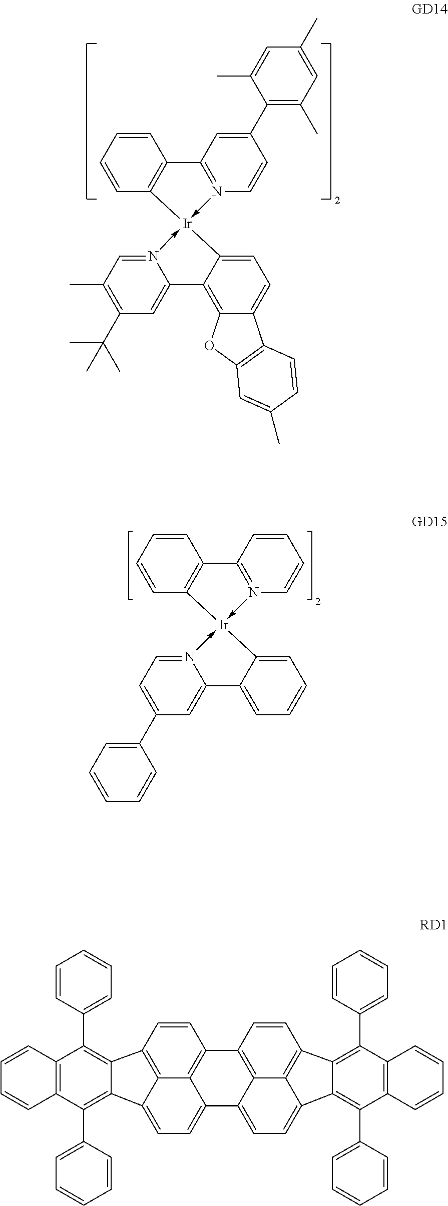

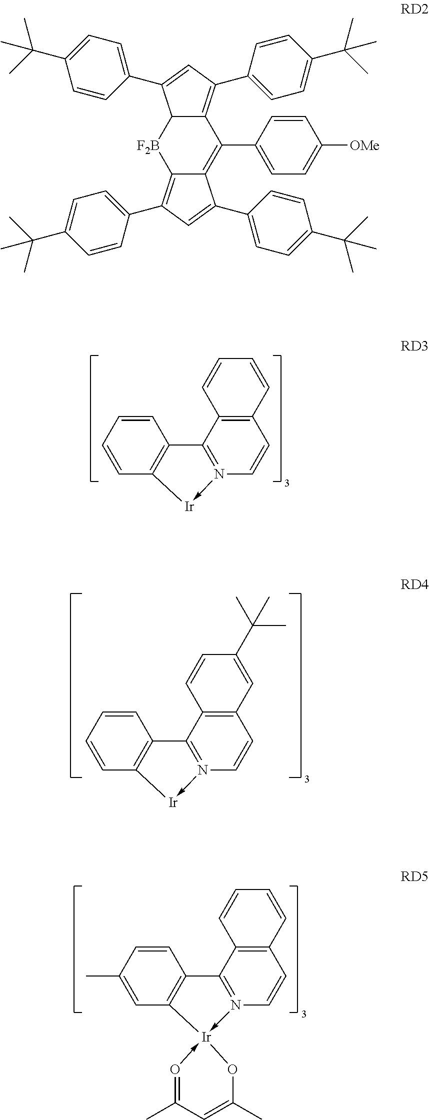

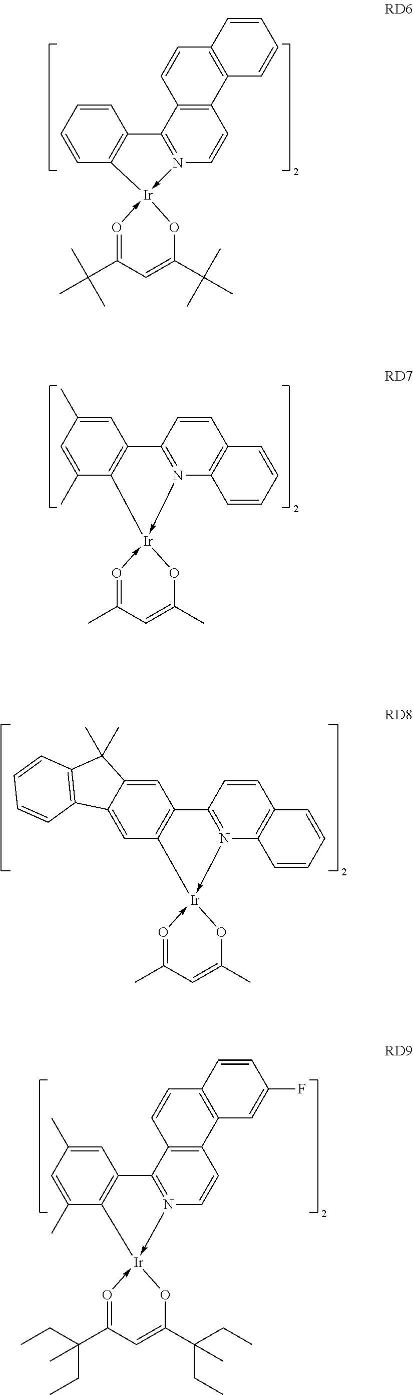

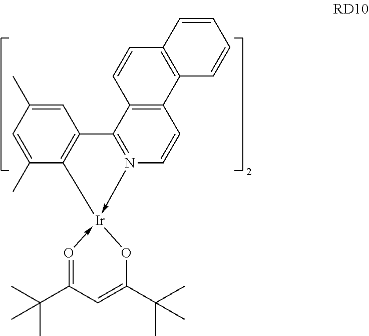

Examples of a light-emitting layer host or a light-emission assist material in the light-emitting layer include aromatic hydrocarbon compounds and derivatives thereof, carbazole derivatives, dibenzofuran derivatives, dibenzothiophene derivatives, organoaluminum complexes, such as tris(8-quinolinolato)aluminum, and organoberyllium complexes. Specific examples of the compound for the light-emitting layer host or light-emission assist material contained in the light-emitting layer are illustrated below, but of course, the compound is not limited thereto.

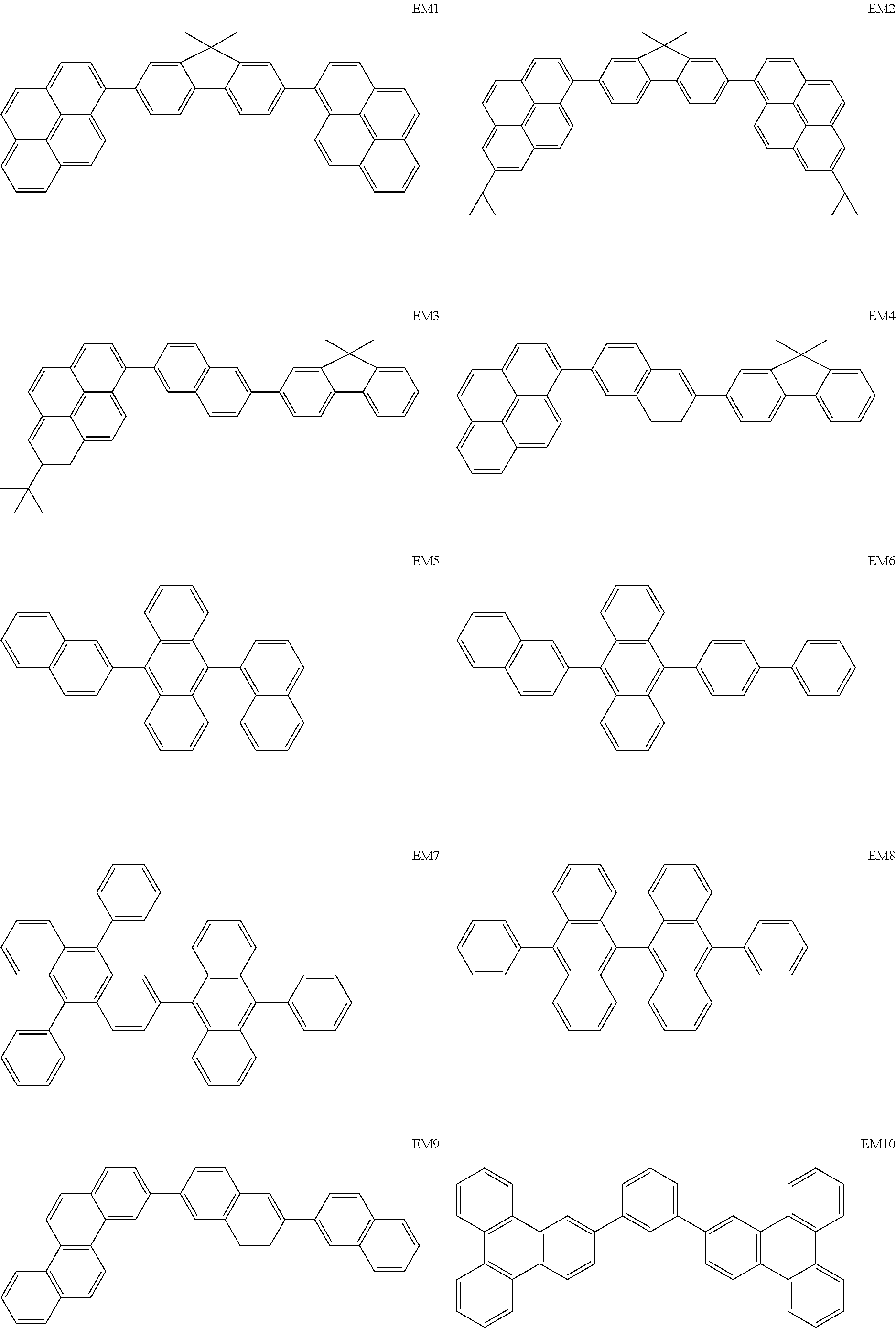

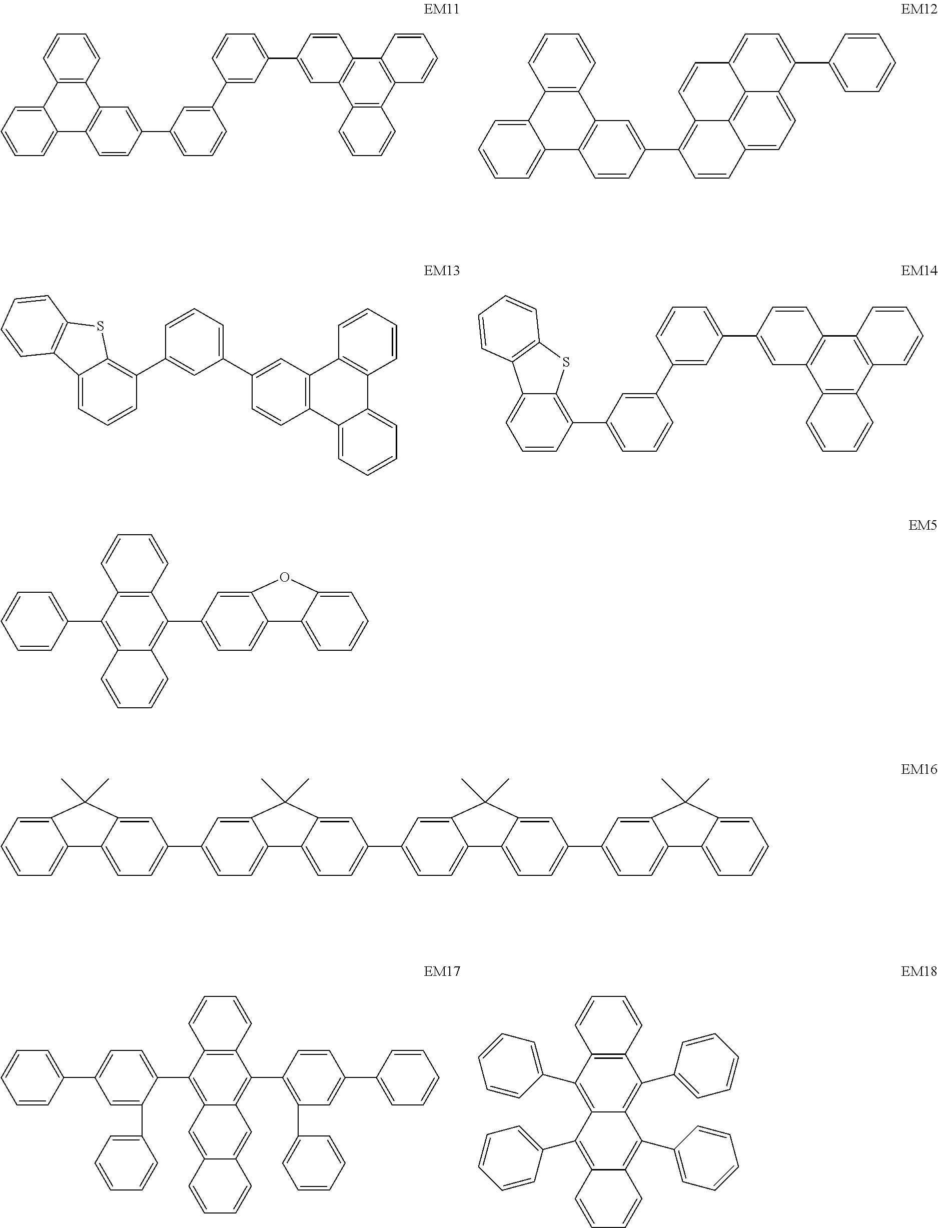

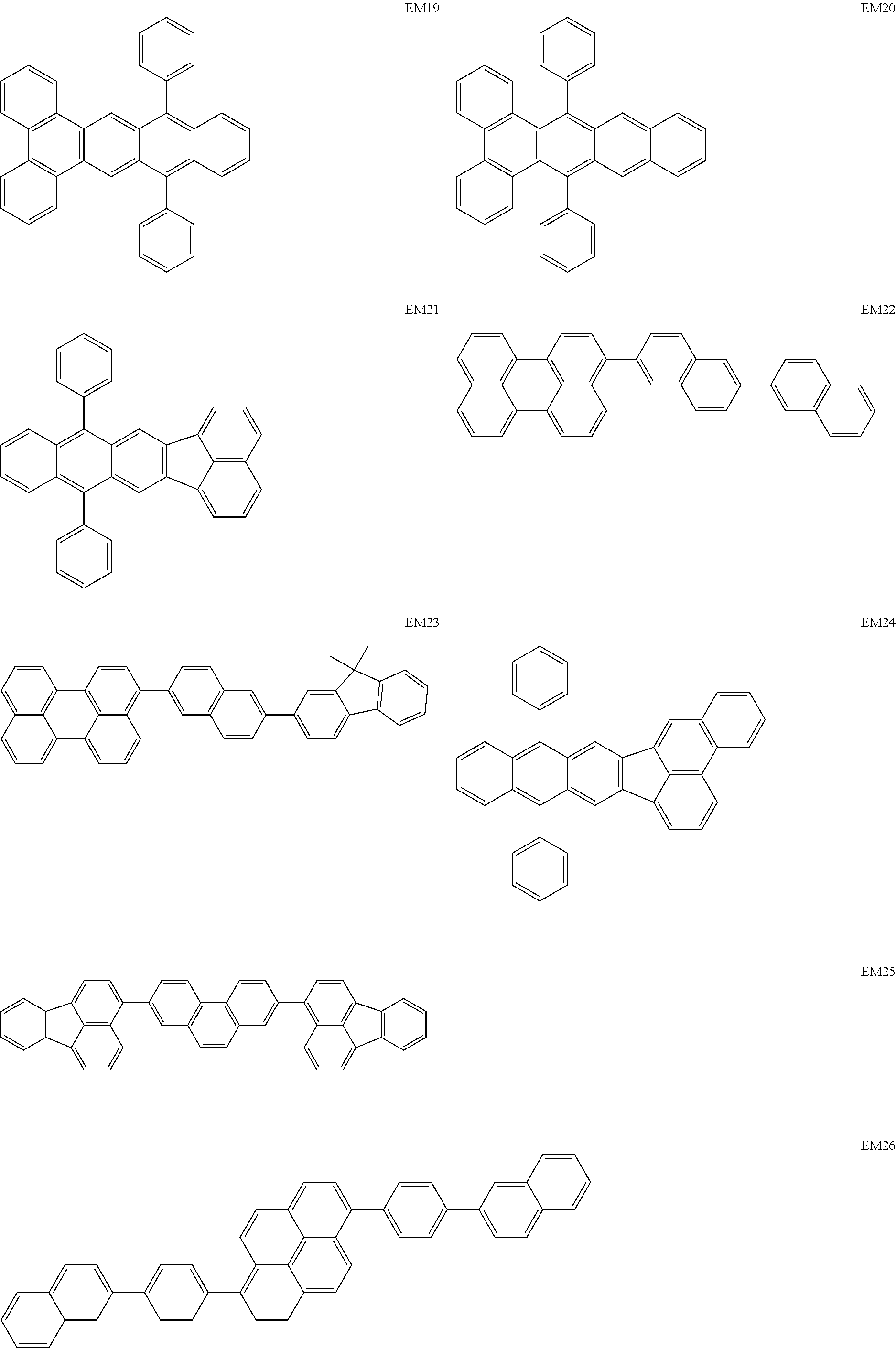

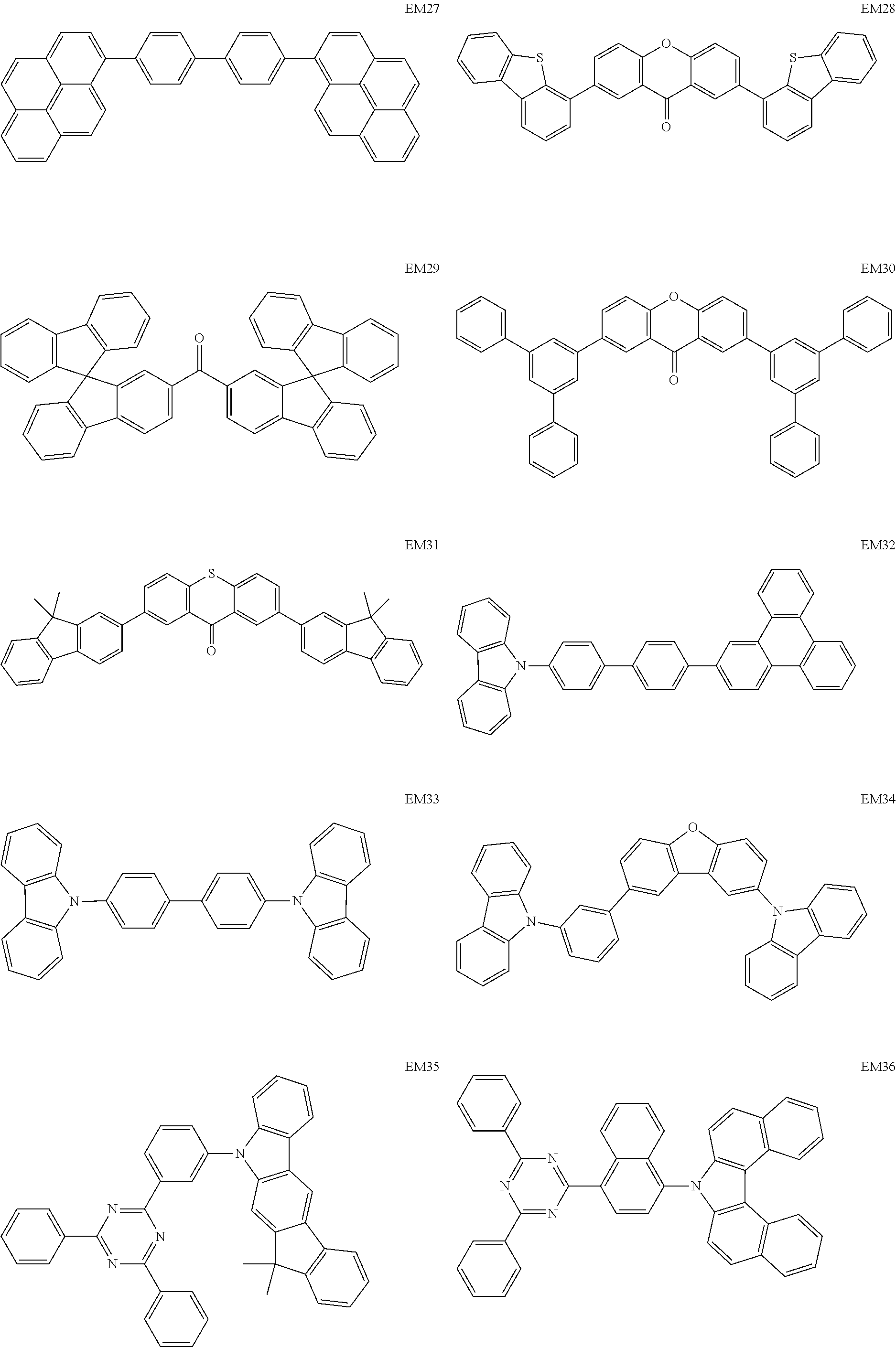

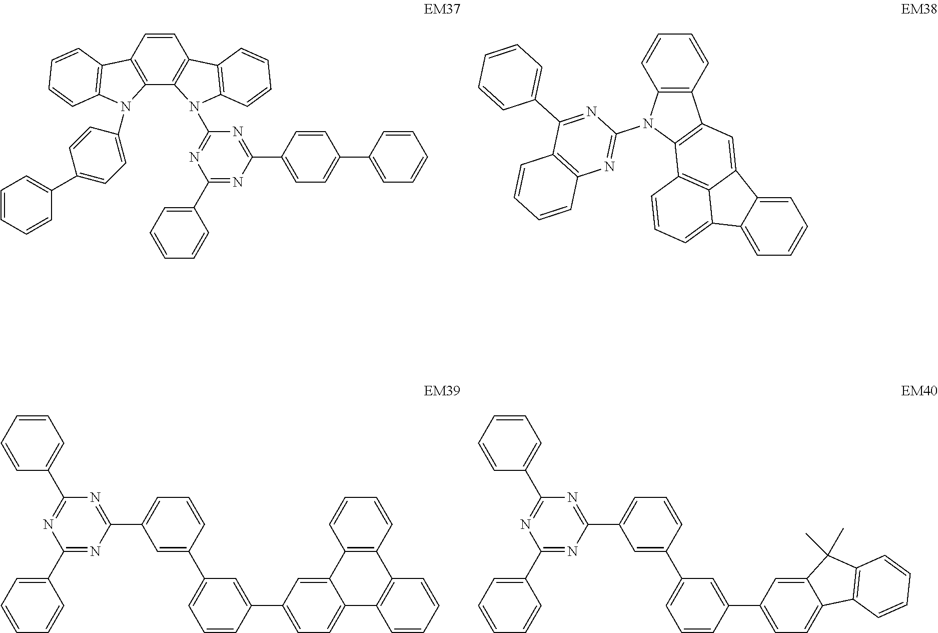

The electron transport material can be freely-selected from materials that can transport electrons injected from the cathode to the light-emitting layer, and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds (such as fluorene derivatives, naphthalene derivatives, chrysene derivatives, and anthracene derivatives). The above-described electron transport materials are also suitably used for the hole-blocking layer. Specific examples of a compound used as the electron transport material are illustrated below, but of course, the electron transport material is not limited thereto.

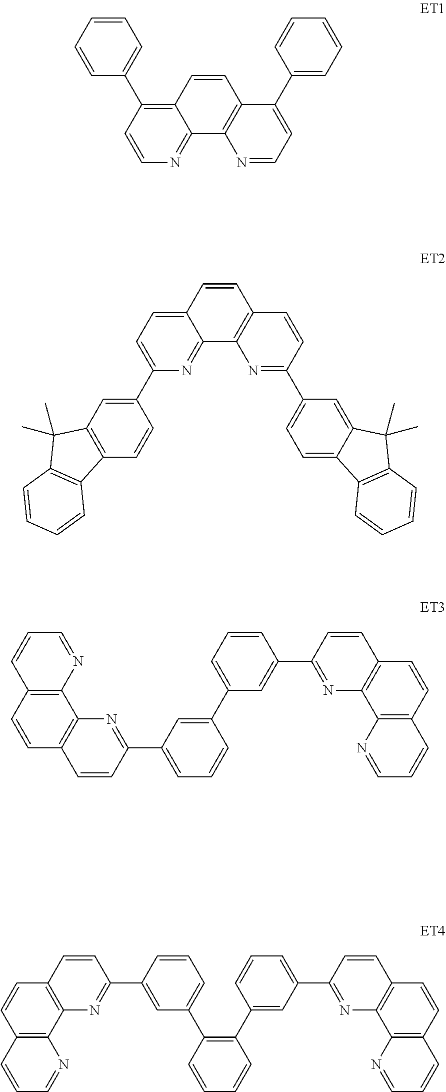

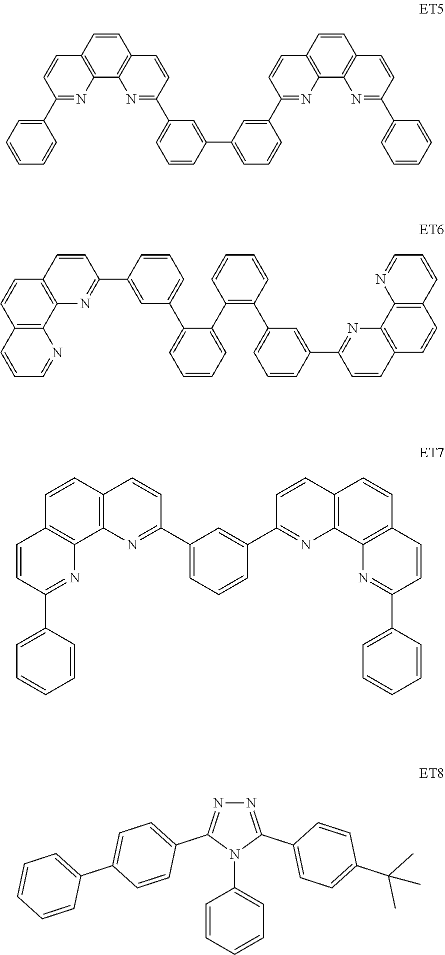 [SMILES: c1ccc(-c2ccc3ccc4ccc(-c5cccc(-c6cccc(-c7ccc8ccc9ccc(-c%10ccccc%10)nc9c8n7)c6)c5)nc4c3n2)cc1 ; c1cc(-c2ccc3ccc4cccnc4c3n2)cc(-c2ccccc2-c2ccccc2-c2cccc(-c3ccc4ccc5cccnc5c4n3)c2)c1 ; c1ccc(-c2ccc3ccc4ccc(-c5cccc(-c6ccc7ccc8ccc(-c9ccccc9)nc8c7n6)c5)nc4c3n2)cc1 ; CC(C)(C)c1ccc(-c2nnc(-c3ccc(-c4ccccc4)cc3)n2-c2ccccc2)cc1]

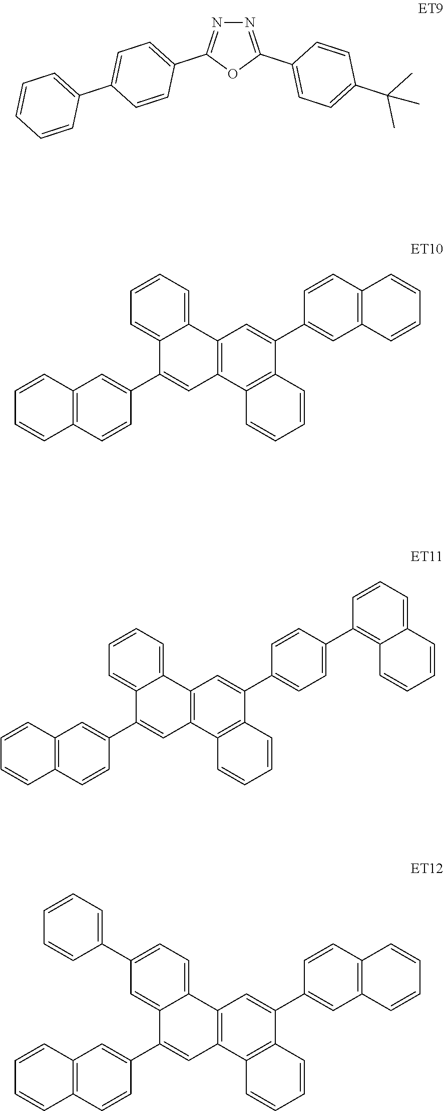

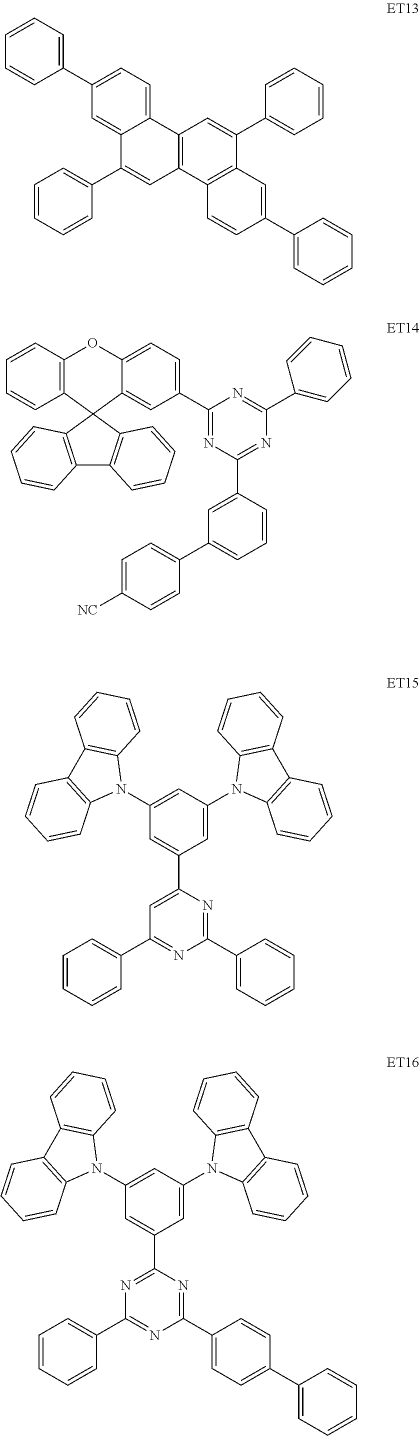

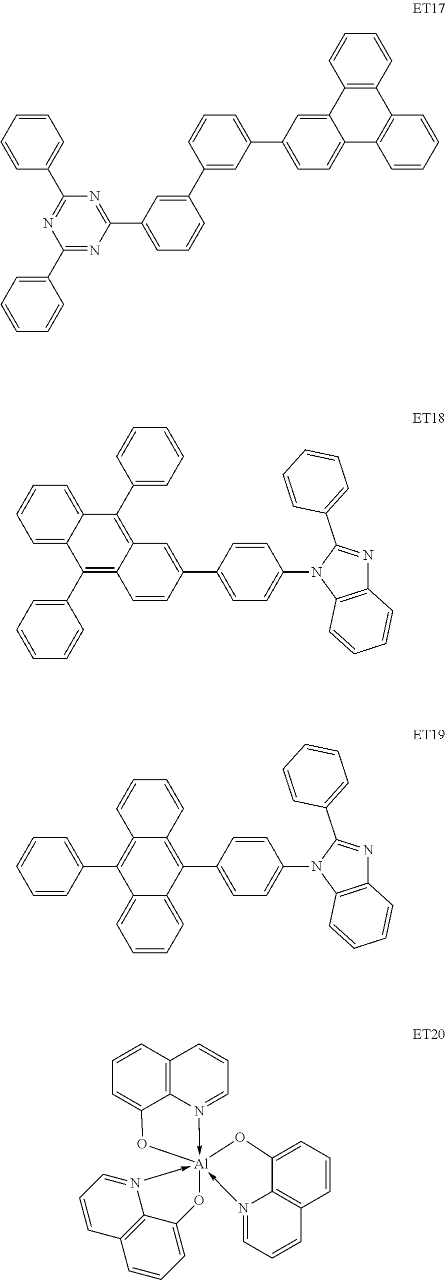

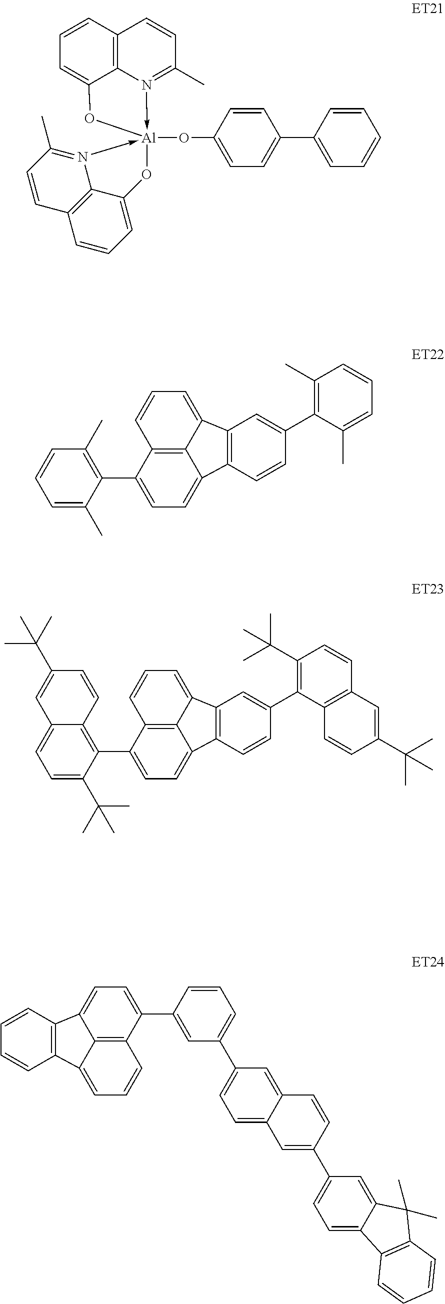

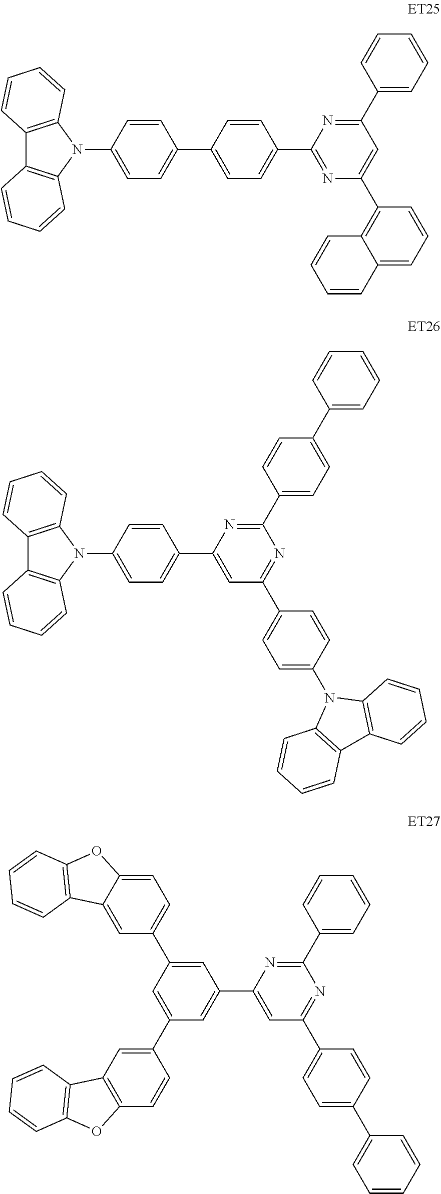 [SMILES: c1ccc(-c2cc(-c3cccc4ccccc34)nc(-c3ccc(-c4ccc(-n5c6ccccc6c6ccccc65)cc4)cc3)n2)cc1 ; c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

### Configuration of Organic Light-Emitting Device

The organic light-emitting device includes an insulating layer, a first electrode, an organic compound layer, and a second electrode over a substrate. A protective layer, a color filter, a microlens may be disposed over the second electrode. In the case of disposing the color filter, a planarization layer may be disposed between the protective layer and the color filter. The planarization layer can be composed of, for example, an acrylic resin. The same applies when a planarization layer is provided between the color filter and the microlens.

### Substrate

Examples of the substrate include silicon wafers, quartz substrates, glass substrates, resin substrates, and metal substrates. The substrate may include a switching device, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

A pair of electrodes can be used. The pair of electrodes may be an anode and a cathode. When an electric field is applied in the direction in which the organic light-emitting device emits light, an electrode having a higher potential is the anode, and the other is the cathode. It can also be said that the electrode that supplies holes to the light-emitting layer is the anode and that the electrode that supplies electrons is the cathode.

As the component material of the anode, a material having a work function as high as possible can be used. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can be used.

These electrode materials may be used alone or in combination of two or more. The anode may be formed of a single layer or multiple layers.

When the anode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the anode is used as a transparent electrode, a transparent conductive oxide layer composed of, for example, indium-tin oxide (ITO) or indium-zinc oxide can be used; however, the anode is not limited thereto. The electrode can be formed by photolithography.

As the component material of the cathode, a material having a lower work function can be used. Examples thereof include elemental metals such as alkali metals, e.g., lithium, alkaline-earth metals, e.g., calcium, aluminum, titanium, manganese, silver, lead, and chromium, and mixtures thereof. Alloys of combinations of these elemental metals can also be used. For example, magnesium-silver, aluminum-lithium, aluminum-magnesium, silver-copper, and zinc-silver can be used. Metal oxides, such as indium-tin oxide (ITO), can also be used. These electrode materials may be used alone or in combination of two or more. The cathode may have a single-layer structure or a multilayer structure. Among them, it is preferable to use silver. To reduce the aggregation of silver, it is more preferable to use a silver alloy. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). Any type of cathode may be used. Any method for forming the cathode may be employed. For example, a direct-current or alternating-current sputtering technique is more preferably employed because good film coverage is obtained and thus the resistance is easily reduced.

### Organic Compound Layer

The organic compound layer may be formed of a single layer or multiple layers. When multiple layers are present, they may be referred to as a hole injection layer, a hole transport layer, an electron-blocking layer, a light-emitting layer, a hole-blocking layer, an electron transport layer, or an electron injection layer in accordance with their functions. The organic compound layer is mainly composed of an organic compound, and may contain inorganic atoms and an inorganic compound. For example, the organic compound layer may contain, for example, copper, lithium, magnesium, aluminum, iridium, platinum, molybdenum, or zinc. The organic compound layer may be disposed between the first electrode and the second electrode, and may be disposed in contact with the first electrode and the second electrode.

The organic compound layer (such as the hole injection layer, the hole transport layer, the electron-blocking layer, the light-emitting layer, the hole-blocking layer, the electron transport layer, or the electron injection layer) included in the organic light-emitting device according to an embodiment of the present invention is formed by a method described below.

For the organic compound layer included in the organic light-emitting device according to an embodiment of the present invention, a dry process, such as a vacuum evaporation method, an ionized evaporation method, sputtering, or plasma, may be employed. Alternatively, instead of the dry process, it is also possible to employ a wet process in which a material is dissolved in an appropriate solvent and then a film is formed by a known coating method (such as spin coating, dipping, a casting method, an LB technique, or an ink jet method).

When the layer is formed by, for example, the vacuum evaporation method or the solution coating method, crystallization and so forth are less likely to occur, and good stability with time is obtained. In the case of forming a film by the coating method, the film may be formed in combination with an appropriate binder resin.

Examples of the binder resin include, but are not limited to, poly(vinyl carbazole) resins, polycarbonate resins, polyester resins, ABS resins, acrylic resins, polyimide resins, phenolic resins, epoxy resins, silicone resins, and urea resins.

These binder resins may be used alone as a homopolymer or copolymer or in combination as a mixture of two or more. Furthermore, additives, such as a known plasticizer, antioxidant, and ultraviolet absorber, may be used, as needed.

### Protective Layer

A protective layer may be disposed on the second electrode. For example, a glass member provided with a moisture absorbent can be bonded to the second electrode to reduce the entry of, for example, water into the organic compound layer, thereby reducing the occurrence of display defects. In another embodiment, a passivation film composed of, for example, silicon nitride may be disposed on the second electrode to reduce the entry of, for example, water into the organic compound layer. For example, after the formation of the second electrode, the substrate may be transported to another chamber without breaking the vacuum, and a silicon nitride film having a thickness of 2 μm may be formed by a CVD method to provide a protective layer. After the film deposition by the CVD method, a protective layer may be formed by an atomic layer deposition (ALD) method. Examples of the material of the layer formed by the ALD method may include, but are not limited to, silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, the thickness may be 50% or less, even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a “material resin layer” without limiting its purpose. The planarization layer may be composed of an organic compound. A low- or high-molecular-weight organic compound may be used. A high-molecular-weight organic compound is preferred.

The planarization layers may be disposed above and below (or on) the color filter and may be composed of the same or different component materials. Specific examples thereof include poly(vinyl carbazole) resins, polycarbonate resins, polyester resins, ABS resins, acrylic resins, polyimide resins, phenolic resins, epoxy resins, silicone resins, and urea resins.

### Microlens

The organic light-emitting device or an organic light-emitting apparatus may include an optical component, such as a microlens, on the outgoing light side. The microlens can be composed of, for example, an acrylic resin or an epoxy resin. The microlens may be used to increase the amount of light emitted from the organic light-emitting device or the organic light-emitting apparatus and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same material as the substrate described above. When the above-described substrate is referred to as a first substrate, the opposite substrate may be referred to as a second substrate.

### Pixel Circuit

An organic light-emitting apparatus including organic light-emitting devices may include pixel circuits coupled to the organic light-emitting devices. Each of the pixel circuits may be of an active matrix type, which independently controls the emission of first and second light-emitting devices. The active matrix type circuit may be voltage programming or current programming. A driving circuit includes the pixel circuit for each pixel. The pixel circuit may include a light-emitting device, a transistor to control the luminance of the light-emitting device, a transistor to control the timing of the light emission, a capacitor to retain the gate voltage of the transistor to control the luminance, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit. The gradient of the current-voltage characteristics of the transistor contained in the pixel circuit may be smaller than the gradient of the current-voltage characteristic of the transistor contained in the display control circuit. The gradient of the current-voltage characteristics can be measured by what is called Vg-Ig characteristics. The transistor contained in the pixel circuit is a transistor coupled to a light-emitting device, such as a first light-emitting device.

### Pixel

An organic light-emitting apparatus including an organic light-emitting device may include multiple pixels. Each pixel includes subpixels configured to emit colors different from each other. The subpixels may have respective red, green, and blue (RGB) emission colors.

Light emerges from a region of the pixel, also called a pixel aperture. This region is also referred to as a first region. The pixel aperture may be 15 μm or less, and may be 5 μm or more. More specifically, the pixel aperture may be, for example, 11 μm, 9.5 μm, 7.4 μm, or 6.4 μm. The distance between subpixels may be 10 μm or less. Specifically, the distance may be 8 μm, 7.4 μm, or 6.4 μm.

The pixels may be arranged in a known pattern in plan view. For example, a stripe pattern, a delta pattern, a Pen Tile matrix pattern, or the Bayer pattern may be used. The shape of each subpixel in plan view may be any known shape. Examples of the shape of the subpixel include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### Application of Organic Light-Emitting Device

The organic light-emitting device according to an embodiment can be used as a component member of a display apparatus or lighting apparatus. Other applications include exposure light sources for electrophotographic image-forming apparatuses, backlights for liquid crystal displays, and light-emitting apparatuses including white-light sources and color filters.

The display apparatus may be an image information-processing unit having an image input unit that receives image information from an area CCD, a linear CCD, a memory card, or the like, an information-processing unit that processes the input information, and a display unit that displays the input image. The display apparatus includes multiple pixels, and at least one of the multiple pixels may include the organic light-emitting device of the present embodiment and a transistor coupled to the organic light-emitting device.

The display unit of an image pickup apparatus or an inkjet printer may have a touch panel function. The display unit of an image pickup apparatus or an inkjet printer may have a touch panel function. The driving mode of the touch panel function may be, but is not particularly limited to, an infrared mode, an electrostatic capacitance mode, a resistive film mode, or an electromagnetic inductive mode. The display apparatus may also be used for a display unit of a multifunction printer.

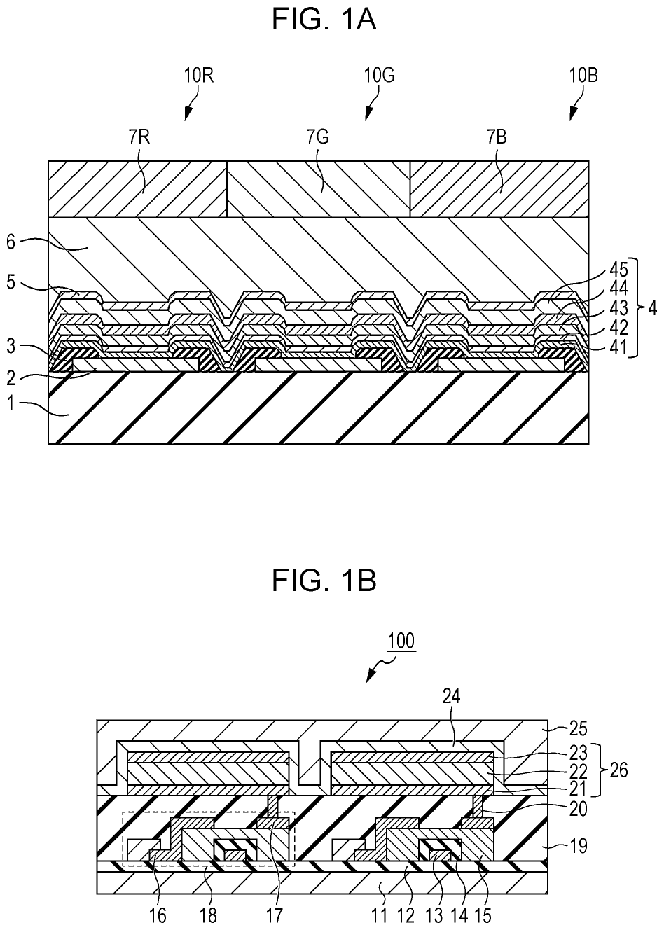

The following describes a display apparatus according to the present embodiment with reference to the attached drawings. FIGS. 1A and 1B are each a schematic cross-sectional view of an example of a display apparatus including organic light-emitting devices and transistors coupled to the respective organic light-emitting devices. Each of the transistors is an example of an active element. The transistors may be thin-film transistors (TFTs).

FIG. 1A is an example of pixels that are components of the display apparatus according to the present embodiment. Each of the pixels includes subpixels 10. The subpixels are separated into 10R, 10G, and 10B according to their light emission. The emission color may be distinguished based on the wavelength of light emitted from the light-emitting layer. Alternatively, light emitted from the subpixels may be selectively transmitted or color-converted with, for example, a color filter. Each subpixels 10 includes a reflective electrode serving as a first electrode 2, an insulating layer 3 covering the edge of the first electrode 2, an organic compound layer 4 covering the first electrode 2 and the insulating layer 3, a transparent electrode serving as a second electrode 5, a protective layer 6, and a color filter 7 over an interlayer insulating layer 1.

The transistors and capacitive elements may be disposed under or in the interlayer insulating layer 1. Each transistor may be electrically coupled to a corresponding one of the first electrodes 2 through a contact hole, which is not illustrated.

The insulating layer 3 is also called a bank or pixel separation film. The insulating layer 3 covers the edge of each first electrode 2 and surrounds the first electrode 2. Portions that are not covered with the insulating layer 3 are in contact with the organic compound layer 4 and serve as light-emitting regions.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semi-transparent electrode.

The protective layer 6 reduces the penetration of moisture into the organic compound layer 4. Although the protective layer 6 is illustrated as a single layer, the protective layer 6 may include multiple layers, and each layer may be an inorganic compound layer or an organic compound layer.

The color filter 7 is separated into 7R, 7G, and 7B according to its color. The color filter 7 may be disposed on a planarization film, which is not illustrated. A resin protective layer, not illustrated, may be disposed on the color filter 7. The color filter 7 may be disposed on the protective layer 6. Alternatively, the color filter 7 may be disposed on an opposite substrate, such as a glass substrate, and then bonded.

A display apparatus 100 illustrated in FIG. 1B includes organic light-emitting devices 26 and TFTs 18 as an example of transistors. A substrate 11 composed of a material, such as glass or silicon is provided, and an insulating layer 12 is disposed thereon. Active elements, such as the TFTs 18, are disposed on the insulating layer 12. The gate electrode 13, the gate insulating film 14, and the semiconductor layer 15 of each of the active elements are disposed thereon. Each TFT 18 further includes a drain electrode 16 and a source electrode 17. The TFTs 18 are overlaid with an insulating film 19. Anode 21 included in the organic light-emitting devices 26 is coupled to the source electrodes 17 through contact holes 20 provided in the insulating film 19.

The mode of electrical connection between the electrodes (anode 21 and cathode 23) included in each organic light-emitting device 26 and the electrodes (source electrode 17 and drain electrode 16) included in a corresponding one of the TFTs 18 is not limited to the mode illustrated in FIG. 1B. That is, it is sufficient that any one of the anode 21 and the cathode 23 is electrically coupled to any one of the source electrode 17 and the drain electrode 16 of the TFT 18. The term “TFT” refers to a thin-film transistor.

In the display apparatus 100 illustrated in FIG. 1B, although each organic compound layer 22 is illustrated as a single layer, the organic compound layer 22 may include multiple layers. To reduce the deterioration of the organic light-emitting devices 26, a first protective layer 24 and a second protective layer 25 are disposed on the cathodes 23.

In the display apparatus 100 illustrated in FIG. 1B, although the transistors are used as switching devices, other switching devices may be used instead.

The transistors used in the display apparatus 100 illustrated in FIG. 1B are not limited to transistors using a single-crystal silicon wafer, but may also be thin-film transistors including active layers on the insulating surface of a substrate. Examples of the material of the active layers include single-crystal silicon, non-single-crystal silicon, such as amorphous silicon and microcrystalline silicon; and non-single-crystal oxide semiconductors, such as indium zinc oxide and indium gallium zinc oxide. Thin-film transistors are also called TFT elements.

The transistors in the display apparatus 100 illustrated in FIG. 1B may be formed in the substrate, such as a Si substrate. The expression “formed in the substrate” indicates that the transistors are produced by processing the substrate, such as a Si substrate. In the case where the transistors are formed in the substrate, the substrate and the transistors can be deemed to be integrally formed.

In the organic light-emitting device according to the present embodiment, the luminance is controlled by the TFT devices, which are an example of switching devices; thus, an image can be displayed at respective luminance levels by arranging multiple organic light-emitting devices in the plane. The switching devices according to the present embodiment are not limited to the TFT devices and may be low-temperature polysilicon transistors or active-matrix drivers formed on a substrate such as a Si substrate. The expression “on a substrate” can also be said to be “in the substrate”. Whether transistors are formed in the substrate or TFT devices are used is selected in accordance with the size of a display unit. For example, when the display unit has a size of about 0.5 inches, organic light-emitting devices are preferably disposed on a Si substrate.

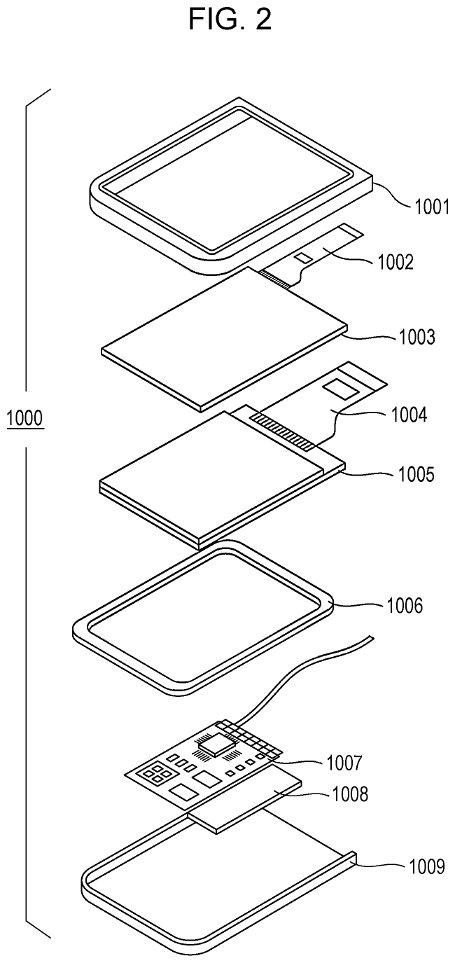

FIG. 2 is a schematic view illustrating an example of a display apparatus according to the present embodiment. A display apparatus 1000 may include a touch panel 1003, a display panel 1005, a frame 1006, a circuit substrate 1007, and a battery 1008 disposed between an upper cover 1001 and a lower cover 1009. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones such as smartphones, tablets, and head-mounted displays.

The display apparatus according to the present embodiment may be used for a display unit of an image pickup apparatus including an optical unit including multiple lenses and an image pickup device that receives light passing through the optical unit. The image pickup apparatus may include a display unit that displays information acquired by the image pickup device. The display unit may be a display unit exposed to the outside of the image pickup apparatus or a display unit disposed in a finder. The image pickup apparatus may be a digital camera or a digital camcorder.

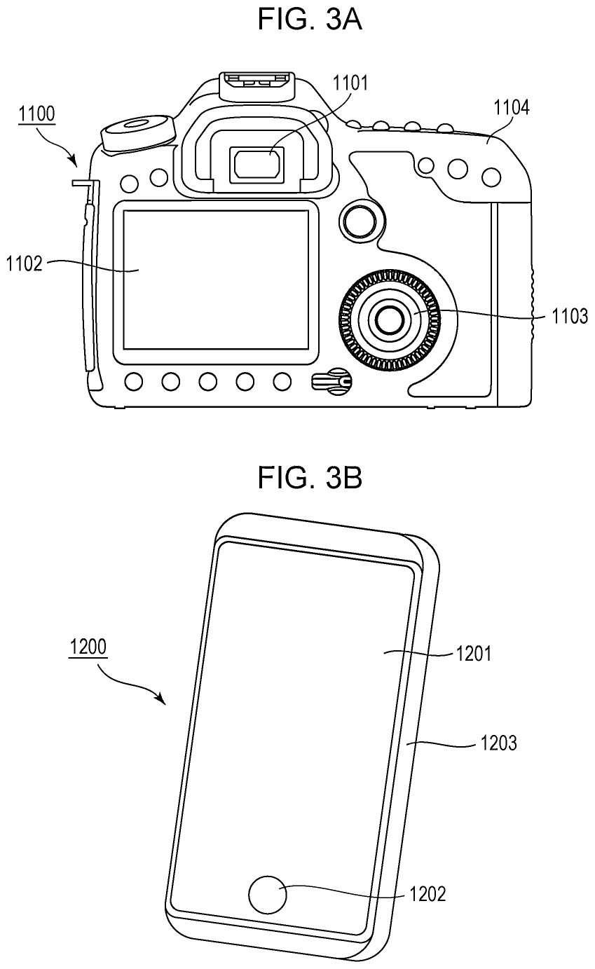

FIG. 3A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 may include the display apparatus according to the present embodiment. In this case, the display apparatus may display environmental information, imaging instructions, and so forth in addition to an image to be captured. The environmental information may include, for example, the intensity of external light, the direction of external light, the moving speed of a subject, and the possibility that a subject is shielded by a shielding material.

The timing suitable for imaging is only for a short time; thus, the information may be displayed as soon as possible. Accordingly, it is preferable to use a display apparatus including the organic light-emitting device of the present embodiment. This is because the organic light-emitting device has a fast response time. The display apparatus including the organic light-emitting device can be used more suitably than liquid crystal displays for such apparatuses required to have a high display speed.

The image pickup apparatus 1100 includes an optical unit, which is not illustrated. The optical unit includes multiple lenses and is configured to form an image on an image pickup device in the housing 1104. The relative positions of the multiple lenses can be adjusted to adjust the focal point. This operation can also be performed automatically. The image pickup apparatus may translate to a photoelectric conversion apparatus. Examples of an image capturing method employed in the photoelectric conversion apparatus may include a method for detecting a difference from the previous image and a method of cutting out an image from images always recorded, instead of sequentially capturing images.

FIG. 3B is a schematic view illustrating an example of an electronic apparatus according to the present embodiment. An electronic apparatus 1200 includes a display unit 1201, an operation unit 1202, and a housing 1203. The housing 1203 may accommodate a circuit, a printed circuit board including the circuit, a battery, and a communication unit. The operation unit 1202 may be a button or a touch-screen-type reactive unit. The operation unit 1202 may be a biometric recognition unit that recognizes a fingerprint to release the lock or the like. An electronic apparatus having a communication unit can also be referred to as a communication apparatus. The electronic apparatus 1200 may further have a camera function by being equipped with a lens and an image pickup device. An image captured by the camera function is displayed on the display unit 1201. Examples of the electronic apparatus 1200 include smartphones and notebook computers.

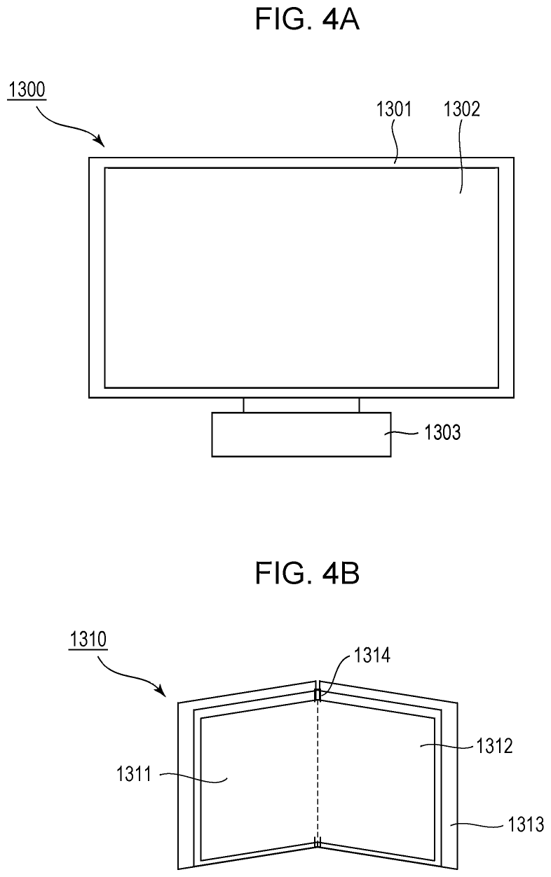

FIGS. 4A and 4B are each a schematic view illustrating an example of the display apparatus according to the present embodiment. FIG. 4A illustrates a display apparatus, such as a television monitor or a PC monitor. A display apparatus 1300 includes a frame 1301 and a display unit 1302. The light-emitting device according to the present embodiment may be used for the display unit 1302. The display apparatus 1300 includes a base 1303 that supports the frame 1301 and the display unit 1302. The base 1303 is not limited to the structure illustrated in FIG. 4A. The lower side of the frame 1301 may also serve as a base. The frame 1301 and the display unit 1302 may be curved. These may have a radius of curvature of 5,000 mm or more and 6,000 mm or less.

FIG. 4B is a schematic view illustrating another example of a display apparatus according to the present embodiment. A display apparatus 1310 illustrated in FIG. 4B can be folded and is what is called a foldable display apparatus. The display apparatus 1310 includes a first display portion 1311, a second display portion 1312, a housing 1313, and an inflection point 1314. The first display portion 1311 and the second display portion 1312 may include the light-emitting device according to the present embodiment. The first display portion 1311 and the second display portion 1312 may be a single, seamless display apparatus. The first display portion 1311 and the second display portion 1312 can be divided from each other at the inflection point. The first display portion 1311 and the second display portion 1312 may display different images. Alternatively, a single image may be displayed in the first and second display portions.

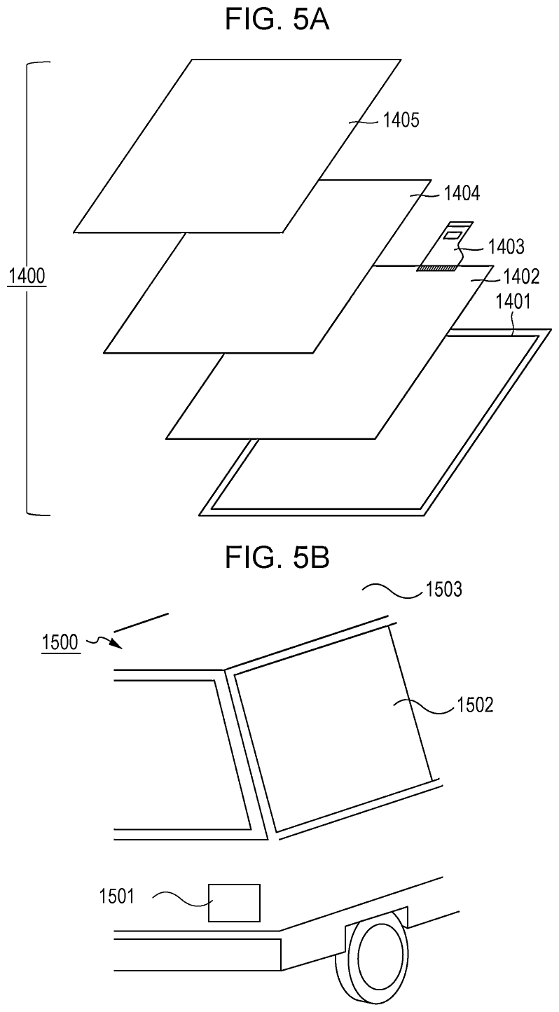

FIG. 5A is a schematic view illustrating an example of a lighting apparatus according to the present embodiment. A lighting apparatus 1400 may include a housing 1401, a light source 1402, a circuit board 1403, an optical filter 1404 that transmits light emitted from the light source 1402, and a light diffusion unit 1405. The light source 1402 may include an organic light-emitting device according to the present embodiment. The optical filter 1404 may be a filter that improves the color rendering properties of the light source. The light diffusion unit 1405 can effectively diffuse light from the light source to deliver the light to a wide range when used for illumination and so forth. The optical filter 1404 and the light diffusion unit 1405 may be disposed at the light emission side of the lighting apparatus. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided. The lighting apparatus may include the organic light-emitting device of the present embodiment and a power supply circuit coupled thereto. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release heat in the device to the outside of the device and is composed of, for example, a metal having a high specific heat and liquid silicone.

FIG. 5B is a schematic view illustrating an automobile as an example of a moving object according to the present embodiment. The automobile includes a tail lamp, which is an example of lighting units. An automobile 1500 includes a tail lamp 1501 and may be configured to light the tail lamp when a brake operation or the like is performed.

The tail lamp 1501 may include an organic light-emitting device according to the present embodiment. The tail lamp 1501 may include a protective member that protects the organic light-emitting device. The protective member may be composed of any transparent material with some degree of high strength and is preferably composed of polycarbonate, for example. The polycarbonate may be mixed with, for example, a furandicarboxylic acid derivative or an acrylonitrile derivative.

The automobile 1500 may include an automobile body 1503 and windows 1502 attached thereto. The windows 1502 may be transparent displays if the windows are not used to check the front and back of the automobile. The transparent displays may include an organic light-emitting device according to the present embodiment. In this case, the components, such as the electrodes, of the organic light-emitting device are formed of transparent members.

The moving object according to the present embodiment may be, for example, a ship, an aircraft, or a drone. The moving object may include a body and a lighting unit attached to the body. The lighting unit may emit light to indicate the position of the body. The lighting unit includes the organic light-emitting device according to the present embodiment.

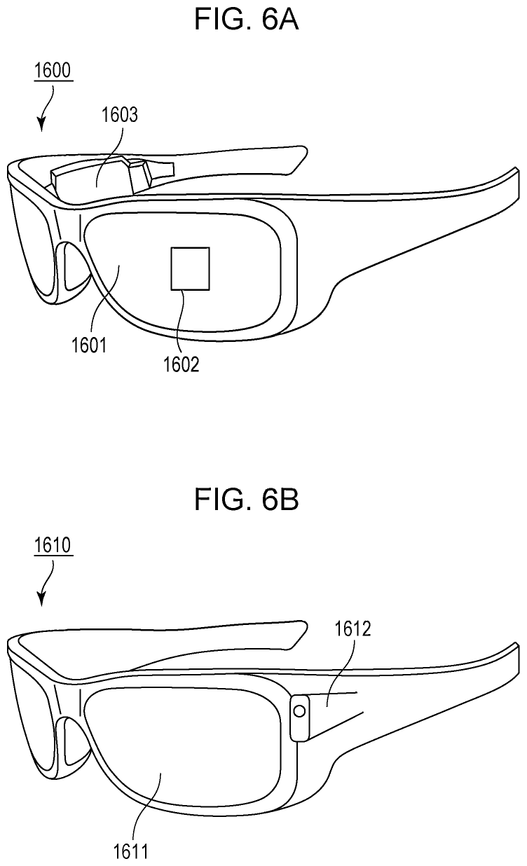

Examples of applications of the display apparatuses of the above embodiments will be described with reference to FIGS. 6A and 6B. The display apparatuses can be used for systems that can be worn as wearable devices, such as smart glasses, HMDs, and smart contacts. An image pickup and display apparatus used in such an example of the applications has an image pickup apparatus that can photoelectrically convert visible light and a display apparatus that can emit visible light.

FIG. 6A is a schematic view illustrating an example of a wearable device according to an embodiment of the present invention. Glasses 1600 (smart glasses) according to an example of applications will be described with reference to FIG. 6A. An image pickup apparatus 1602, such as a CMOS sensor or SPAD, is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power source that supplies electric power to the image pickup apparatus 1602 and the display apparatus. The control unit 1603 controls the operation of the image pickup apparatus 1602 and the display apparatus. The lens 1601 has an optical system for focusing light on the image pickup apparatus 1602.

FIG. 6B is a schematic view illustrating another example of a wearable device according to an embodiment of the present invention. Glasses 1610 (smart glasses) according to an example of applications will be described with reference to FIG. 6B. The glasses 1610 include a control unit 1612. The control unit 1612 includes an image pickup apparatus corresponding to the image pickup apparatus 1602 illustrated in FIG. 6A and a display apparatus. A lens 1611 is provided with the image pickup apparatus in the control unit 1612 and an optical system that projects light emitted from the display apparatus. An image is projected onto the lens 1611. The control unit 1612 functions as a power source that supplies electric power to the image pickup apparatus and the display apparatus and controls the operation of the image pickup apparatus and the display apparatus.

The control unit 1612 may include a gaze detection unit that detects the gaze of a wearer. Infrared light may be used for gaze detection. An infrared light-emitting unit emits infrared light to an eyeball of a user who is gazing at a displayed image. An image of the eyeball is captured by detecting the reflected infrared light from the eyeball with an image pickup unit having light-receiving elements. The deterioration of image quality is reduced by providing a reduction unit that reduces light from the infrared light-emitting unit to the display unit when viewed in plan. The user's gaze at the displayed image is detected from the image of the eyeball captured with the infrared light. Any known method can be employed to the gaze detection using the captured image of the eyeball. As an example, a gaze detection method based on a Purkinje image of the reflection of irradiation light on a cornea can be employed. More specifically, the gaze detection process is based on a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present invention may include an image pickup apparatus including light-receiving elements, and may control an image displayed on the display apparatus based on the gaze information of the user from the image pickup apparatus. Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view and the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can be used. The smart glasses can display the captured external information in real time.

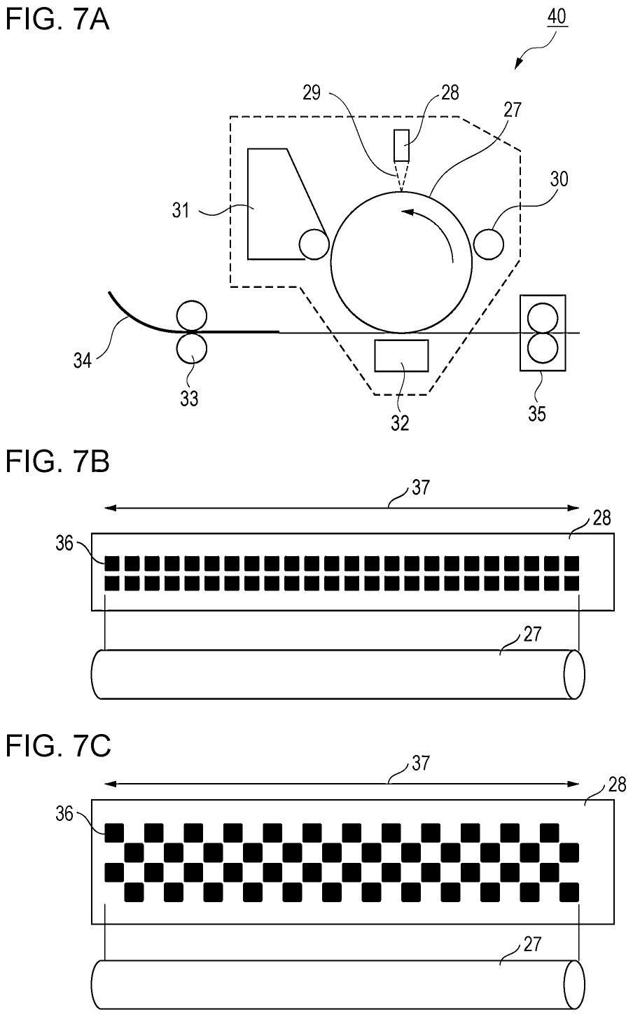

FIG. 7A is a schematic view of an example of an image-forming apparatus according to an embodiment of the present invention. An image-forming apparatus 40 is an electrophotographic image-forming apparatus and includes a photoconductor 27, an exposure light source 28, a charging unit 30, a developing unit 31, a transfer unit 32, a transport roller 33, and a fusing unit 35. The irradiation of light 29 is performed from the exposure light source 28 to form an electrostatic latent image on the surface of the photoconductor 27. The exposure light source 28 includes the organic light-emitting device according to the present embodiment. The developing unit 31 contains, for example, a toner. The charging unit 30 charges the photoconductor 27. The transfer unit 32 transfers the developed image to a recording medium 34. The transport roller 33 transports the recording medium 34. The recording medium 34 is paper, for example. The fusing unit 35 fixes the image formed on the recording medium 34.

FIGS. 7B and 7C each illustrate the exposure light source 28 and are each a schematic view illustrating multiple light-emitting portions 36 arranged on a long substrate. Arrows 37 are parallel to the axis of the photoconductor and each represent the row direction in which the organic light-emitting devices are arranged. The row direction is the same as the direction of the axis on which the photoconductor 27 rotates. This direction can also be referred to as the long-axis direction of the photoconductor 27. FIG. 7B illustrates a configuration in which the light-emitting portions 36 are arranged in the long-axis direction of the photoconductor 27. FIG. 7C is different from FIG. 7B in that the light-emitting portions 36 are arranged alternately in the row direction in a first row and a second row. The first row and the second row are located at different positions in the column direction. In the first row, the multiple light-emitting portions 36 are spaced apart. The second row has the light-emitting portions 36 at positions corresponding to the positions between the light-emitting portions 36 in the first row. In other words, the multiple light-emitting portions 36 are also spaced apart in the column direction. The arrangement in FIG. 7C can be rephrased as, for example, a lattice arrangement, a staggered arrangement, or a checkered pattern.

As described above, the use of an apparatus including the organic light-emitting device according to the present embodiment enables a stable display with good image quality even for a long time.

### EXAMPLES

Examples will be described below. However, the present invention is not limited thereto.

### Example 1 (Synthesis of Exemplified Compound A1)

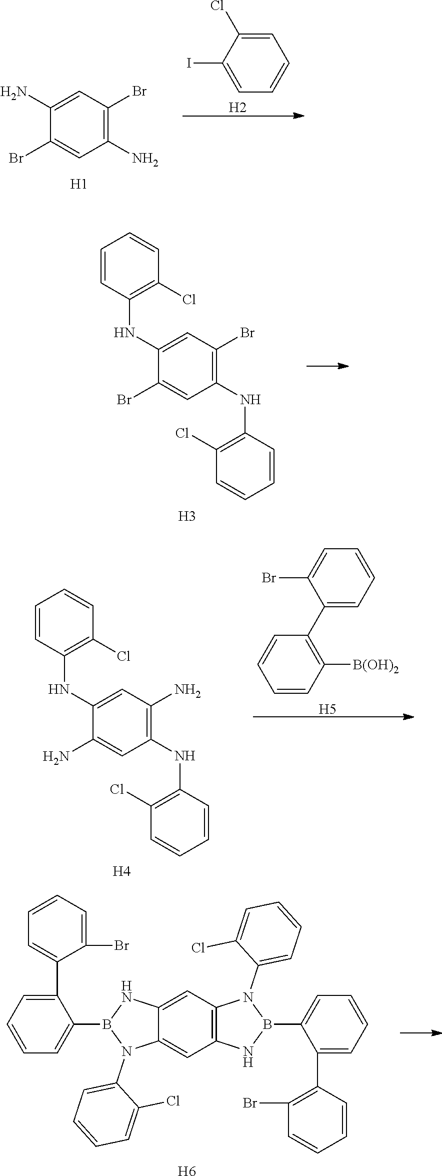

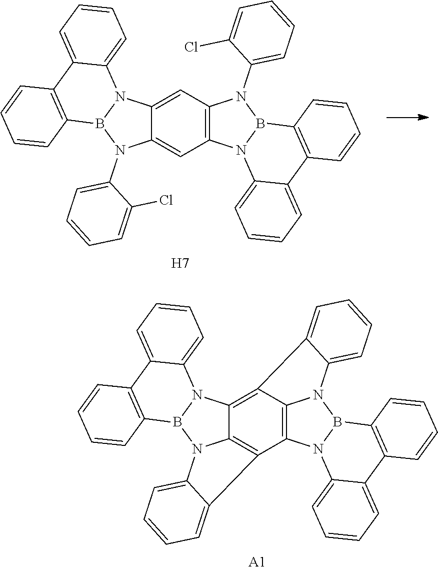

### (1) Synthesis of Compound H3

Reagents and a solvent, described below, were placed in a 500-ml recovery flask.
Compound H1: 5.00 g (18.8 mmol)
Compound H2: 8.97 g (37.6 mmol)
Pd(dba)₂: 324 mg (0.56 mmol)
DPPF: 1.04 g (1.88 mmol)
t-BuONa: 3.61 g (37.6 mmol)
Toluene: 200 ml

The reaction solution was heated to 90° C. under a stream of nitrogen and stirred at this temperature (90° C.) for 5 hours. After completion of the reaction, extraction was performed with toluene and water, followed by concentration. The resulting concentrate was purified by silica gel column chromatography (toluene) to give 4.76 g (yield: 52%) of pale purple compound H3.

### (2) Synthesis of Compound H4

Reagents and a solvent, described below, were placed in a 200-ml recovery flask.
Compound H3: 4.50 g (9.24 mmol)
LiHMDS (in THF 1.0 M): 19.4 mL (19.4 mmol)
Pd(dba)₂: 106 mg (0.18 mmol)
P(BP) (Cy)₂: 162 mg (0.46 mmol)
THF: 100 ml

The reaction solution was heated to 65° C. under a stream of nitrogen and stirred at this temperature (65° C.) for 3 hours. After the reaction was completed, quenching was performed with dilute hydrochloric acid, and the mixture was neutralized with an aqueous sodium hydroxide solution and an aqueous sodium bicarbonate solution. Extraction was performed with toluene and water, followed by concentration. The resulting concentrate was purified by silica gel column chromatography (toluene) to give 1.56 g (yield: 47%) of purple compound H4.

### (3) Synthesis of Compound H6

Reagents and a solvent, described below, were placed in a 100-ml recovery flask.
Compound H4: 1.50 g (4.18 mmol)
Compound H5: 2.32 g (8.36 mmol)
Toluene: 60 ml

The reaction solution was heated to 120° C. under a stream of nitrogen and stirred at this temperature (120° C.) for 6 hours. Then 30 ml of the solvent was removed by evaporation, followed by the addition of heptane. The solid was collected by filtration to give 2.18 g (yield: 62%) of pale yellow compound H6.

### (4) Synthesis of Compound H7

Reagents and a solvent, described below, were placed in a 200-ml recovery flask.
Compound H6: 2.00 g (2.38 mmol)
Pd(dba)₂: 41 mg (0.07 mmol)
DPPF: 132 mg (0.24 mmol)
t-BuONa: 915 mg (9.52 mmol)
Toluene: 100 ml

The reaction solution was heated to 120° C. under a stream of nitrogen and stirred at this temperature (120° C.) for 5 hours. After completion of the reaction, extraction was performed with dichloromethane and water, followed by concentration. The resulting concentrate was purified by silica gel column chromatography (dichloromethane:heptane) to give 501 mg (yield: 31%) of pale yellow compound H7.

### (5) Synthesis of Exemplified Compound A1

Reagents and a solvent, described below, were placed in a 100-ml recovery flask.
Compound H7: 500 mg (0.74 mmol)
Pd(OAc)₂: 16 mg (0.07 mmol)
P(t-Bu)₃: 45 mg (0.22 mmol)
DBU: 451 mg (2.96 mmol)
o-Xylene: 50 ml

The reaction solution was heated to 140° C. under a stream of nitrogen and stirred at this temperature (140° C.) for 6 hours. After completion of the reaction, methanol was added. The resulting solid was collected by filtration and washed with water and methanol. The resulting crude product was purified by silica gel column chromatography (dichloromethane:heptane) to give 112 mg (yield: 25%) of yellow compound A1.

Exemplified compound A1 was subjected to mass spectrometry with MALDI-TOF-MS (Autoflex LRF, manufactured by Bruker).

### MALDI-TOF-MS

Measured value: m/z=606, calculated value: C₄₂H₂₄B₂N₄=606

### Examples 2 to 22 (Syntheses of Exemplified Compounds)

As presented in Tables 3 to 6, exemplified compounds of Examples 2 to 22 were synthesized as in Example 1, except that raw material H1 of Example 1 was changed to raw material 1, raw material H2 to raw material 2, and raw material H5 to raw material 3. The resulting exemplified compounds were subjected to mass spectrometry as in Example 1, and the measured values of m/z are also presented.

TABLE 3

| | Exemplified | | | | |
|---|---|---|---|---|---|
| Example | compound | Raw material 1 | Raw material 2 | Raw material 3 | m/z |
| 2 | A3 | 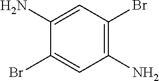 | 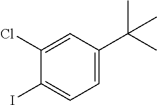 | 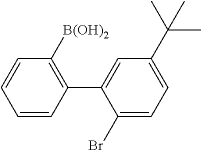 [SMILES: CC(C)(C)c1ccc(Br)c(-c2ccccc2B(O)O)c1] | 831 |
| 3 | A4 | 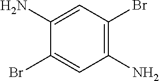 | 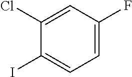 | 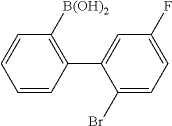 [SMILES: OB(O)c1ccccc1-c1cc(F)ccc1Br] | 678 |
| 4 | A8 | 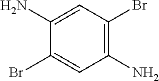 | 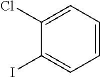 | 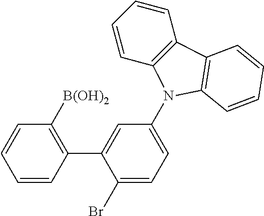 [SMILES: OB(O)c1ccccc1-c1cc(-n2c3ccccc3c3ccccc32)ccc1Br] | 937 |
| 5 | A10 | 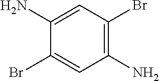 | 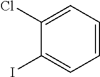 | 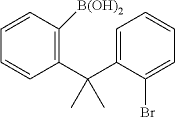 [SMILES: CC(C)(c1ccccc1Br)c1ccccc1B(O)O] | 690 |
| 6 | A12 | 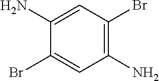 | 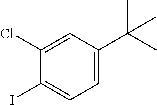 | 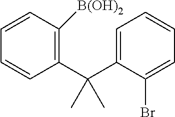 [SMILES: CC(C)(c1ccccc1Br)c1ccccc1B(O)O] | 803 |
| 7 | A16 | 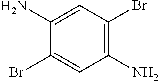 | 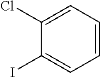 | 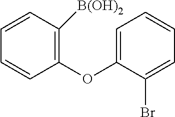 [SMILES: OB(O)c1ccccc1Oc1ccccc1Br] | 638 |
| 8 | A19 | 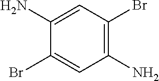 | 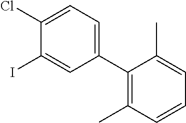 [SMILES: Cc1cccc(C)c1-c1ccc(Cl)c(I)c1] | 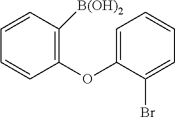 [SMILES: OB(O)c1ccccc1Oc1ccccc1Br] | 847 |

TABLE 4

| | Exemplified | Raw material | Raw material | | |
|---|---|---|---|---|---|
| Example | compound | 1 | 2 | Raw material 3 | m/z |
| 9 | B1 | 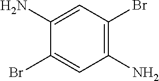 | 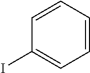 | 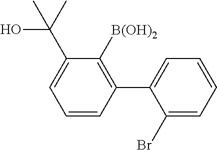 [SMILES: CC(C)(O)c1cccc(-c2ccccc2Br)c1B(O)O] | 690 |
| 10 | B10 | 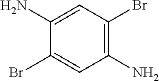 | 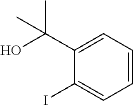 | 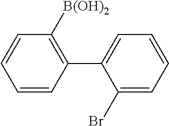 [SMILES: OB(O)c1ccccc1-c1ccccc1Br] | 690 |
| 11 | B12 | 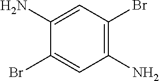 | 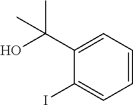 | 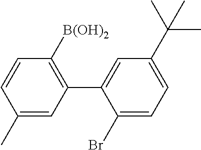 [SMILES: Cc1ccc(B(O)O)c(-c2cc(C(C)(C)C)ccc2Br)c1] | 859 |
| 12 | C1 | 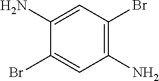 | 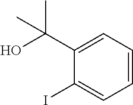 | 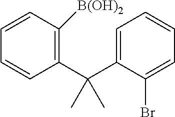 [SMILES: CC(C)(c1ccccc1Br)c1ccccc1B(O)O] | 775 |
| 13 | C4 | 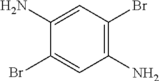 | 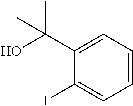 | 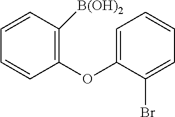 [SMILES: OB(O)c1ccccc1Oc1ccccc1Br] | 722 |

TABLE 5

| | Exemplified | Raw material | Raw material | Raw material | |
|---|---|---|---|---|---|
| Example | compound | 1 | 2 | 3 | m/z |
| 14 | D8 | 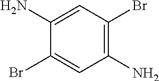 | 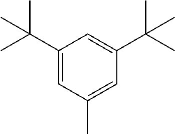 | 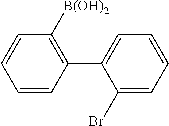 [SMILES: OB(O)c1ccccc1-c1ccccc1Br] | 835 |
| 15 | D10 | 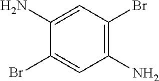 | 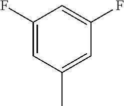 | 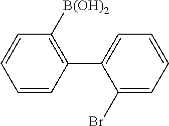 [SMILES: OB(O)c1ccccc1-c1ccccc1Br] | 682 |
| 16 | D14 | 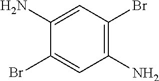 | 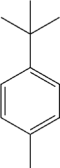 | 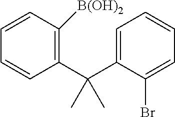 [SMILES: CC(C)(c1ccccc1Br)c1ccccc1B(O)O] | 807 |

TABLE 6

| | Exemplified | Raw material | Raw | | |
|---|---|---|---|---|---|
| Example | compound | 1 | material 2 | Raw material 3 | m/z |
| 17 | E2 | 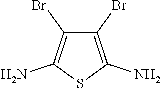 | 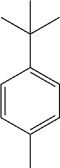 | 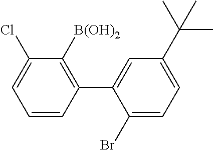 [SMILES: CC(C)(C)c1ccc(Br)c(-c2cccc(Cl)c2B(O)O)c1] | 837 |
| 18 | E3 | 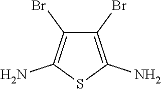 | 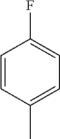 | 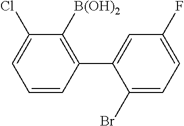 [SMILES: OB(O)c1c(Cl)cccc1-c1cc(F)ccc1Br] | 684 |
| 19 | E7 | 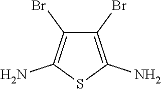 | 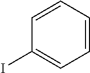 | 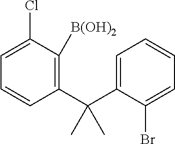 [SMILES: CC(C)(c1ccccc1Br)c1cccc(Cl)c1B(O)O] | 696 |
| 20 | E9 | 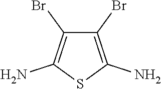 | 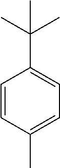 | 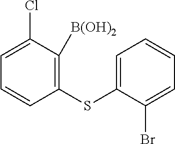 [SMILES: OB(O)c1c(Cl)cccc1Sc1ccccc1Br] | 789 |
| 21 | E10 | 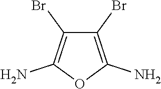 | 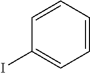 | 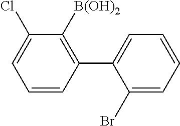 [SMILES: OB(O)c1c(Cl)cccc1-c1ccccc1Br] | 680 |
| 22 | E15 | 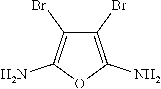 | 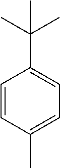 | 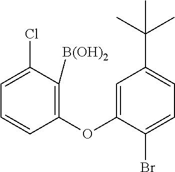 [SMILES: CC(C)(C)c1ccc(Br)c(Oc2cccc(Cl)c2B(O)O)c1] | 853 |

### Examples 23 to 33 (Syntheses of Exemplified Compounds)

As presented in Tables 7 and 8, exemplified compounds of Examples 23 to 33 were synthesized as in Example 1, except that raw material H1 of Example 1 was changed to raw material 1, raw material H2 was changed to raw material 2, raw material H5 was changed to raw material 3, and raw material 4 was added as a raw material for the synthesis in (4) of Example 1. The resulting exemplified compounds were subjected to mass spectrometry as in Example 1, and the measured values of m/z are also presented.

TABLE 7

| | Exemplified | | Raw | | | |
|---|---|---|---|---|---|---|
| Example | compound | Raw material 1 | material 2 | Raw material 3 | Raw material 4 | m/z |
| 23 | D2 | 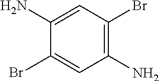 | 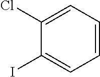 | 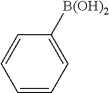 | 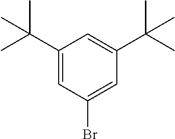 | 835 |
| 24 | D4 | 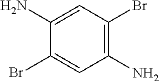 | 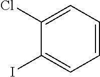 | 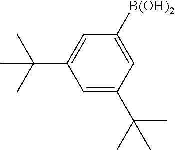 [SMILES: CC(C)(C)c1cc(B(O)O)cc(C(C)(C)C)c1] | 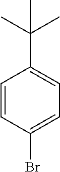 | 947 |
| 25 | D6 | 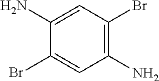 | 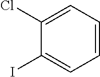 | 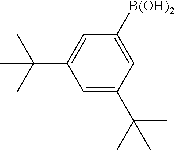 [SMILES: CC(C)(C)c1cc(B(O)O)cc(C(C)(C)C)c1] | 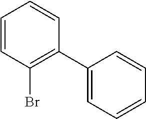 [SMILES: Brc1ccccc1-c1ccccc1] | 987 |

TABLE 8

| | Exemplified | | Raw | | Raw material | |
|---|---|---|---|---|---|---|
| Example | compound | Raw material 1 | material 2 | Raw material 3 | 4 | m/z |
| 26 | F2 | 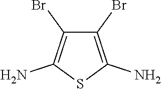 | 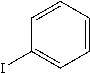 | 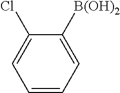 | 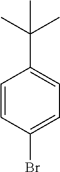 | 729 |
| 27 | F4 | 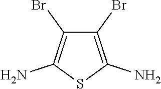 | 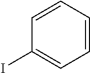 | 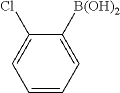 | 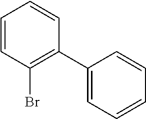 [SMILES: Brc1ccccc1-c1ccccc1] | 769 |
| 28 | F5 | 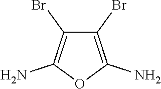 | 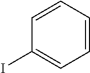 | 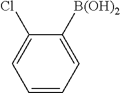 | 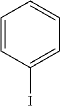 | 600 |
| 29 | F10 | 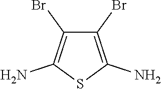 | 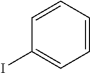 | 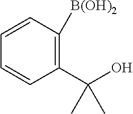 | 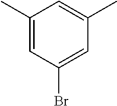 | 757 |
| 30 | F12 | 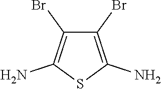 | 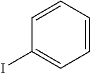 | 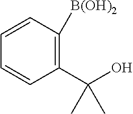 | 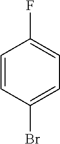 | 737 |
| 31 | F13 | 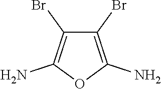 | 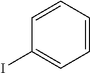 | 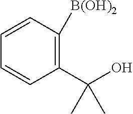 | 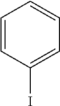 | 684 |
| 32 | F15 | 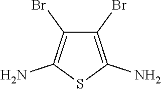 | 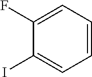 | 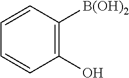 | 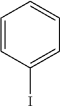 | 648 |
| 33 | F19 | 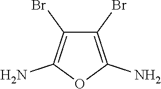 | 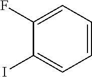 | 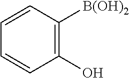 | 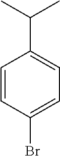 | 716 |

### Example 34

In this Example, an organic EL device having a bottom-emission structure was produced in which an anode, a hole injection layer, a hole transport layer, an electron-blocking layer, a light-emitting layer, a hole-blocking layer, an electron transport layer, an electron injection layer, and a cathode were sequentially formed over a substrate.

An ITO film was formed on a glass substrate and subjected to desired patterning to form an ITO electrode (anode). The ITO electrode had a thickness of 100 nm. The substrate on which the ITO electrode had been formed in this way was used as an ITO substrate in the following steps. Next, vacuum evaporation was performed by resistance heating in a vacuum chamber to successively form organic EL layers and an electrode layer presented in Table 9 on the ITO substrate. Here, the opposing electrode (metal electrode layer, cathode) had an electrode area of 3 mm².

TABLE 9

| | | | | Thickness |
|---|---|---|---|---|
| | Material | | | (nm) |
| Cathode | Al | | | 100 |
| Electron injection | LiF | | | 1 |
| layer (EIL) | | | | |
| Electron transport | ET2 | | | 15 |
| layer (ETL) | | | | |
| Hole-blocking | ET12 | | | 15 |
| layer (HBL) | | | | |
| Light-emitting | Host | EM4 | Ratio by mass | 20 |
| layer (EML) | Guest | Al | EM4:A1 = | |
| | | | 99:1 | |
| Electron-blocking | HT12 | | | 15 |
| layer (EBL) | | | | |
| Hole transport | HT3 | | | 30 |
| layer (HTL) | | | | |
| Hole injection | HT16 | | | 5 |
| layer (HIL) | | | | |

The characteristics of the resulting device were measured and evaluated. The light-emitting device exhibited blue light emission with a maximum current efficiency of 13.2 cd/A. With regard to measurement instruments, specifically, the current-voltage characteristics were measured with a Hewlett-Packard 4140B microammeter, and the luminance was measured with a Topcon BM7. The device was subjected to a continuous operation test at a current density of 20 mA/cm². The time when the percentage of luminance degradation reached 5% (LT95) was measured and found to be 139 hours.

### Examples 35 to 56 and Comparative Examples 1 and 2

Organic light-emitting devices were produced in the same manner as in Example 34, except that the compounds were changed to compounds given in Table 10 as appropriate. The characteristics of the resulting devices were measured and evaluated as in Example 34. Table 10 presents the measurement results. Comparative compounds 1-a and 2-a used in the comparative examples are compound 1-a described in Non Patent Literature 1 and compound 2-a described in Patent Literature 1, respectively.

TABLE 10

| | | | | EML | | | | | | |
|---|---|---|---|---|---|---|---|---|---|---|
| | | | | | Light- | | | Current | | |
| | | | | | emitting | | | efficiency | LT95 | Emission |
| | HIL | HTL | EBL | Host | material | HBL | ETL | [cd/A] | [h] | color |
| Example 35 | HT16 | HT3 | HT12 | EM27 | A3 | ET10 | ET2 | 14.8 | 135 | Blue |
| Example 36 | HT16 | HT3 | HT9 | EM5 | A4 | ET12 | ET2 | 14.7 | 131 | Blue |
| Example 37 | HT16 | HT3 | HT12 | EM26 | A10 | ET12 | ET2 | 14.3 | 133 | Blue |
| Example 38 | HT16 | HT3 | HT12 | EM4 | A19 | ET12 | ET2 | 14.8 | 138 | Blue |
| Example 39 | HT16 | HT3 | HT12 | EM4 | B1 | ET12 | ET2 | 13.9 | 124 | Blue |
| Example 40 | HT16 | HT3 | HT12 | EM4 | B10 | ET12 | ET2 | 13.8 | 126 | Blue |
| Example 41 | HT16 | HT3 | HT12 | EM4 | C1 | ET12 | ET2 | 13.5 | 119 | Blue |
| Example 42 | HT16 | HT3 | HT12 | EM4 | C4 | ET12 | ET2 | 13.4 | 118 | Blue |
| Example 43 | HT16 | HT3 | HT12 | EM27 | D2 | ET12 | ET5 | 12.4 | 107 | Blue |
| Example 44 | HT16 | HT3 | HT9 | EM27 | D4 | ET12 | ET5 | 12.6 | 106 | Blue |
| Example 45 | HT16 | HT3 | HT12 | EM4 | D6 | ET12 | ET2 | 12.6 | 109 | Blue |
| Example 46 | HT16 | HT3 | HT12 | EM4 | D8 | ET12 | ET2 | 12.7 | 107 | Blue |
| Example 47 | HT16 | HT2 | HT12 | EM26 | D14 | ET10 | ET2 | 12.5 | 104 | Blue |
| Example 48 | HT16 | HT3 | HT12 | EM4 | E2 | ET12 | ET2 | 13.9 | 131 | Blue |
| Example 49 | HT16 | HT3 | HT12 | EM4 | E7 | ET12 | ET2 | 14.1 | 127 | Blue |
| Example 50 | HT16 | HT3 | HT9 | EM3 | E12 | ET10 | ET2 | 14.1 | 125 | Blue |
| Example 51 | HT16 | HT3 | HT12 | EM27 | F2 | ET12 | ET5 | 12.9 | 104 | Blue |
| Example 52 | HT16 | HT3 | HT12 | EM4 | F4 | ET12 | ET2 | 12.8 | 106 | Blue |
| Example 53 | HT16 | HT3 | HT9 | EM27 | F5 | ET12 | ET5 | 12.7 | 104 | Blue |
| Example 54 | HT16 | HT3 | HT12 | EM4 | F10 | ET12 | ET2 | 12.9 | 105 | Blue |
| Example 55 | HT16 | HT3 | HT12 | EM4 | F15 | ET12 | ET2 | 12.6 | 104 | Blue |
| Example 56 | HT16 | HT2 | HT12 | EM26 | F19 | ET10 | ET2 | 12.7 | 106 | Blue |
| Comparative | HT16 | HT3 | HT12 | EM4 | Comparative | ET12 | ET2 | 7.5 | 75 | Blue- |
| Example 1 | | | | | compound | | | | | violet |
| | | | | | 1-a | | | | | |
| Comparative | HT16 | HT3 | HT12 | EM4 | Comparative | ET12 | ET2 | 10.9 | 79 | Blue- |
| Example 2 | | | | | compound | | | | | violet |
| | | | | | 2-a | | | | | |

From Table 10, in Comparative Examples 1 and 2 in which comparative compound 1-a and comparative compound 2-a were used respectively, the current efficiency was 10.9 cd/A or less, and the 5% degradation lifetime (LT95) was 80 hours or less, which were inferior to the current efficiencies and the durability characteristics of the blue light-emitting devices of the examples. In contrast, the devices containing the organic compounds of the present embodiment exhibited good durability characteristics. This is because each of the compounds according to the present embodiment has a bisdiazaborole skeleton with a fused-ring structure, has an emission wavelength suitable for blue light emission, is stable as a molecular structure due to the fused-ring structure, has a low LUMO level, and has high stability against oxygen.

### Example 57

An organic light-emitting device was produced in the same manner as in Example 34, except that the compounds were changed to compounds given in Table 11 as appropriate. The characteristics of the resulting devices were measured and evaluated as in Example 34. The results indicated that good green light emission was obtained from the light-emitting device. The device was subjected to a continuous operation test at a current density of 100 mA/cm². The time when the percentage of luminance degradation reached 5% (LT95) was measured and found to be more than 500 hours.

TABLE 11

| | | | | Thickness |
|---|---|---|---|---|
| | Material | | | (nm) |
| Cathode | Al | | | 100 |
| Electron injection | LiF | | | 1 |
| layer (EIL) | | | | |
| Electron transport | ET2 | | | 10 |
| layer (ETL) | | | | |
| Hole-blocking | ET12 | | | 20 |
| layer (HBL) | | | | |
| Light-emitting | First host | EM3 | Ratio by mass | 30 |
| layer (EML) | Second host | A1 | EM3:A1:GD1 = | |
| | Guest | GD1 | 89.7:10.0:0.3 | |
| Electron-blocking | HT12 | | | 15 |
| layer (EBL) | | | | |
| Hole transport | HT3 | | | 30 |
| layer (HTL) | | | | |
| Hole injection | HT16 | | | 5 |
| layer (HIL) | | | | |

### Examples 58 to 72 and Comparative Examples 3 and 4

Organic light-emitting devices were produced in the same manner as in Example 57, except that the compounds were changed to compounds given in Table 12 as appropriate. In Examples 66 to 72 and Comparative Examples 3 and 4, the ratio by mass of the first host to the guest is 99.7:0.3. The characteristics of the resulting devices were measured and evaluated as in Example 57. Table 12 presents the measurement results.

TABLE 12

| | EML | | | Emission | LT95 |
|---|---|---|---|---|---|
| | First host | Second host | Guest | color | [h] |
| Example 58 | EM1 | A1 | GD1 | Green | 590 |
| Example 59 | EM1 | A16 | GD1 | Green | 510 |
| Example 60 | EM3 | B10 | GD1 | Green | 560 |
| Example 61 | EM1 | E2 | GD1 | Green | 530 |
| Example 62 | EM4 | A1 | RD1 | Red | 710 |
| Example 63 | EM3 | A16 | RD1 | Red | 620 |
| Example 64 | EM1 | B10 | RD1 | Red | 680 |
| Example 65 | EM15 | E2 | RD1 | Red | 650 |
| Example 66 | A16 | | GD1 | Green | 510 |
| Example 67 | B10 | | GD1 | Green | 540 |
| Example 68 | E2 | | GD1 | Green | 520 |
| Example 69 | A1 | | RD1 | Red | 600 |
| Example 70 | A16 | | RD1 | Red | 560 |
| Example 71 | B10 | | RD1 | Red | 590 |
| Example 72 | E2 | | RD1 | Red | 580 |
| Comparative | Comparative | | GD1 | Green | 250 |
| Example 3 | compound 1-a | | | | |
| Comparative | Comparative | | GD1 | Green | 300 |
| Example 4 | compound 2-a | | | | |

As presented in Table 12, in each of Comparative Examples 3 and 4, the 5% degradation lifetime is 500 hours or less, which indicates poor durability characteristics. In contrast, in each of the devices containing the organic compounds according to the present embodiment, the 5% degradation lifetime is more than 500 hours. That is, the lifetime is longer in each example. The devices containing the organic compounds of the present embodiment exhibit good durability characteristics.

### Example 73

In this Example, an organic EL device having a top-emission structure was produced in which an anode, a hole injection layer, a hole transport layer, an electron-blocking layer, a first light-emitting layer, a second light-emitting layer, a hole-blocking layer, an electron transport layer, an electron injection layer, and a cathode were sequentially formed over a substrate.

A laminated film of Al and Ti was formed on a glass substrate to a thickness of 40 nm by a sputtering method, and was patterned using photolithography to form an anode. Here, the opposing electrode (metal electrode layer, cathode) had an electrode area of 3 mm². Subsequently, the cleaned substrate on which the electrode had been formed and materials were attached to a vacuum evaporation apparatus (available from ULVAC, Inc.). The apparatus was evacuated to 1.3×10⁻⁴ Pa (1×10⁻⁶ Torr), and then UV/ozone cleaning was performed. Thereafter, each layer was formed so as to achieve the layer configuration given in Table 13. Finally, sealing was performed in a nitrogen atmosphere.

TABLE 13

| | | | | Thickness |
|---|---|---|---|---|
| | Material | | | (nm) |
| Cathode | Mg | | Ratio by mass | 10 |
| | Ag | | Mg:Ag = | |
| | | | 50:50 | |
| Electron | LiF | | | 1 |
| injection layer | | | | |
| (EIL) | | | | |
| Electron | ET2 | | | 25 |
| transport layer | | | | |
| (ETL) | | | | |
| Hole-blocking | ET12 | | | 80 |
| layer (HBL) | | | | |
| Second light- | Second host | EM1 | Ratio by mass | 15 |
| emitting layer | Second guest | A1 | EM1:A1 = | |
| (2nd EML) | (blue dopant) | | 99:1 | |
| First light- | First host | EM1 | Ratio by mass | 10 |
| emitting layer | First guest | RD1 | EM1:RD1:GD7 = | |
| (1st EML) | (red dopant) | | 96.7:0.3:3.0 | |
| | Third guest | GD7 | | |
| | (green dopant) | | | |
| Electron- | HT7 | | | 10 |
| blocking layer | | | | |
| (EBL) | | | | |
| Hole transport | HT2 | | | 20 |
| layer (HTL) | | | | |
| Hole injection | HT16 | | | 5 |
| layer (HIL) | | | | |

The characteristics of the resulting device were measured and evaluated. The resulting light-emitting device exhibited good white light emission. A continuous operation test was performed at an initial luminance of 1,000 cd/m², and the percentage of luminance degradation after 100 hours was measured and found to be 25%.

### Examples 74 to 77 and Comparative Examples 5 and 6

Organic light-emitting devices were produced in the same manner as in Example 73, except that the compounds were changed to compounds given in Table 14 as appropriate. The characteristics of the resulting devices were measured and evaluated as in Example 73. Table 14 presents the measurement results.

TABLE 14

| | | | | | | Percentage |
|---|---|---|---|---|---|---|
| | 1^{st} EML | | | 2^{nd} EML | | of luminance |
| | First | First | Third | Second | Second | degradation |
| | host | guest | guest | host | guest | [%] |
| Example 74 | EM27 | RD1 | GD7 | EM27 | A10 | 25 |
| Example 75 | EM1 | RD1 | GD6 | EM1 | B10 | 27 |
| Example 76 | EM1 | RD1 | GD7 | EM1 | E1 | 29 |
| Example 77 | EM4 | RD1 | GD7 | EM4 | F4 | 31 |
| Comparative | EM1 | RD1 | GD7 | EM1 | Compar- | 51 |
| Example 5 | | | | | ative | |
| | | | | | compound | |
| | | | | | 1-a | |
| Comparative | EM1 | RD1 | GD7 | EM1 | Compar- | 40 |
| Example 6 | | | | | ative | |
| | | | | | compound | |
| | | | | | 2-a | |

From Table 14, in the organic light-emitting devices containing comparative compound 1-a and comparative compound 2-a, the percentages of luminance degradation were 51% and 40%, respectively. This is due to the fact that when the comparative compounds are used as guests, the compounds have high LUMO levels and inferior stability against oxygen. In contrast, the devices containing the organic compounds of the present embodiment exhibited good durability characteristics. This is because each of the compounds according to the present embodiment has a bisdiazaborole skeleton with a fused-ring structure and has a low LUMO level and high stability against oxygen.

As described above, the organic compound according to the present embodiment has high luminous efficiency, high color purity, and a deep LUMO level (far from the vacuum level), and can emit blue light. Therefore, when the organic compound according to the present embodiment is used in an organic light-emitting device, it is possible to provide an organic light-emitting device with excellent color purity, luminous efficiency, and durability characteristics.

The organic compound according to the present invention is a blue light-emitting material having high luminous efficiency, high color purity, and a deep LUMO level (far from vacuum level). Therefore, it is possible to provide an organic light-emitting device having excellent color purity, luminous efficiency, and durability characteristics.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An organic compound represented by the following general formula [1-1] or [1-2]: 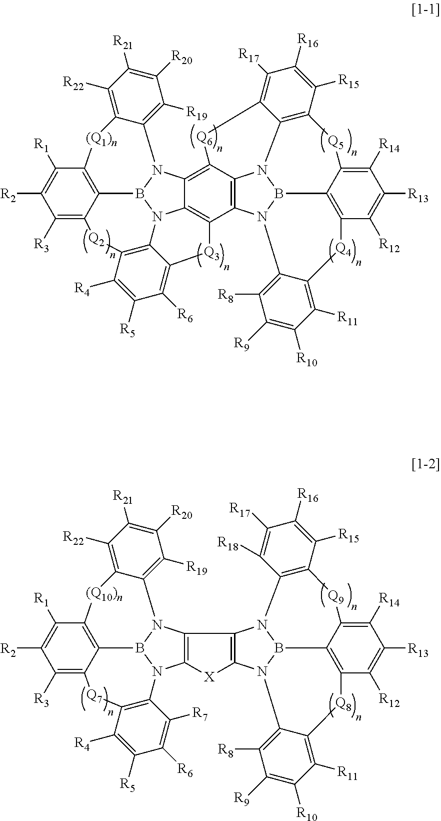
where in general formula [1-1] or [1-2], R₁ to R₂₂ are each independently selected from the group consisting of a hydrogen atom, a deuterium atom, a halogen atom, a cyano group, a substituted or unsubstituted alkyl group, a substituted or unsubstituted alkoxy group, a substituted or unsubstituted amino group, a substituted or unsubstituted aryl group, a substituted or unsubstituted aryloxy group, a substituted or unsubstituted heteroaryl group, a substituted or unsubstituted heteroaryloxy group, and a substituted or unsubstituted silyl group,
Q₁ to Q₁₀ are each independently selected from the group consisting of a direct bond and a linking group, the linking group is selected from the group consisting of C(R₂₃) (R₂₄), N(R₂₅), an oxygen atom, a sulfur atom, a selenium atom, and a tellurium atom, R₂₃ to R₂₅ are each independently selected from the group consisting of a hydrogen atom, a halogen atom, a substituted or unsubstituted alkyl group, a substituted or unsubstituted alkoxy group, a substituted or unsubstituted aryl group, and a substituted or unsubstituted heteroaryl group, R₂₃ and R₂₄ are optionally taken together to form a ring,
each n is 0 or 1, provided that in each of general formulae [1-1] and [1-2], at least one of n is 1,
X is selected from the group consisting of an oxygen atom, a sulfur atom, a selenium atom, a tellurium atom, and N(R₂₆), and R₂₆ is selected from the group consisting of a hydrogen atom, a halogen atom, a substituted or unsubstituted alkyl group, a substituted or unsubstituted alkoxy group, a substituted or unsubstituted aryl group, and a substituted or unsubstituted heteroaryl group.

2. The organic compound according to claim 1, wherein the organic compound is represented by the following general formula [2]: 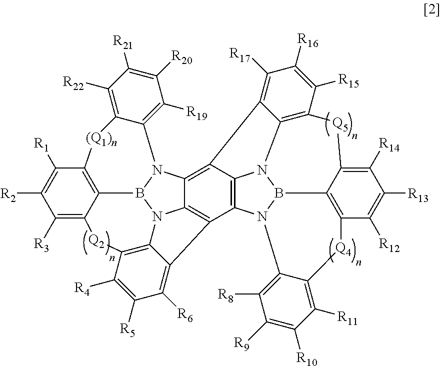
where in general formula [2], at least two of n are 1.

3. The organic compound according to claim 1, wherein the organic compound is represented by the following general formula [3]: 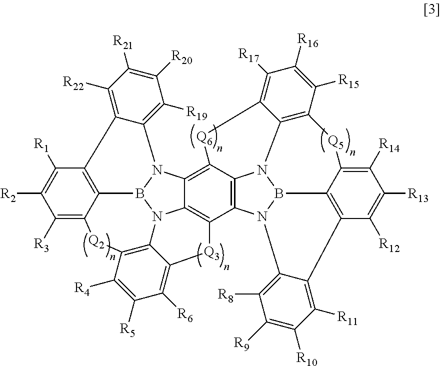
where in general formula [3], at least two of n are 1.

4. The organic compound according to claim 1, wherein the organic compound is represented by the following general formula [4]:

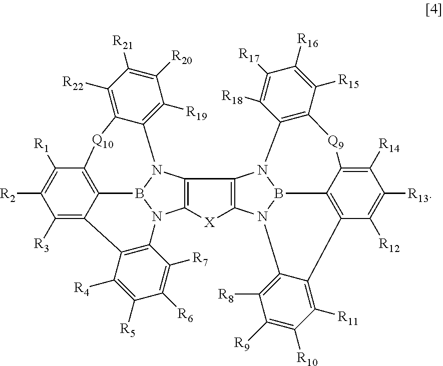

5. The organic compound according to claim 1, wherein at least two of n are 1.

6. The organic compound according to claim 1, wherein at least four of n are 1.

7. An organic light-emitting device, comprising:
an anode and a cathode; and
an organic compound layer disposed between the anode and the cathode, wherein at least one layer of the organic compound layer contains the organic compound according to claim 1.

8. The organic light-emitting device according to claim 7, wherein the layer containing the organic compound is a light-emitting layer.

9. The organic light-emitting device according to claim 7, wherein the organic light-emitting device emits blue light.

10. The organic light-emitting device according to claim 8, further comprising another light-emitting layer stacked on the light-emitting layer, wherein the another light-emitting layer emits light of a color different from a color of light emitted from the light-emitting layer.

11. The organic light-emitting device according to claim 10, wherein the organic light-emitting device emits white light.

12. A display apparatus, comprising multiple pixels, at least one of the multiple pixels including the organic light-emitting device according to claim 7 and a transistor coupled to the organic light-emitting device.

13. A photoelectric conversion apparatus, comprising an optical unit including multiple lenses, an image pickup device configured to receive light passing through the optical unit, and a display unit configured to display an image captured by the image pickup device,
wherein the display unit includes the organic light-emitting device according to claim 7.

14. An electronic apparatus, comprising a display unit including the organic light-emitting device according to claim 7, a housing provided with the display unit, and a communication unit disposed in the housing and configured to communicate with an outside.

15. A lighting apparatus, comprising a light source including the organic light-emitting device according to claim 7, and a light diffusion unit or an optical filter configured to transmit light emitted from the light source.

16. A moving object, comprising a lighting unit including the organic light-emitting device according to claim 7, and a body provided with the lighting unit.

17. An exposure light source for an electrophotographic image-forming apparatus, comprising the organic light-emitting device according to claim 7.
